(19) United States
(12) Patent Application Publication
(10) Pub. No.: US 2025/0232997 A1
(43) Pub. Date: Jul. 17, 2025

(54) ADAPTIVE POSITIONING SYSTEMS AND ROUTINES USING AN AUTOCALIBRATION WAFER AND A CALIBRATION WAFER WITH CUTOUTS

(71) Applicant: Lam Research Corporation, Fremont, CA (US)

(72) Inventors: Peter S. Thaulad, San Jose, CA (US); Brett M. Herzig, San Jose, CA (US); Damon Tyrone Genetti, Livermore, CA (US); Charles Byron Reins, San Mateo, CA (US)

(21) Appl. No.: 18/703,238

(22) PCT Filed: Oct. 18, 2022
(86) PCT No.: PCT/US2022/047055

§ 371 Date: Apr. 19, 2024

Related U.S. Application Data
(60) Provisional application No. 63/262,767, filed on Oct. 20, 2021.

(51) Int. Cl. H01L 21/68

(52) U.S. Cl. CPC H01L 21/68

(57) ABSTRACT

Apparatuses and methods for assisting in the calibration of a wafer-handling robot for a semiconductor processing tool are provided herein. Some embodiments include a calibration wafer having a nominally circular disk shape having an outer edge with a nominal diameter of 200 mm±1 mm, 300 mm±1 mm, or 450 mm±1 mm, two or more cutouts arranged along the outer edge, and a plurality of fiducial markers, in which each cutout is at least partially defined by one or more edges, each cutout extends radially inwards at least 2 mm from a reference circle defined by the outer edge, and one or more fiducial markers are adjacent to each cutout.

### RELATED APPLICATION(S)

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

Semiconductor processing tools utilize wafer-handling robots to move semiconductor wafers in between various wafer stations. Since wafer-handling robots typically pick up semiconductor wafers from below using a blade- or spatula-type end effector and the semiconductor wafers are not positively secured to the wafer-handling robot end effector, there is often some small degree of variance in relative positioning between the end effector and the semiconductor wafers placed thereupon. Due to the sensitivity of semiconductor processing operations, it is typical to correct for such variance when placing semiconductor wafers using a wafer-handling robot so that the semiconductor wafers are placed in their respective processing stations within an acceptable tolerance range at a desired location, e.g., generally centered in the processing stations. Modern semiconductor processing tools utilize active wafer centering (AWC) systems to aid in such wafer placements.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

In some embodiments, a calibration wafer for use in a semiconductor processing tool may be provided. The calibration wafer may include a nominally circular disk shape having an outer edge with a nominal diameter of 200 mm±1 mm, 300 mm±1 mm, or 450 mm±1 mm, two or more cutouts arranged along the outer edge, and a plurality of fiducial markers. Each cutout may be at least partially defined by one or more edges, each cutout may extend radially inwards at least 2 mm from a reference circle defined by the outer edge, and one or more fiducial markers may be adjacent to each cutout.

In some embodiments, for each cutout, at least one fiducial marker may extend around at least one edge of the one or more edges of the cutout.

In some such embodiments, each cutout may have a shape, and at least one fiducial marker may have a substantially similar shape to the shape of the cutout.

In some such embodiments, for each cutout, at least one fiducial marker may be adjacent to the least one edge of the cutout.

In some embodiments, for each cutout, at least one fiducial marker may have a section that extends along at least a part of at least one edge of the cutout and is offset from the at least one edge by a substantially constant offset distance.

In some embodiments, for each cutout, at least one fiducial marker may be positioned within a distance of about 5 mm or less from one edge of the corresponding cutout.

In some embodiments, for each cutout, at least one fiducial marker may have a width between about 3 mm and about 0.01 mm.

In some embodiments, for each cutout, at least one fiducial marker may have a shape of a C-shape, an L-shape, a semi-circular shape, a partially obround shape, a linear shape, a plurality of lines, a non-linear shape, or one or more linear sections and one or more non-linear sections.

In some embodiments, each cutout may include at least four fiducial markers that form a pattern, and the pattern may be a plurality of circles, a plurality of triangles, a plurality of squares, a plurality of rectangles, a plurality of diamonds, a plurality of squares with at least two squares in contact with each other, a checkerboard, or a combination thereof.

In some embodiments, for each cutout, at least one fiducial marker may have a linear shape and is oriented along an axis that substantially intersects with a center of the calibration wafer.

In some embodiments, when viewed along an axis parallel to a center axis of the calibration wafer, each cutout may have a shape, and the shape may be a square, a square with rounded corners, a rectangle, a rectangle with rounded corners, a V-shape, a circle, a semi-circle, a triangle, a triangle with rounded corners, an obround shape, an ellipse, a hexagon, a pentagon, an octagon, a shape with linear and non-linear sections, or a shape with a plurality of linear sections.

In some embodiments, when viewed along an axis parallel to a center axis of the calibration wafer, each cutout may have a shape, and the shape has a width less than or equal to about 10 mm and a length less than or equal to about 10 mm.

In some embodiments, the calibration wafer may include three or more cutouts arranged along the outer edge.

In some embodiments, the cutouts may be arranged in a circular array about a center point of the calibration wafer.

In some such embodiments, the cutouts may be spaced substantially equally from each other about the center point.

In some embodiments, each cutout may be a through-hole.

In some embodiments, the calibration wafer may further include a top surface and a bottom surface opposite the top surface and at least partially defining a nominal thickness, and the top surface may have a different surface roughness than the bottom surface.

In some such embodiments, the top surface may be a lapped surface.

In some further such embodiments, the bottom surface may be a polished surface.

In some such embodiments, the calibration wafer may be comprised of silicon.

In some embodiments, the calibration wafer may further a nominal thickness of between about 0.5 mm and about 1.5 mm.

In some embodiments, a system for assisting in the calibration of a wafer-handling robot for a semiconductor processing tool may be provided. The system may include an autocalibration wafer including a substrate sized to be carried by the wafer-handling robot and having a first side that is configured to contact an end effector of the wafer-handling robot when the substrate is carried by the wafer-handling robot, a plurality of first imaging sensors supported by the substrate and positioned at locations offset from a common point of the substrate, each first imaging sensor having a downward-facing field of view when the substrate is oriented with the first side facing downwards, and a first controller, and the first controller is communicatively connected with each of the first imaging sensors, the calibration wafer of any one of the above embodiments, and a semiconductor processing tool that includes a wafer-handling robot, one or more wafer stations, and a second controller. Each wafer station includes one or more corresponding wafer supports, the wafer-handling robot and the second controller are communicatively connected, and the second controller and the first controller, in aggregate, are configured to: a) cause the wafer-handling robot to transfer the calibration wafer to a first wafer support of the one or more wafer supports of a first wafer station of the one or more wafer stations, b) cause the wafer-handling robot to position the autocalibration wafer above the first wafer station and the calibration wafer positioned thereon such that at least a part of each cutout is within a field of view of a corresponding first imaging sensor, and c) cause each first imaging sensor to obtain a corresponding first image of a fiducial marker on the calibration wafer and a fiducial of the first wafer support within the corresponding cutout of the calibration wafer while the autocalibration wafer is positioned over the first wafer support and the calibration wafer.

In some embodiments, the fiducial of the first wafer support may be an edge of the first wafer support.

In some embodiments, each first imaging sensor may have a field of view, and for each cutout of the calibration wafer, at least one fiducial marker may have a width between less than or equal to about 40% of the field of view.

In some embodiments, each first imaging sensor may have a field of view, and when viewed along an axis parallel to a center axis of the calibration wafer, each cutout may have a shape, and the shape may have a width less than or equal to about 50% of the field of view and a length less than or equal to about 50% of the field of view.

In some embodiments, the second controller and the first controller, in aggregate, may be further configured to d) determine a calibration wafer/wafer support horizontal offset between the center point of the calibration wafer and the center point of the first wafer support based on gap sizes between the fiducials of the first wafer support and the calibration wafer in the first images.

In some such embodiments, the second controller and the first controller, in aggregate, may be further configured to e) compare the calibration wafer/wafer support horizontal offset to a threshold calibration wafer/wafer support horizontal offset, and f) cause, responsive to determining that the calibration wafer/wafer support horizontal offset is above the threshold calibration wafer/wafer support horizontal offset, the wafer-handling robot to reposition the calibration wafer relative to the first wafer support to reduce the calibration wafer/wafer support horizontal offset.

In some further such embodiments, the second controller and the first controller, in aggregate, may be further configured to repeat (a) through (f) N times or until the calibration wafer/wafer support horizontal offset is at or below the threshold calibration wafer/wafer support horizontal offset, whichever occurs first.

In some embodiments, the second controller and the first controller, in aggregate, may be further configured to d) cause, before causing the wafer-handling robot to transfer the calibration wafer to the first wafer support, the wafer-handling robot to position the autocalibration wafer above the first wafer station, and e) cause each first imaging sensor to obtain a corresponding second image of a fiducial of the first wafer support while the autocalibration wafer is positioned above the first wafer support and while the calibration wafer is not positioned on the first wafer support.

In some such embodiments, the second controller and the first controller, in aggregate, may be further configured to determine a center point of the first wafer support based, at least in part, on the second images.

In some embodiments, the autocalibration wafer may further include a centrally-located, downward-facing second imaging sensor, and the second controller and the first controller, in aggregate, may be further configured to d) cause, before causing the wafer-handling robot to transfer the calibration wafer to the first wafer support, the wafer-handling robot to position the autocalibration wafer above the first wafer station, and e) cause the second imaging sensor to obtain a corresponding second image of a fiducial of the first wafer support while the autocalibration wafer is positioned above the first wafer support and while the calibration wafer is not positioned on the first wafer support.

In some such embodiments, the second controller and the first controller, in aggregate, may be further configured to determine a center point of the first wafer support based, at least in part, on the second image.

In some embodiments, the second controller and the first controller, in aggregate, may be further configured to d) cause, while the calibration wafer is not positioned on the first wafer support, the wafer-handling robot to transfer a first edge ring to the first wafer support such that a center point of the first edge ring is nominally centered on a center point of the first wafer support when viewed along a vertical axis. Also, a) may further include causing the wafer-handling robot to transfer the calibration wafer to the first wafer support after transferring the first edge ring to the first wafer support, b) may further include causing the wafer-handling robot to position the autocalibration wafer above the first wafer station, the first edge ring, and the calibration wafer positioned thereon such that each cutout is within the field of view of the corresponding first imaging sensor, and c) may further include causing each first imaging sensor to obtain the corresponding first image of the fiducial marker on the calibration wafer, the fiducial of the first wafer support within the cutout of the calibration wafer, and a fiducial of the first edge ring within the cutout of the calibration wafer while the autocalibration wafer is positioned over the first wafer support, the calibration wafer, and the first edge ring.

In some such embodiments, the second controller and the first controller, in aggregate, may be further configured to e) determine a calibration wafer/wafer support horizontal offset between the center point of the calibration wafer and the center point of the first wafer support based on gap sizes between the fiducials of the first wafer support and the calibration wafer in the first images, f) cause, responsive to determining that the calibration wafer/wafer support horizontal offset is above a threshold calibration wafer/wafer support horizontal offset, the wafer-handling robot to reposition the calibration wafer relative to the first wafer support to reduce the calibration wafer/wafer support horizontal offset, g) determine an edge ring/wafer support horizontal offset between the center point of the first edge ring and the center point of the first wafer support based, at least in part, on gap sizes between the fiducials of the first wafer support and the first edge ring in the first images, and h) cause, responsive to determining that the edge ring/wafer support horizontal offset is above a threshold edge ring/wafer support horizontal offset, the wafer-handling robot to reposition the first edge ring relative to the first wafer support to reduce the edge ring/wafer support horizontal offset.

In some further such embodiments, the determination in (g) may be further based on gap sizes between the first wafer support, the calibration wafer, and the first edge ring in the first images.

In some further such embodiments, the second controller and the first controller, in aggregate, may be further configured to i) repeat (a) through (c), (e), and (f), M times or until the calibration wafer/wafer support horizontal offset is at or below a threshold calibration wafer/wafer support horizontal offset, whichever occurs first, and j) repeat (a) through (d), (f), and (h), N times or until the edge ring/wafer support horizontal offset is at or below a threshold edge ring/wafer support horizontal offset, whichever occurs first.

In some such embodiments, the second controller and the first controller, in aggregate, may be further configured to e) determine an edge ring/wafer support horizontal offset between the center point of the first edge ring and the center point of the first wafer support based on gap sizes between the fiducials of the first wafer support and the first edge ring in the first images, f) compare the edge ring/wafer support horizontal offset to a threshold edge ring/wafer support horizontal offset, and g) cause, responsive to determining that the edge ring/wafer support horizontal offset is above the threshold edge ring/wafer support horizontal offset, the wafer-handling robot to reposition the first edge ring relative to the first wafer support to reduce the edge ring/wafer support horizontal offset.

In some further such embodiments, the second controller and the first controller, in aggregate, may be further configured to repeat (a) through (g) N times or until the edge ring/wafer support horizontal offset is at or below the threshold edge ring/wafer support horizontal offset, whichever occurs first.

In some embodiments, the second controller and the first controller, in aggregate, may be further configured to d) cause, while the calibration wafer is not positioned on the first wafer support, the wafer-handling robot to transfer a first edge ring to the first wafer support such that a center point of the first edge ring is nominally centered on a center point of the first wafer support when viewed along a vertical axis, e) cause the wafer-handling robot to transfer the calibration wafer to the first wafer support after transferring the first edge ring to the first wafer support, f) cause the wafer-handling robot to position the autocalibration wafer above the first wafer station, the first edge ring, and the calibration wafer positioned thereon such that each cutout is within a field of view of a corresponding first imaging sensor, and g) cause each first imaging sensor to obtain a corresponding second image of a fiducial marker on the calibration wafer, a fiducial of the first wafer support within the cutout of the calibration wafer, and a fiducial of the first edge ring within the cutout of the calibration wafer while the autocalibration wafer is positioned over the first wafer support, the calibration wafer, and the first edge ring.

In some such embodiments, the second controller and the first controller, in aggregate, may be further configured to h) determine a calibration wafer/wafer support horizontal offset between the center point of the calibration wafer and the center point of the first wafer support based on gap sizes between the fiducials of the first wafer support and the calibration wafer in the second images, and i) determine an edge ring/wafer support horizontal offset between the center point of the first edge ring and the center point of the first wafer support based on gap sizes between the fiducials of the first wafer support and the first edge ring in the second images.

In some further such embodiments, the determination in (i) may be further based on gap sizes between the first wafer support, the calibration wafer, and the first edge ring in the second images.

In some embodiments, the semiconductor processing tool may include a semiconductor processing chamber, the first wafer station may be in the semiconductor processing chamber, and the first wafer support may include a pedestal in the semiconductor processing chamber.

In some embodiments, the semiconductor processing tool may include a load lock for transferring wafers between different pressure environments, the first wafer station may be in the load lock, and the first wafer support may be a structure in the load lock.

In some embodiments, the semiconductor processing tool may include a buffer for storing one or more wafers before, after, or in between processing operations, the first wafer station may be in the buffer, and the first wafer support may be one of a plurality of wafer support ledges in the buffer.

In some embodiments, the second controller and the first controller, in aggregate, may be further configured to select a first wafer support of the one or more wafer supports of a first wafer station of the one or more wafer stations, cause the wafer-handling robot to retrieve the calibration wafer, cause the wafer-handling robot to retrieve the autocalibration wafer, and cause the wafer-handling robot to transfer the calibration wafer to the first wafer support such that a center point of the calibration wafer is nominally centered on a center point of the first wafer support when viewed along a vertical axis.

In some embodiments, (a) may be performed while an edge ring is not positioned on the first wafer support.

In some embodiments, a system for assisting in the calibration of a wafer-handling robot for a semiconductor processing tool may be provided. The system may include an autocalibration wafer including a substrate sized to be carried by the wafer-handling robot and having a first side that is configured to contact an end effector of the wafer-handling robot when the substrate is carried by the wafer-handling robot, a plurality of first imaging sensors supported by the substrate and positioned at locations offset from a common point of the substrate, each first imaging sensor having a downward-facing field of view when the substrate is oriented with the first side facing downwards, and a first controller, and the first controller is communicatively connected with each of the first imaging sensors, the calibration wafer of any one of the above embodiments, and a semiconductor processing tool that includes a wafer-handling robot, one or more wafer stations, and a second controller. Each wafer station includes one or more corresponding wafer supports, the wafer-handling robot and the second controller are communicatively connected, and the second controller and the first controller, in aggregate, are configured to a) cause, before causing the wafer-handling robot to transfer the calibration wafer to the first wafer support, the wafer-handling robot to position the autocalibration wafer above the first wafer station, b) cause each first imaging sensor to obtain a corresponding first image of a fiducial of the first wafer support while the autocalibration wafer is positioned above the first wafer support and while the calibration wafer is not positioned on the first wafer support and/or cause a centrally-located, downward-facing second imaging sensor of the autocalibration wafer to obtain a corresponding second image of a fiducial of the first wafer support while the autocalibration wafer is positioned above the first wafer support and while the calibration wafer is not positioned on the first wafer support, c) determine a center point of the first wafer support based, at least in part, on the first images and/or second image, d) cause, after (a) and (b), the wafer-handling robot to transfer the calibration wafer to a first wafer support of the one or more wafer supports of the first wafer station of the one or more wafer stations, e) cause, after (d), the wafer-handling robot to position the autocalibration wafer above the first wafer station and the calibration wafer positioned thereon such that at least a part of each cutout is within a field of view of a corresponding first imaging sensor, f) cause each first imaging sensor to obtain a corresponding third image of a fiducial marker on the calibration wafer and a fiducial of the first wafer support within the corresponding cutout of the calibration wafer while the autocalibration wafer is positioned over the first wafer support and the calibration wafer, g) cause the wafer-handling robot to transfer the calibration wafer off the first wafer support, h) cause, while the calibration wafer is not positioned on the first wafer support, the wafer-handling robot to transfer a first edge ring to the first wafer support such that a center point of the first edge ring is nominally centered on the center point of the first wafer support when viewed along a vertical axis, i) cause the wafer-handling robot to transfer the calibration wafer to the first wafer support after transferring the first edge ring to the first wafer support, j) cause the wafer-handling robot to position the autocalibration wafer above the first wafer station, the first edge ring, and the calibration wafer positioned thereon such that each cutout is within a field of view of a corresponding first imaging sensor, and k) cause each first imaging sensor to obtain a corresponding fourth image of a fiducial marker on the calibration wafer, a fiducial of the first wafer support within the cutout of the calibration wafer, and a fiducial of the first edge ring within the cutout of the calibration wafer while the autocalibration wafer is positioned over the first wafer support, the calibration wafer, and the first edge ring.

In some embodiments, the second controller and the first controller, in aggregate, may be further configured to I) determine, after (f) and before (h), a calibration wafer/wafer support horizontal offset between the center point of the calibration wafer and the center point of the first wafer support based on gap sizes between the fiducials of the first wafer support and the calibration wafer in the third images.

In some embodiments, the second controller and the first controller, in aggregate, may be further configured to I) determine a calibration wafer/wafer support horizontal offset between the center point of the calibration wafer and the center point of the first wafer support based on gap sizes between the fiducials of the first wafer support and the calibration wafer in the fourth images, and m) determine an edge ring/wafer support horizontal offset between the center point of the first edge ring and the center point of the first wafer support based on gap sizes between the fiducials of the first wafer support and the first edge ring in the fourth images.

In some embodiments, a method may be provided. The method may include positioning a calibration wafer with one or more cutouts onto a wafer support of a wafer station, positioning an autocalibration wafer, the autocalibration wafer having a substrate and a plurality of first imaging sensors positioned at locations offset from a common point of the substrate and each first imaging sensor having a downward-facing field of view when the substrate is oriented with a first side of the substrate facing downwards, above the calibration wafer and the wafer support such that at least a part of each cutout is within the field of view of a corresponding first imaging sensor, obtaining, by the plurality of first imaging sensors on the autocalibration wafer, a corresponding first image of one or more fiducial markers on the calibration wafer and one or more fiducials of the wafer support nearby the corresponding one or more cutouts of the calibration wafer while the autocalibration wafer is positioned above the calibration wafer; and determining a calibration wafer/wafer support horizontal offset between the center point of the calibration wafer and the center point of the wafer support based on one or more gap sizes between the one or more fiducial markers on the calibration wafer and the one or more fiducials of the wafer support in the corresponding first images.

In some embodiments, the method may further include comparing the calibration wafer/wafer support horizontal offset to a threshold calibration wafer/wafer support horizontal offset, and repositioning, responsive to determining that the calibration wafer/wafer support horizontal offset is above the threshold calibration wafer/wafer support horizontal offset, the calibration wafer relative to the wafer support to reduce the calibration wafer/wafer support horizontal offset.

In some embodiments, the method may further include positioning, before positioning the calibration wafer on the wafer support, the autocalibration wafer above the wafer station, obtaining, by each first imaging sensor, a corresponding second image of a fiducial of the first wafer support while the autocalibration wafer is positioned above the first wafer support and while the calibration wafer is not positioned on the first wafer support, and determining a center point of the wafer support based, at least in part, on the second images.

In some embodiments, the method may further include positioning, before positioning the calibration wafer on the wafer support, the autocalibration wafer above the wafer station, obtaining, by a centrally-located, downward-facing second imaging sensor of the autocalibration wafer, a corresponding second image of a fiducial of the first wafer support while the autocalibration wafer is positioned above the first wafer support and while the calibration wafer is not positioned on the first wafer support, and determining a center point of the wafer support based, at least in part, on the second images.

In some embodiments, the method may further include transferring, while the calibration wafer is not positioned on the first wafer support, an edge ring to the wafer support such that a center point of the edge ring is nominally centered on a center point of the wafer support when viewed along a vertical axis. Also, the positioning of the calibration wafer may further include positioning the calibration wafer on the wafer support after transferring the edge ring to the wafer support, the positioning of the autocalibration wafer above the wafer station further may include positioning the autocalibration wafer above the wafer station, the edge ring, and the calibration wafer positioned thereon such that each cutout is within the field of view of the corresponding first imaging sensor, the obtaining may further include causing each first imaging sensor to obtain the corresponding first image of the fiducial marker on the calibration wafer, the fiducial of the wafer support within the cutout of the calibration wafer, and a fiducial of the edge ring within the cutout of the calibration wafer while the autocalibration wafer is positioned over the wafer support, the calibration wafer, and the edge ring, and the determining may further include determining an edge ring/wafer support horizontal offset between the center point of the edge ring and the center point of the wafer support based, at least in part, on gap sizes between the fiducials of the wafer support and the edge ring in the first images.

In some such embodiments, the method may further include repositioning, responsive to determining that the calibration wafer/wafer support horizontal offset is above a threshold calibration wafer/wafer support horizontal offset, the calibration wafer relative to the wafer support to reduce the calibration wafer/wafer support horizontal offset.

In some further such embodiments, the method may further include repeating the positioning of the calibration wafer, the positioning of the autocalibration wafer, the obtaining, the determining of the calibration wafer/wafer support horizontal offset, and the repositioning M times or until the calibration wafer/wafer support horizontal offset is at or below a threshold calibration wafer/wafer support horizontal offset, whichever occurs first.

In some such embodiments, the method may further include repositioning, responsive to determining that the edge ring/wafer support horizontal offset is above a threshold edge ring/wafer support horizontal offset, the edge ring relative to the wafer support to reduce the edge ring/wafer support horizontal offset.

In some further such embodiments, the method may further include repeating the positioning of the edge ring, the positioning of the calibration wafer, the positioning of the autocalibration wafer, the obtaining, the determining, and the repositioning N times or until the calibration wafer/wafer support horizontal offset is at or below a threshold calibration wafer/wafer support horizontal offset, whichever occurs first.

In some such embodiments, the determining may be further based on gap sizes between the wafer support, the calibration wafer, and the edge ring in the first images.

In some embodiments, a method may be provided. The method may include positioning, before positioning an edge ring or a calibration wafer of any one of the above embodiments onto a wafer support of a wafer station, an autocalibration wafer above a wafer station, the autocalibration wafer having a substrate and a plurality of first imaging sensors positioned at locations offset from a common point of the substrate and each first imaging sensor having a downward-facing field of view when the substrate is oriented with a first side of the substrate facing downwards, obtaining, by each first imaging sensor, a corresponding first image of a fiducial of the wafer support while the autocalibration wafer is positioned above the first wafer support and while the calibration wafer or the edge ring are not positioned on the wafer support and/or obtaining a centrally-located, downward-facing second imaging sensor of the autocalibration wafer to obtain a corresponding second image of a fiducial of the wafer support while the autocalibration wafer is positioned above the wafer support and while the calibration wafer or edge ring are not positioned on the first wafer support, determining, based, at least in part, on the first images and/or second image, a center point of the wafer support, positioning, after the determining, the calibration wafer on the wafer support, positioning, after positioning the calibration wafer on the wafer support, the autocalibration wafer above the wafer station and the calibration wafer positioned thereon such that at least a part of each cutout is within a field of view of a corresponding first imaging sensor, obtaining, by each first imaging sensor, a corresponding third image of a fiducial marker on the calibration wafer and a fiducial of the wafer support within the corresponding cutout of the calibration wafer while the autocalibration wafer is positioned over the wafer support and the calibration wafer, transferring the calibration wafer off the wafer support, positioning an edge ring to the wafer support such that a center point of the edge ring is nominally centered on the center point of the wafer support when viewed along a vertical axis, positioning the calibration wafer on the wafer support after transferring the edge ring to the wafer support, positioning the autocalibration wafer above the wafer station, the edge ring, and the calibration wafer positioned thereon such that each cutout is within a field of view of a corresponding first imaging sensor, obtaining, by each first imaging sensor, a corresponding fourth image of a fiducial marker on the calibration wafer, a fiducial of the wafer support within the cutout of the calibration wafer, and a fiducial of the edge ring within the cutout of the calibration wafer while the autocalibration wafer is positioned over the first wafer support, the calibration wafer, and the edge ring, determining a calibration wafer/wafer support horizontal offset between the center point of the calibration wafer and the center point of the wafer support based on gap sizes between the fiducials of the wafer support and the calibration wafer in the fourth images, and determining an edge ring/wafer support horizontal offset between the center point of the edge ring and the center point of the wafer support based on gap sizes between the fiducials of the wafer support and the edge ring in the fourth images.

In some embodiments, a calibration wafer for use in a semiconductor processing tool may be provided. The calibration wafer may include a nominally circular disk shape having an outer edge with a nominal diameter of 200 mm±1 mm, 300 mm±1 mm, or 450 mm±1 mm, one or more through-holes in an interior region of the calibration wafer, and a plurality of fiducial markers. Each through-hole may be at least partially defined by one or more edges, and one or more fiducial markers may be adjacent to each through-hole.

In some embodiments, one or more through-holes may be positioned at the center of the calibration wafer, and at least one fiducial marker may be adjacent to the one or more through-holes at the center of the calibration wafer. In some embodiments, the one or more through-holes may be positioned off the center of the calibration wafer.

In some embodiments, the calibration wafer may include a plurality of through-holes that are each spaced at a radial distance from the center of the calibration wafer that is less than the nominal diameter of the calibration wafer.

In some such embodiments, the plurality of through-holes may be substantially equally spaced around the center of the calibration wafer. In some embodiments, the plurality of through-holes may not be equally spaced around the center of the calibration wafer.

In some embodiments, the calibration wafer may further include two or more cutouts arranged along the outer edge, and a second plurality of fiducial markers, in which each cutout may be at least partially defined by one or more edges, each cutout may extend radially inwards at least 2 mm from a reference circle defined by the outer edge, and one or more fiducial markers of the second plurality of fiducial markers may be adjacent to each cutout. In some embodiments, the calibration wafer may include one or no cutouts along the outer edge.

In some embodiments, a system for assisting in the calibration of a wafer-handling robot for a semiconductor processing tool may be provided. The system may include an autocalibration wafer including a substrate sized to be carried by the wafer-handling robot and having a first side that is configured to contact an end effector of the wafer-handling robot when the substrate is carried by the wafer-handling robot, a first imaging sensor supported by the substrate and having a downward-facing field of view when the substrate is oriented with the first side facing downwards, and a first controller, wherein the first controller is communicatively connected with the first imaging sensor, a calibration wafer having one or more through-holes and one or more fiducial markers adjacent to each through-hole, and a semiconductor processing tool that includes a wafer-handling robot, one or more wafer stations, and a second controller. Each wafer station may include one or more corresponding wafer supports that each have one or more fiducial markers on a wafer support area of the corresponding wafer support, the wafer-handling robot and the second controller may be communicatively connected, and the second controller and the first controller, in aggregate, may be configured to a) cause the wafer-handling robot to transfer the calibration wafer to a first wafer support of the one or more wafer supports of a first wafer station of the one or more wafer stations, b) cause the wafer-handling robot to position the autocalibration wafer above the first wafer station and the calibration wafer positioned thereon such that at least a part of the through-hole is within a field of view of the first imaging sensor, and c) cause the first imaging sensor to obtain a corresponding first image of a fiducial marker on the calibration wafer and a fiducial of the first wafer support within the corresponding through-hole of the calibration wafer while the autocalibration wafer is above the calibration wafer.

In some embodiments, the autocalibration wafer may include a plurality of first imaging sensors, the calibration wafer may include a plurality of through-holes, b) may further include causing the wafer-handling robot to position the autocalibration wafer above the first wafer station and the calibration wafer positioned thereon such that at least a part of each through-hole is within a field of view of each corresponding first imaging sensor, and c) may further include causing each first imaging sensor to obtain a corresponding first image of a fiducial marker on the calibration wafer and a fiducial of the first wafer support within the corresponding through-hole of the calibration wafer while the autocalibration wafer is positioned above the calibration wafer.

In some embodiments, the fiducial of the first wafer support may be a fiducial marker on the wafer support area of the first wafer support.

In some embodiments, the fiducial of the first wafer support may be a fiducial marker at the center of the wafer support area of the first wafer support.

### BRIEF DESCRIPTION OF THE DRAWINGS

The various implementations disclosed herein are illustrated by way of example, and not by way of limitation, in the figures of the accompanying drawings, in which like reference numerals refer to similar elements.

FIG. 1A depicts a top view of a wafer support area and an edge ring.

FIG. 1B depicts a top view of a wafer and the wafer support area and the edge ring of FIG. 1A.

FIG. 2A depicts a top view of a calibration wafer.

In FIG. 2B depicts a magnified view of one cutout of the calibration wafer of FIG. 2A.

FIGS. 2C-2E depict example magnified sections of the calibration wafer cutout of FIG. 2B with fiducial markers that form various patterns.

FIG. 3A depicts the calibration wafer of FIG. 2A placed relative to a wafer support area.

FIGS. 3B-3D depict magnified views of three areas in FIG. 3A.

FIGS. 3E-3G depict additional magnified views of the three areas in FIG. 3A.

FIG. 4A depicts an edge ring and the calibration wafer of FIG. 2A placed relative to a wafer support area.

FIGS. 4B-4D depict magnified views of three areas in FIG. 4A.

FIGS. 4E-4G depict additional magnified views of the three areas in FIG. 4A.

FIG. 5 depicts a schematic of an example autocalibration wafer with broken lines/shaded regions showing a wafer support, edge ring, and calibration wafer positioned therebeneath.

FIG. 6 is a photograph of an example autocalibration wafer.

FIG. 7 depicts a line drawing plan view of another example autocalibration wafer 700.

FIGS. 8A through 8J depict a schematic of a semiconductor processing tool during various stages of operation using an autocalibration wafer and a calibration wafer with a plurality cutouts.

FIG. 9 depicts a flow chart of a technique for determining the location of a reference point of a structure at a wafer station using an autocalibration wafer.

FIG. 10 depicts a flow chart of a technique for determining the relative positioning of two structures at a wafer station using an autocalibration wafer.

FIG. 11 depicts a flow chart of a technique for determining the location of the center point of a wafer support using an autocalibration wafer.

FIG. 12 depicts a flow chart of a technique for calibrating the placement of a calibration wafer on a wafer support.

FIG. 13 depicts a flow chart of a technique for concurrently calibrating the placement of a calibration wafer relative to a wafer support and an edge ring relative to the wafer support.

FIG. 14 depicts a flow chart of such a technique for verifying repeatability of wafer placement.

FIG. 15 depicts a calibration wafer having a center through-hole positioned on a wafer support having a fiducial.

FIG. 16 depicts a calibration wafer having a plurality of through-holes that is positioned on a wafer support having a plurality of fiducials.

The Figures herein are generally not drawn to scale, although various aspects of the Figures, e.g., as discussed below, may be drawn to scale.

### DETAILED DESCRIPTION

### Introduction and Context

In typical semiconductor processing systems, accurate placement of wafers in preparation for various semiconductor processing operations and/or wafer-handling operations is achieved through a manual or semi-automated teaching process which typically requires the involvement of a technician or other human oversight in order to (1) “teach” a wafer-handling robot the desired locations of semiconductor wafers, edge rings, and/or wafer supports, such as electrostatic chucks (ESCs) with respect to each other or relative to an end effector of a wafer-handling robot, (2) “teach” an active wafer centering (AWC) system, and (3) perform wafer placement repeatability verification; once the wafer-handling robot has been taught such locations, any potential deviation in wafer placement from such a location for any given wafer, e.g., due to slight misalignments between that wafer and the end effector arising during the transfer of the wafer to the end effector, may be corrected out through using the AWC. Such manual or semi-automated teaching processes are time-consuming and cumbersome to implement.

Such teaching processes typically begin with training a wafer-handling robot the various locations where wafers are to be picked from or placed into during semiconductor processing tool operation. Generally speaking, while wafer-handling robots may be initially configured to have a general sense of where each such location is in a tool, wafer-handling robots will require some degree of customization to adapt their operation to the unique characteristics of the particular semiconductor processing tool that they are installed in, e.g., to accommodate different assembly tolerances or part tolerances. In order to accomplish this, wafer-handling robots may be placed into a teaching mode in which the wafer-handling robot may, for each location that is to be “taught,” be guided into a position that corresponds with the position or configuration that the wafer-handling robot would be in under certain “ideal” conditions for that location—for example, the position or configuration that the wafer-handling robot is in when a semiconductor wafer is positioned with its center within a known distance (which may generally be desirably minimized or reduced to zero) from a reference point on an end effector of the wafer-handling robot and also within a known distance (which may also generally be desirably minimized or reduced to zero) from, for example, of the center of a wafer support at that location.

In typical wafer-handling robot training, the “ideal” positioning of the wafer-handling robot for each location may be achieved, for example, through the use of one or more fixtures or other structures that may interface with a feature on the wafer-handling robot end effector that serves as a reference point and with another feature that is fixed with respect to the target location. For example, in some wafer-handling robot teaching scenarios, a disk having a diameter similar to that of a semiconductor wafer may be pinned into place on the end effector of the wafer-handling robot using, for example, a shaft or pin that passes through the center of the disk and through a reference feature, e.g., a hole, in the end effector. Therefore, the disk is centered on what is intended to be the location on the end effector on which semiconductor wafers will be centered when carried by the wafer-handling robot using the end effector. There may be similar pins that may be installed in features of the wafer support that may contact the edge of the disk when the end effector/disk are urged against such pins, thereby causing the disk and end effector to be guided into a particular position, e.g., a centered position. During such wafer-handling movement, the wafer-handling robot may be placed into an unpowered state that allows for the joints/arm segments of the wafer-handling robot to be easily moved through manual manipulation by an operator. Once the wafer-handling robot is properly positioned, the wafer-handling robot controller may obtain measurements of the various linkage positions of the wafer-handling robot, e.g., through obtaining measurements of relative or absolute angular displacement of the various rotational joints of the wafer-handling robot, in order to determine what the associated kinematic state of the wafer-handling robot is when in the desired position. Once the wafer-handling robot has obtained such positional information and associated it with that location, the location may be considered to have been taught to the wafer-handling robot.

Once a wafer-handling robot has been taught the various locations to which wafers will be delivered (or from which wafers will be retrieved), the wafer-handling robot may be controlled so as to enter the kinematic state that was taught for a location when performing future wafer transfer operations involving that location. If the semiconductor wafers placed on the end effector of the wafer-handling robot are placed so as to be exactly centered on the reference point of the end effector, those same semiconductor wafers will similarly be adequately centered in the destination location when placed by the end effector of the wafer-handling robot after the wafer-handling robot is returned to the taught kinematic state for that location. However, due to various reasons, semiconductor wafers placed on the end effector of the wafer-handling robot may not be exactly centered on the reference point of the end effector. Such misalignments may appear to be relatively minor, e.g., on the scale of tens of micrometers, but even such minute misalignments may be detrimental to wafer processing operations. The use of active wafer centering (AWC) systems to allow for correction of such end effector/wafer misalignments has become commonplace within the industry.

In a typical AWC configuration, optical AWC sensors and optical beam emitters are positioned outside of a semiconductor wafer processing chamber in fixed locations such that a semiconductor wafer, when passed into the processing chamber by a wafer-handling robot, travels through two or more of the optical beams emitted by the optical beam emitters. The AWC sensors may detect when each optical beam encounters an edge of a semiconductor wafer (as evidenced by either the occlusion or reestablishment of an optical beam directed at one of the optical sensors). The AWC system may, at each instant in which an edge of the semiconductor wafer triggers one of the AWC optical sensors, obtain from sensors of the wafer-handling robot defining coordinate locations for a reference point, e.g., a point that is nominally centered on the semiconductor wafer (this may only be an estimated or desired center location, as the exact placement of the semiconductor wafer on the end effector may not be known), on the end effector of the wafer-handling robot. For a circular semiconductor wafer and with at least two AWC optical beam sensors, the resulting four or more coordinates are sufficient (and as few as three coordinates can be used) to determine the location of the center point of the semiconductor wafer relative to the semiconductor processing chamber (the AWC sensor and the wafer-handling robot base are both fixedly mounted with respect to the semiconductor processing chamber). Once such wafer center information has been obtained, it may be used as either a reference location for future wafer placements or may serve as a measurement of a current wafer position that may need correction.

For example, to train an AWC system, a reference wafer of some sort may be manually centered on a desired destination, e.g., a pedestal in a semiconductor processing chamber. Such manual centering may, for example, be performed with the aid of a fixture or a jig that guides the reference wafer to be properly centered with respect to the pedestal. Once the reference wafer is considered to be sufficiently centered on the pedestal, the wafer-handling robot may be controlled to retrieve the reference wafer and remove it from the semiconductor processing chamber; as the reference wafer is removed from the semiconductor processing chamber, the AWC system may be used to measure and determine the center of the reference wafer. This information, coupled with information from the wafer-handling robot that describes the displacements undergone by the reference wafer in moving from the pedestal-centered location to the center location determined by the AWC system, allows for future wafer placements to be adjusted to achieve similar wafer-pedestal centering. For example, if a new wafer is placed on the wafer-handling robot and passed through the AWC sensor in the same manner as the reference wafer, the center of the new wafer may be found to be somewhat offset, e.g., 0.5 mm in the X direction and 0.25 mm in the Y direction, from the previously-determined center location of the reference wafer. To correct for such variance, the wafer-handling robot may be controlled to account for such displacements when placing the new wafer on the pedestal by applying a corrective displacement when placing the new wafer, e.g., by moving the new wafer by an additional −0.5 mm in the X direction and −0.25 mm in the Y direction before, after, or during displacement of the new wafer by the inverse of the displacement used to bring the reference wafer from the pedestal and to and through the AWC sensor.

Similar techniques using AWC systems may also be used for adjusting the placement of edge rings onto wafer supports, e.g., the center point of an edge ring may be determined using an AWC as it passes through the optical beams of an AWC system, and any offset between such an edge ring center point and, for example, a reference location used by the AWC system as the “ideal” center placement for a wafer or edge ring. In implementations in which an AWC system is used in conjunction with edge ring placement, there may be more edge/optical beam intersections than with a semiconductor wafer due to the edge ring having both an inner edge and an outer edge (thus, there may be four edge/optical beam intersections detected by each optical sensor as the edge ring passes through the AWC optical sensors instead of just two, as is the case when a semiconductor wafer is passed through the optical beam sensors). In such implementations, the data resulting from some of the edge/optical beam intersections, e.g., the intersections of the optical beams with the outer edge of the edge ring, may be ignored, and the center of the edge ring may be determined based on the remaining edge/optical beam intersections, e.g., the intersections of the optical beams with the inner edge of the edge ring. The reference point used by the AWC system to evaluate the degree to which an edge ring deviates from a desired placement on a wafer-handling robot end effector may, in some implementations, be the same reference point that may be used for semiconductor wafer AWC correction, i.e., a reference point determined based on measurements obtained from a semiconductor wafer using the AWC system. In other implementations, the reference point used for edge ring AWC correction may be obtained based on measurements obtained from an edge ring using the AWC system, e.g., the AWC system may be trained with an edge ring in order to obtain a reference point for future edge ring placements. It will be understood that the placement techniques discussed herein, as well as the AWC training and correction techniques discussed herein, may generally be applicable in the context of both semiconductor wafer placement operations and edge ring placement operations.

AWC systems are widely used in the semiconductor processing industry and have typically provided good wafer-centering performance. However, the training process is labor-intensive, may occupy a significant period of time, and is prone to user error. While such training may occur as part of initial semiconductor processing tool set-up, such training may need to be repeated periodically over the lifetime of the tool, e.g., when any modifications to the relative locations of the semiconductor processing chamber, AWC sensor, and the wafer-handling robot have occurred, or if wafer processing operations begin to exhibit non-uniformities indicating that the placement of semiconductor wafers on the pedestal has drifted off-center, or generally if any maintenance is performed on the chamber, including a wet clean. It will be understood that references to placing wafers or edge rings onto wafer supports, pedestals, or other equipment by a wafer-handling robot may also, in various implementations, implicitly include indirect placement of the wafer or edge ring onto the wafer support. For example, in many semiconductor processing machines, vertically-translating lift pins positioned in the wafer support may be used to lift wafers off of a wafer-handling robot end effector, allowing the end effector to then be moved out from underneath the wafer without moving the wafer. The lift pins may then be controlled to lower the wafer onto the wafer support. The same process may be repeated in reverse to remove a wafer or other structure from a wafer support.

The term “wafer support,” as used herein, may refer to any of a variety of structures that are configured to support a semiconductor wafer within a semiconductor processing tool (other than the end effector of a wafer-handling robot). Wafer supports may include, for example, pedestals, ESCs, or other generally circular platform-like structures that may be located within semiconductor processing chambers (or other chambers) and that generally contact a semiconductor wafer in a distributed manner, e.g., through face-to-face contact between the back side of the semiconductor wafer and the top face of the wafer support, as well as structures that may support the semiconductor wafer through more restrictive contact, e.g., arcuate support ledges that may only contact the semiconductor wafer at points along the semiconductor wafer's outer circumference. The top face of the wafer support may also have various configurations, such as a planar surface, or a non-planar surface that includes a plurality of contact areas, such as micro-contact areas with circular surfaces or mesas having square surfaces, that contact and support the wafer.

Wafer supports may include not only components that directly contact the semiconductor wafer, but may also include components or portions that extend beyond the outer circumference of the semiconductor wafer, e.g., an annular portion of a pedestal or ESC that may extend beyond the outer circumference of a semiconductor wafer. Wafer supports may, in some instances, be equipped to provide for movement of the semiconductor wafers supported thereby, e.g., vertical movement and/or rotational movement. Wafer supports may also, in some instances, include lift pins, such as those discussed above, or other mechanisms that may be caused to extend upwards relative to the remainder of such wafer supports, thereby lifting semiconductor wafers off of the remainder of the wafer supports. In some instances, a wafer support may include various removable components, such as edge rings. For example, some wafer supports may be configured to be used with a removable edge ring, e.g., an edge ring that is designed to be able to be removed by a wafer-handling robot of a semiconductor processing tool, that may interface with one or more non-removable edge rings, e.g., edge rings that are not designed to be able to be removed by a wafer-handling robot of a semiconductor processing tool-such non-removable edge rings may, of course, still be removed by a technician, that are, for the purposes of this disclosure, considered to be part of the wafer support.

The present disclosure contemplates an autocalibration system, e.g., an adaptive positioning system, that may be used in conjunction with an AWC system (or similar apparatus) and/or wafer-handling robot in order to, among other things, provide for automated teaching of the AWC system and/or the wafer-handling robot for a semiconductor processing tool; such a system may be used for automated teaching of a wafer-handling robot either under vacuum or atmospheric pressure, as the chambers within which the teaching occurs may be sealed as they would be during normal semiconductor processing operations. Such an autocalibration system may also allow for various aspects of component or wafer placement to be evaluated and/or corrected, as needed, in order to comply with process requirements.

The autocalibration system may also be used to guide the placement of edge rings, which are nominally annular structures that have an inner diameter that is typically sized just slightly larger (or smaller, in some cases) than the outer diameter of a semiconductor processing wafer, thereby effectively “extending” the diameter of the semiconductor wafer during processing. Edge rings have the effect of causing any “edge effects” that might degrade on-wafer process result uniformity to occur on the outer edge of the edge ring (where wafer uniformity is largely unaffected) rather than on the semiconductor wafer itself.

The autocalibration systems provided herein use an autocalibration wafer, which has on-board downward facing imaging sensors that are configured to collect images, in conjunction with a calibration wafer which has a plurality of cutouts that provide visibility to the autocalibration wafer's imaging sensors of structures underneath the calibration wafer, such as edges and surfaces of wafer support and/or edge ring, that would otherwise be covered by a wafer when it is placed on the wafer support. The autocalibration wafer's downward-facing imaging sensors are able to capture images of structures and features underneath it, but these imaging sensors are typically limited by their field of view and their line of sight. Accordingly, they generally cannot see through one structure that is obstructing another structure or feature. For example, when a wafer is placed on a wafer support, it may cover some or all of the wafer support area and other features, such as a portion of an edge ring, and the autocalibration wafer's imaging sensors are unable to see and capture images of the features and structures covered by the wafer.

In a further example, some wafer support areas have an outer diameter that is less than the outer diameter of a wafer placed thereon such that the wafer may partially or fully cover and obscure the wafer support area and its outer diameter from being visible to the autocalibration wafer's imaging sensors. Additionally, when optional edge rings are used, the edge rings may have a structure that is positioned close to the wafer support area and positioned underneath a wafer when the wafer is placed on the wafer support area. Because of this wafer support area and edge ring spacing, the wafer on the wafer support area may again partially or fully cover and obscure the edge ring's structure that is underneath the wafer from being visible to the autocalibration wafer's imaging sensors.

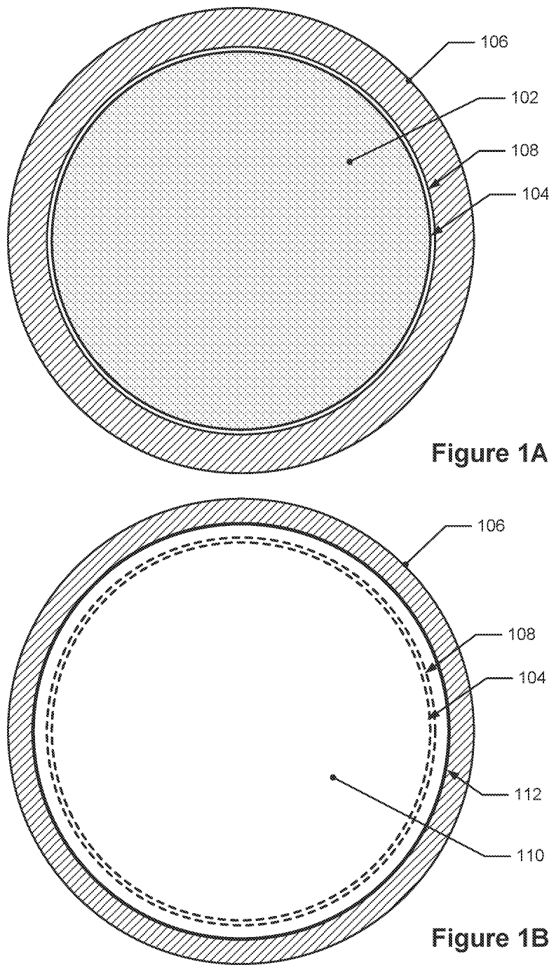

This obstruction by a wafer is illustrated in FIGS. 1A and 1B, with FIG. 1A depicting a top view of a wafer support area and an edge ring, and FIG. 1B depicting a top view of a wafer and the wafer support area and the edge ring of FIG. 1A. As can be seen in FIG. 1A, the wafer support area 102 has a circular area with an outer edge 104 and the edge ring 106 is positioned around and radially outside the wafer support area 102. The inner edge 108 of the edge ring 106 is also positioned close to the outer edge 104 of the wafer support area 102. In some implementations, the inner edge 108 of the edge ring 106 and the outer edge 104 of the wafer support area 102 may both be smaller than a wafer's outer edge. As illustrated in FIG. 1B, when the wafer 110 with an outer edge 112 larger than the inner edge 108 of the edge ring 106 and the outer edge 104 of the wafer support area 102 is placed on the wafer support area 102, the wafer 110 may cover and at least partially obstruct the inner edge 108 and the outer edge 104 from being visible, including from being visible from above, as shown by the inner edge 108 and the outer edge 104 depicted in broken lines indicating they are not visible from above.

According to some embodiments, a calibration wafer with a plurality of cutouts positioned near or around the outer edge of the calibration wafer is disclosed. In some embodiments, the calibration wafer may have one or more cutouts, two or more cutouts, or three or more cutouts, for example. The calibration wafer advantageously provides visibility and line-of-sight viewing of various structures under the calibration wafer that would otherwise be covered and unviewable by conventional wafers without such cutouts. The calibration wafer's cutouts thereby enable the autocalibration wafer's downward imaging sensors to simultaneously capture images of various fiducials associated with the wafer support, the calibration wafer, and/or the edge ring placed on that wafer support that would otherwise be covered by the calibration wafer placed thereon. These fiducials include, for example, fiducial markers or structures on the calibration wafer, the wafer support area's outer edge, and the edge ring's inner edge. Fiducials, as the term is used herein, refer to features that are assumed as being generally fixed with respect to particular structures, e.g., a circular edge of a component may serve as a fiducial of the center point of that structure (it will be understood that such fiducials may, over time, undergo changes in size and/or shape due, for example, to erosion or deposition occurring due to wafer processing operations; such gradual changes in shape and/or size should not be considered to change the “fixed” nature of such fiducials in the context of this disclosure.) In the examples discussed herein, the fiducials used are features such as the outer edge of a semiconductor wafer, outer and/or inner edges of an edge ring, the outer edge of a wafer support or an edge of a feature of the wafer support, a surface discontinuity in a wafer support (for example, a wafer support's upper surface may have a circular boss surrounded by an annular surface that is recessed downward from the circular boss; the transition between the circular boss and the annular surface may be such a surface discontinuity), or any other feature that is suitable for the techniques discussed herein.

### Calibration Wafers, Systems, and Techniques

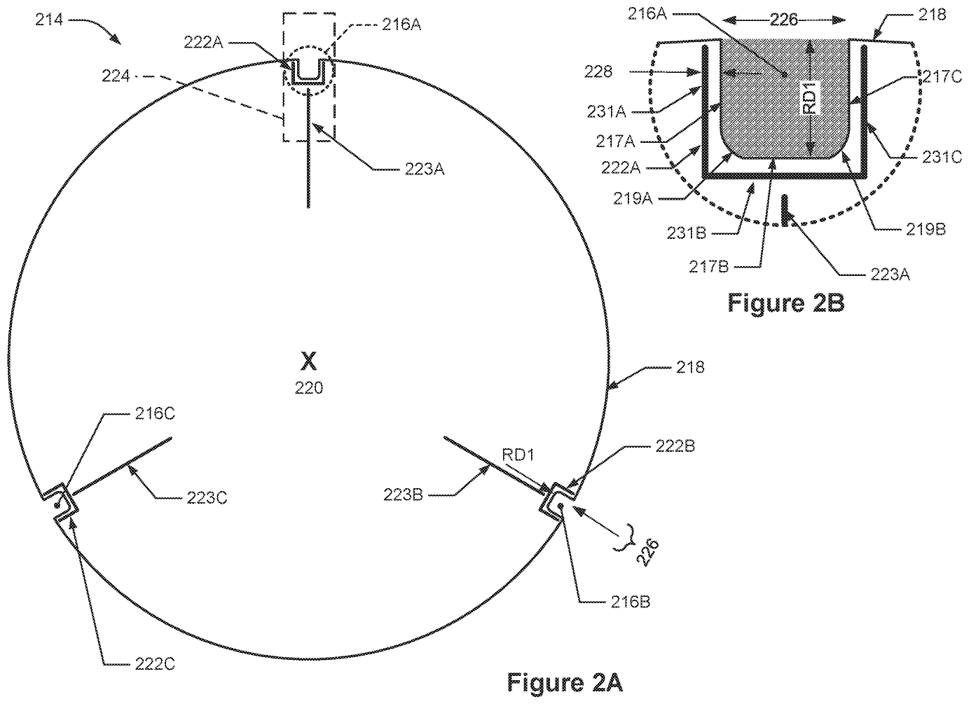

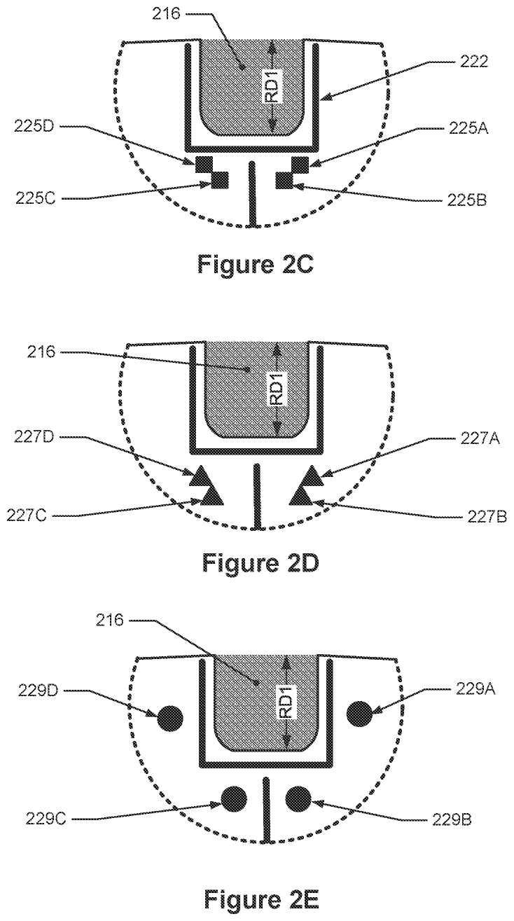

Aspects of this disclosure pertain to a calibration wafer with a plurality of cutouts and an autocalibration wafer with downward facing imaging sensors configured to simultaneously capture fiducials of the calibration wafer and fiducials of other structures that are visible within and/or adjacent to each of the cutouts. As noted above, these other structures are those that would typically be covered by a wafer placed on the wafer support, such as the outer edge of the wafer support area and/or the inner edge of the edge ring. Unless otherwise stated, the term “calibration wafer” is used to describe the calibration wafer having a plurality of cutouts as explained in more detail below and shown, for example, in FIGS. 2A and 2B that are discussed below. In some embodiments, the calibration wafer may have one or more cutouts, two or more cutouts, or three or more cutouts, for example. Further, the term “autocalibration wafer” as used herein, refers to wafers that are “smart” or otherwise equipped with sensors and other electronics that enable such autocalibration wafers to obtain data and measure various parameters relating to semiconductor processing tool performance.

With respect to the autocalibration wafer, generally speaking, it may have a size and shape similar to that of a wafer and/or edge ring that the semiconductor processing tool is configured to process, thereby allowing the autocalibration wafer to be transported by a wafer-handling robot of the semiconductor processing tool in generally the same manner as the wafer-handling robot transports semiconductor wafers during processing. Thus, the autocalibration wafer may be sized so as to have a maximum height and diameter that are less than the vertical and horizontal clearances of passages of the semiconductor processing tool through which wafers may be transported by the wafer-handling robot.

As noted above, the autocalibration wafer may include a variety of sensors—although the number and type of sensors may vary depending on the particular functionalities provided by the autocalibration wafer. It will be understood that an autocalibration wafer in accord with this disclosure may be configured to provide any one of, some, or all of the sensors/functionalities discussed herein.

In addition to the various sensors that the autocalibration wafer may include, the autocalibration wafer may also include various components for controlling and obtaining data from those sensors, communicating with other components (such as a controller of a semiconductor processing tool), and/or storing and/or manipulating the data collected from the sensors. Such autocalibration wafers may thus be linked to a controller of a semiconductor processing tool, introduced into the semiconductor processing tool, and then, through actions caused by one or both of a controller (or controllers) of the autocalibration wafer and the controller (or controllers) of the semiconductor processing tool, caused to perform various sensing and data collection operations during various phases of a calibration routine or placement routine performed by the semiconductor processing tool. As will be apparent from the examples discussed in more detail below, such a calibration routine or placement routine may be performed by the semiconductor processing tool with little or no human oversight.

In some embodiments, the autocalibration wafer may have a substrate with an overall shape similar to that of a semiconductor wafer, e.g., a generally circular shape, although it will be recognized that the autocalibration wafer may, in some instances, be shaped differently—for example, portions of the substrate that are not used to support sensors or other components, or that do not come into contact with, for example, contact pads on an end effector or lift pins of a pedestal, may be omitted, which may result in openings or notches in the autocalibration wafer. Moreover, in some implementations, the autocalibration wafer may have peninsulas or other protrusions along an otherwise nominally circular exterior edge, e.g., to support a sensor at a location that is beyond the nominal outer diameter of the corresponding semiconductor wafer. The autocalibration wafer may also include one or more indexing features, e.g., a flat edge, a notch, etc., along an exterior boundary to provide a mechanism for identifying the orientation of the autocalibration wafer. Reference may be made herein to the “center” of the autocalibration wafer, which will be understood to refer to a point of the autocalibration wafer that is intended to be positioned in the same position as the center of a semiconductor wafer or edge ring is positioned when the autocalibration wafer is transported or positioned within the semiconductor processing tool in a similar manner to how the semiconductor wafer or the edge ring are typically transported or positioned. It will be understood that while the center of the autocalibration wafer may coincide with a geometric center of the substrate and/or a center of mass of the autocalibration wafer, such alignment is not a necessary condition.

As noted above, the autocalibration wafer may have a plurality of downward-facing imaging sensors, e.g., charge-coupled device (CCD) sensors or complementary metal oxide semiconductor (CMOS) sensors, located at various positions at radial offsets from the center of the autocalibration wafer. Such offsets may be selected such that when the autocalibration wafer is, for example, positioned above a semiconductor wafer placed on a wafer support of the semiconductor processing tool, each imaging sensor has a field of view that is wide enough to capture a portion of the edge of semiconductor wafer, as well as a portion of the wafer support. If the semiconductor processing tool typically uses an edge ring during wafer processing operations, then the imaging sensors may be radially offset from the center of the autocalibration wafer such that the imaging sensor field of view is wide enough to capture a portion of the edge ring (when placed on the wafer support) as well.

In some implementations of an autocalibration wafer, the downward-facing imaging sensors may be placed along a circle that has a diameter of nominally the same size, e.g., within ±10% or ±20% of, as the semiconductor wafers that the semiconductor processing tool is configured to process. In yet other implementations, the downward-facing imaging sensors may be placed along a circle that has a diameter in between that of the semiconductor wafers that the semiconductor processing tool is configured to process and an edge ring that the semiconductor processing tool is configured to use. In some such implementations, the downward-facing imaging sensors may be positioned along a diameter that is the average, or within, for example, ±10% of the average, of the nominal outer diameter of the edge ring and the nominal inner diameter of the edge ring or the nominal outer diameter of the semiconductor wafer. Such positioning may, for example, cause the downward-facing imaging sensors to be able to simultaneously capture the outer edge of a wafer support (or an edge of a feature on the wafer support, e.g., an ESC), the outer and/or inner edges of the edge ring, and the outer edge of the semiconductor wafer within their fields of view when the autocalibration wafer is generally positioned at a location centered above the wafer support (and when the semiconductor wafer and/or edge ring are centered on the wafer support).

As provided above, such imaging sensor placement allows the autocalibration wafer to simultaneously obtain images of various fiducials associated with a wafer support, a calibration wafer with the plurality of cutouts, and/or an edge ring placed on that wafer support.

The images obtained of a given set of fiducials for the calibration wafer, edge ring, or other structure may then be analyzed to determine an offset (or offsets) between reference points on two structures associated with those fiducials. For example, if the fiducials used are fiducial markers, such as lines or shapes, on the calibration wafer and the outer circular edge of the wafer support seen within the cutouts of the calibration wafer, then the relative sizes of the radial gaps between the fiducials of the calibration wafer and the outer circular edge of the wafer support area may be determined and used to generate an estimate of the degree to which the center of the calibration wafer is offset from the center of the wafer support area. In general, images from at least three imaging sensors must be used to make such a determination (similar techniques may be practiced with images from only two imaging sensors, but will generally not be as accurate, as assumptions must be made as to the relative sizes of the fiducials used). In some instances, some fiducials may not be visible at all times, in which case intermediate fiducials may be needed.

In another example, if the fiducials used are the outer circular edge of the wafer support area and the inner edge of the edge ring that are both visible within the cutouts of the calibration wafer, then the relative sizes of the radial gaps between the fiducials of the wafer support area and the edge ring may be determined and used to generate an estimate of the degree to which the center of the edge ring is offset from the center of the wafer support area.

Further, the plurality of cutouts enables the simultaneous imaging of the calibration wafer and its fiducials, the wafer support's fiducials, e.g., the outer edge of the wafer support area, and the edge ring's fiducials, e.g., the inner edge of the edge ring. This concurrent imaging further allows the simultaneous and direct determinations of the relative offset of the calibration wafer with respect to the wafer support, and the relative offset of the edge ring with respect to the wafer support. These simultaneous imaging and determinations may advantageously be made without the use of intermediary or “proxy” fiducials and without removing the calibration wafer to view the structures underneath it.

Once fiducials for two structures have been imaged by the autocalibration wafer and an offset between the two structures determined, the offset can be compared against a threshold offset, which may represent the maximum offset between those structures that is considered acceptable for proper operation of the semiconductor processing tool. If the offset exceeds the threshold offset, then the semiconductor processing tool may cause corrective action to be taken.

Various aspects of the calibration wafer will now be discussed. FIG. 2A depicts a top view of a calibration wafer according to some embodiments. In FIG. 2A, the calibration wafer 214 has a plurality of cutouts 216A, 216B, and 216C that are arranged along the outer edge 218 of the calibration wafer 214; cutout 216A is encircled by a dashed circle while the other cutouts 216B and 216C have indicators in their respective centers. In some implementations the calibration wafer 214 may be nominally circular and the outer edge 218 may have a nominal diameter that is the same, or substantially the same, e.g., within ±5%, of a process wafer. In some such implementations, the outer edge 218 of the calibration wafer 214 may have a diameter that is 200 mm±1 mm, 300 mm±1 mm, or 450 mm±1 mm. As noted herein, although calibration wafer 214 includes three cutouts, some implementations of the calibration wafer may have one cutout, two cutouts, three cutouts, or more. In some such implementations, the calibration wafer may have only one cutout in the edge of the wafer and this cutout is not considered the same feature as a notch or alignment notch.

Each cutout 216A-C may be defined by one or more edges and the one or more edges may define a shape of the cutout. As can be seen in FIG. 2A, each cutout 216A-C has a generally rectangular shape. In FIG. 2B, which depicts a magnified view of one cutout of the calibration wafer of FIG. 2A, the cutout 216A is highlighted with shading and it has a generally rectangular shape with two rounded corners. In some embodiments, the two rounded corners may be chamfered corners instead. This cutout 216A may be considered to be defined by, or to have, three linear edges 217A-C and two curved edges 219A and B. In some implementations, the cutout shape may differ and may be a square, a square with rounded corners, a rectangle, a rectangle with rounded corners, a V-shape, a circle, a semi-circle, a triangle, a triangle with rounded corners, an obround shape, an ellipse, a hexagon, a pentagon, an octagon, a shape with linear and non-linear sections, or a shape with a plurality of linear sections. In some implementations, the cutouts may be considered a portion of material removed from the calibration wafer 214, which may include the edge of the calibration wafer being removed. In some instances, a cutout may be a hole through the calibration wafer which leaves the calibration wafer edge intact, i.e., a through-hole. For example, a through-hole cutout may have material between its edge and the outer edge 218 of the calibration wafer 214. As seen in FIG. 2A, the edge of the calibration wafer 214 at each cutout 216A-C has been removed while the remaining edge 218 is intact.

As further illustrated in FIG. 2A, each cutout 216A-C extends radially inwards from the outer edge 218 towards the center axis 220, marked with an “X”, by a radial distance RD1 which may also be considered a length of the cutout. This radial distance may be measured from a reference circle defined by, and co-radial with, the outer edge 218. The cutouts may also have a width 226, which may also be considered a tangential width, that is perpendicular to the radial distance RD1. In some implementations, the radial distance RD1 may be at least 2 mm and the width 226 may be at least 2 mm. In some implementations, the radial distance RD1 may be less than or equal to about 10 mm and/or the width 226 may be less than or equal to about 10 mm. Similar to above, in some embodiments, the width 226 may be a function of the imaging sensor's, e.g., the camera's, field of view. In some instances, the imagining sensor's field of view may limit the radial distance RD1 (e.g., a length of the cutout shape) and/or width 226 of the cutout to less than or equal to about 20 mm, about 15 mm, about 12 mm, about 10 mm, or about 5 mm, for example, or to less than or equal to about 50%, about 40%, about 30%, or about 20% of the field of view, for instance.

The cutouts 216A-C may be positioned along the outer circumference or outer edge 218 of the calibration wafer 214 and may be spaced apart by some known amount, e.g., 120° apart in this example. In some implementations, the cutouts 216A-C may also be spaced apart equally or substantially equally from each other (e.g., without about ±10% deviation from equal spacing). The downward-facing first imaging sensors of an autocalibration wafer may be caused to be positioned such that at least a portion of each of the cutouts 216A-C are within the fields of view 224 of the first imaging sensors which is represented by a dashed box 224.

The calibration wafer 214 may also include one or more sets of fiducial markers, such as fiducial markers 222A-C and fiducial markers 223A-C which may be positioned adjacent to each cutout 216A-C, respectively, including adjacent to an edge of the cutout. The fiducial markers 222A-C and 223A-C may also be positioned along the outer circumference or outer edge 218 of the calibration wafer 214 and may be spaced apart by a known amount, and also positioned so that at least some parts of each fiducial marker 222A-C and/or 223A-C is within the field of view 224 of the first imaging sensors. In this example, the fiducial markers 222A-C and/or 223A-C are spaced apart by a known distance, such as 120° about the circumference of the calibration wafer 214.

The fiducial markers 222A-C may also have known shapes and sizes, such as C-shaped, and the fiducial markers 223A-C may be radial lines which may be identified in the image data and used to establish a directional vector in each image. For example, if a fiducial marker 222A is of a known size and shape, e.g., having three 2 mm long linear sections, that known information may be used to determine the scale of the imaged features. For example, if a gap between a fiducial maker on the calibration wafer and a fiducial of a wafer support has a size that is 0.34 times the size of an edge of a fiducial marker having three 2 mm linear sections in the same image, then the size of the gap may be determined to be 0.34*2 mm=0.68 mm. In some implementations, such calculations may take into account, e.g., using machine vision or optical image correction techniques, the distortion of the images due to lens effects (e.g., using for example a checkerboard pattern) and may correct for such distortion using, for example calibration data associated with the autocalibration wafer.

The fiducial markers of the calibration wafer 214 are further illustrated in FIG. 2B; here the fiducial markers 222A and 223A of cutout 216A are more clearly visible. Fiducial marker 222A extends around at least a part of the edge, or perimeter, of the cutout 216A and as shown, it extends around substantially all of the cutout 216A. This fiducial marker 222A may also be considered adjacent to the edge of the cutout 216A. In some implementations, the fiducial marker 222A has three linear sections that each extend along at least a part of an edge of the cutout 216A. For example, the leftmost linear section 231A of fiducial marker 222A extends along at least a part of edge 217A and edge 219A, while the horizontal or bottom section 231B of fiducial marker 222A extends along at least a part of edges 219A, 217B, and 219B, and the rightmost linear section 231C of fiducial marker 222A extends along at least a part of edge 217C and edge 219B.

In some implementations, the fiducial marker may have a substantially similar shape to the cutout to which it is adjacent. For example, in FIG. 2B, the edges of the cutout may be considered to form a C-shape and the fiducial marker 222A is also seen having a substantially similar, e.g., within about 20%, C-shape. In some other implementations, the fiducial marker may have the form of other shapes, such as an L-shape, a semi-circular shape, a partially obround shape, a linear shape, a plurality of lines, a non-linear shape, or one or more linear sections and one or more non-linear sections.

The fiducial marker 222A may also have a known thickness or width, such as between about 0.01 mm and about 1 mm, about 0.01 mm and about 2 mm, about 0.01 mm and about 3 mm, or about 0.01 mm and about 4 mm, for example. This thickness or width may be considered the thickness of its line defining its shape, such as the width of the line defining the C-shape in FIG. 2B, for example. In some embodiments, the width of a fiducial marker may be a function of the imaging sensor's, e.g., a camera's, field of view. In some instances, the imagining sensor's field of view may limit the width of a fiducial marker to less than or equal to about 1 mm, about 2 mm, about 3 mm, or about 5 mm, for example, or to less than or equal to about 40%, about 30%, or about 20% of the field of view, for instance. As noted above, each cutout may have at least one fiducial marker that is adjacent to each cutout. In some implementations, this adjacency may be quantified as a distance from one of the edges of the cutout; in some instances, it may be considered a radial distance from the nominal center of the cutout. In FIG. 2B, this distance 228 is identified and in some embodiments, this distance may be about 5 mm or less, about 4 mm or less, about 3 mm or less about 2 mm or less, about 1 mm or less, or about 0.5 mm or less.

Referring back to FIG. 2A, each cutout 216A-C may also include a fiducial marker 223A-C with a linear shape, e.g., it is a line, that is oriented along an axis that intersects, or substantially intersects (e.g., within about 5% or about 1%), the center 220 of the calibration wafer 214. This linear fiducial marker 223A-C may be used to establish a directionality or orientation of each the image captured by each of the autocalibration wafer's imaging sensors. This line may be used to convert each of the three images into a single coordinate system.

In some embodiments, the calibration wafer may have additional fiducial markers that form a pattern that has multiple shapes, such as a plurality of circles, a plurality of triangles, a plurality of squares, a plurality of rectangles, a plurality of diamonds, a plurality of squares with at least two squares in contact with each other, a checkerboard, or a combination thereof. FIGS. 2C-2E depict example magnified sections of the calibration wafer cutout of FIG. 2B with fiducial markers that form various patterns. These fiducial markers may be used in addition, or alternatively, to those fiducial markers already discussed; as known to those skilled in the art, these fiducial markers and corresponding patterns are used for a computer vision pose operation for determining the position and orientation of the calibration wafer, cutout, and/or the other fiducial markers.

In FIG. 2C, the calibration wafer has a plurality of squares, four squares 225A-D as shown, that form a pattern adjacent to the cutout 216 and to the fiducial marker 223. Here, the corners of squares 225A and 225B are contacting each other and the corners of squares 225C and 225D are also touching each other which enables a more precise and accurate determination. In FIG. 2D, the calibration wafer has a plurality of triangles, four triangles 227A-D as shown, that form a pattern adjacent to the cutout 216 and to the fiducial marker 223. Here, the corners of triangles 227A and 227B are contacting each other and the corners of triangles 227C and 227D are also touching each other. In FIG. 2E, the calibration wafer has a plurality of circles, four circles 229A-D as shown, that form a pattern adjacent to the cutout 216 and to the fiducial marker 223, and in different positions than the fiducial markers of FIGS. 2C and 2D.

The calibration wafer may have various attributes that advantageously enable its use in the techniques described below. This may include attributes and features that enable or improve the imaging and subsequent image processing of the calibration wafer. For example, some implementations of the autocalibration wafer include light sources that illuminate the structures underneath it, including the calibration wafer, wafer support, and edge ring (when present). Therefore, reflectiveness of the top surface of the calibration wafer can impact the images taken by the autocalibration wafer and the resulting quality and accuracy of the measurements of fiducials on the calibration wafer. For instance, if the top surface of the calibration wafer is highly polished (e.g., shinny), the amount of light that would reflect off the calibration wafer to the imaging sensors could cause an unacceptable amount of distortion, which will likely lead to inaccurate measurements of the features. One example is that very bright reflection may cause insufficient contrast between the calibration wafer's fiducials, such as its fiducial markers and cutout edges, and the wafer support. Accordingly, some implementations of the calibration wafer have a top surface that is lapped to reduce its surface reflectivity. This lapping may result in the top surface of the calibration wafer having a mat finish. In some such implementations, the bottom surface of the calibration wafer may be a polished surface including polished silicon, for example.

In some embodiments, the calibration wafer may also be comprised of a material that approximates a process wafer, such as silicon. Although bare polished silicon is advantageous for mimicking a process wafer's contact with the end effector as well as thermal expansion and other material properties, but as mentioned above, in some implementations, using polished silicon would be too reflective. Accordingly, some implementations of the calibration wafer in the present disclosure are comprised of silicon with a top surface that is lapped to a first surface roughness, e.g., on the order of a micron, and a bottom surface that is polished to a second surface roughness, e.g., on the order of a several Angstroms. In some embodiments, non-silicon materials with lower inherent reflectivity, e.g., ceramics, may be used. However, some non-silicon materials may not produce sufficient contrast with respect to the fiducial markers in order to generate detailed images for feature measurement. For example, fiducial markers laser marked, etched, or otherwise applied to ceramic calibration wafers may not be sufficiently visible in the captured images.

In some other embodiments, it may be advantageous to have the calibration wafer be comprised of other materials, such as titanium, an aluminum or aluminum alloy, and/or composite material such as a carbon fiber.

The calibration wafer also has a nominal outer diameter and thickness that are nearly identical to a process wafer. The more similar the calibration wafer's shape, size, and/or material are to a process wafer, the more accurate its performance is to a process wafer which in turn provides for more accurate measurements and processing of wafers. Further, the calibration wafer can be handled by existing hardware that is configured to handle normal wafers, thereby not requiring special hardware, requalifications of clearances, slit valve widths, motion paths of robots, etc., for handling this calibration wafer. This may include the calibration wafer having the nominal outer diameter of 200 mm±1 mm, 300 mm±1 mm, or 450 mm±1 mm, and a nominal thickness of between about 0.5 mm and about 1.5 mm.

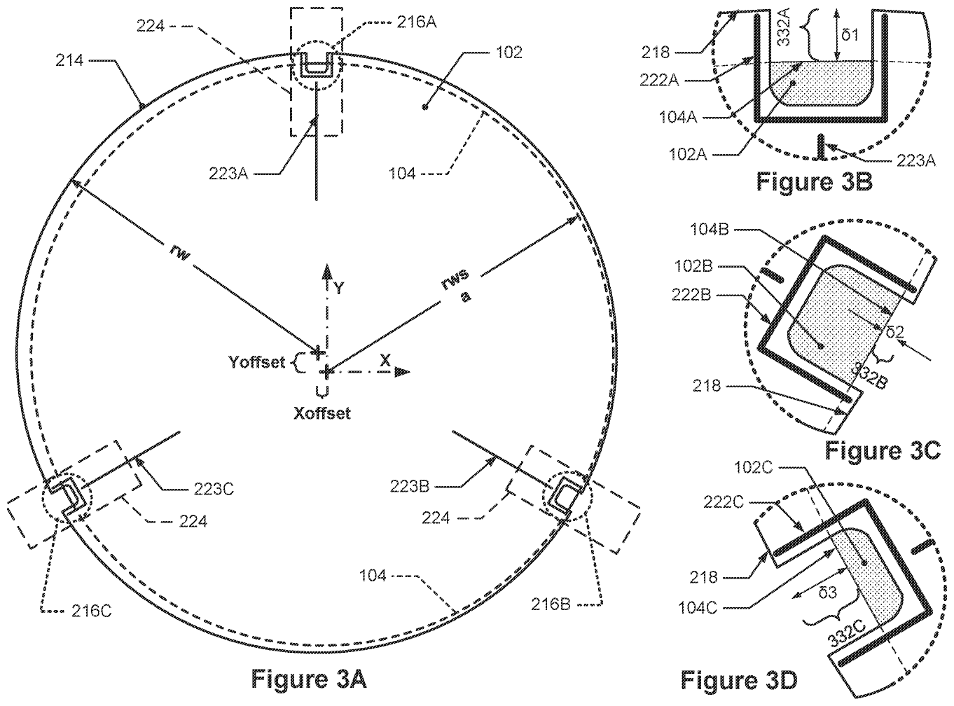

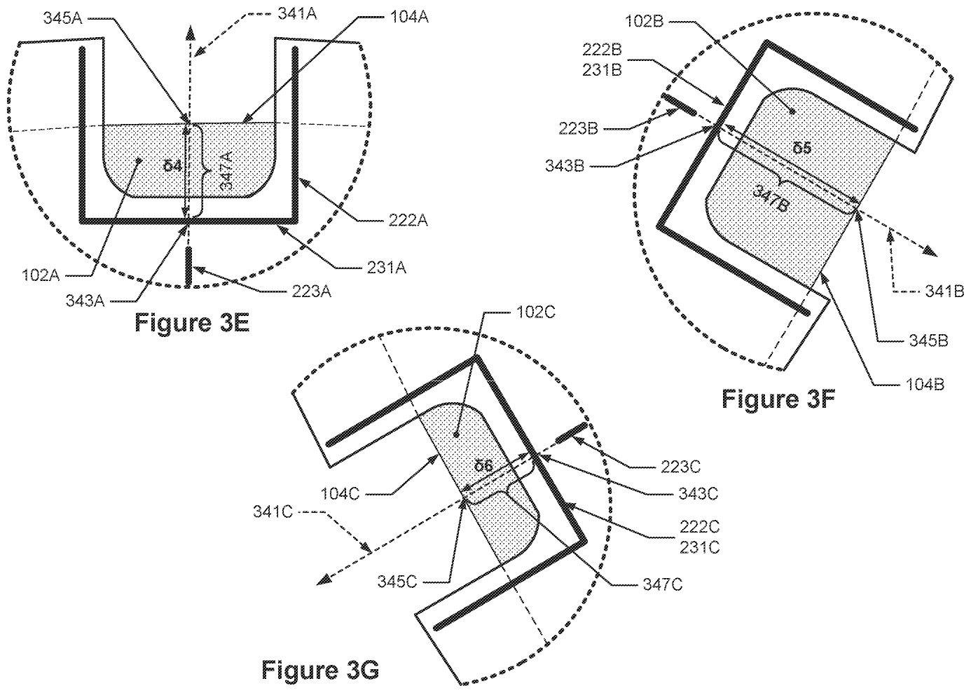

While various techniques may be used to determine a center-to-center offset between two structures and are considered within the scope of this disclosure, an example technique for determining such an offset is provided in the context of FIGS. 3A through 3D. As explained in more detail below, a calibration wafer/wafer support offset between the center point of the calibration wafer and the center point of the wafer support may be based on gap sizes between the fiducials of the wafer support and the calibration wafer. FIG. 3A depicts the calibration wafer of FIG. 2A placed relative to a wafer support area. Here, the calibration wafer 214 is positioned on a wafer support area 102 having an outer edge 104 that has a diameter smaller than the outer edge 218 of the calibration wafer 214. The calibration wafer 214 covers the wafer support area 102 except at the cutouts 216A-C where portions of the wafer support area 102, including portions of its outer edge 104, are visible and depicted as solid lines; the sections of the outer edge 104 of the wafer support area 102 that are covered by the calibration wafer 214 and not visible are depicted in broken lines.

The calibration wafer 214 and the wafer support area 102 are not shown to scale in FIG. 3A to make it easier to see, for example, including the misalignment between the centers (shown with crosshairs) of the calibration wafer 214 and the wafer support area 102 and the gaps in between the fiducials of the calibration wafer 214 and the wafer support area 102. As explained above and seen in FIG. 3A, the calibration wafer 214 includes a set of fiducial markers 222A-C positioned adjacent to each cutout 216A-C, respectively.

In such a technique, certain assumptions may be made regarding various factors—for example, the diameter of the calibration wafer may be assumed to be circular which, if true, may provide the necessary information for measuring deviations along its edge to determine off-centeredness; in the same for alternative example, the diameter of the calibration wafer may be assumed to be a known quantity, e.g., 300 mm, and/or the diameter of the wafer support area may also be assumed to be a known quantity, e.g., 275 mm. Thus, the radius r_{w} from the center point of the calibration wafer 214 to the outer edge 218 of the calibration wafer 214 may be assumed to be constant, except at the cutouts 216A-C. Further, the radius r_{wsq} from the center point of the wafer support area 102 to its outer edge 104 may also be assumed to be constant. As also noted above, the cutouts 216A-C are positioned so that they are within the fields of view of the first imaging sensors.

If one assumes that the center of the calibration wafer 214 also serves as the origin of a coordinate system in which the center-to-center offset between the wafer support area 102 and the calibration wafer 214 is to be determined, solving for the center location of the wafer support area 102 may be done by determining the location of three points along the outer edge 104 of the wafer support area 102 (which may be considered a fiducial of wafer support area 102) then determining the center location of a circle defined by those three points. Once the center location of the wafer support area 102 in the coordinate system of the calibration wafer 214 is known, then it is a simple process to extract the center-to-center offset between those two components. This center-to-center offset may then be used to determine a corresponding corrective offset that is to be performed using the wafer handling robot to place the calibration wafer (and future process wafers) in a more centered location relative to the wafer support area 102.

As shown in FIG. 3A, portions of the wafer support area 102 and its outer edge 104 are visible within each of the cutouts 216A-C. Further, these cutouts and portions of the wafer support area 102 are within the fields of view 224 of each imaging sensor that are depicted as a dashed rectangle. The cutouts, which are each within a dotted circle, and the portions of the wafer support visible within the cutouts are further illustrated in FIGS. 3B-3D which depict magnified views of three areas in FIG. 3A; these dotted circles in FIG. 3A represent the field of view in FIGS. 3B-3D. FIG. 3B depicts cutout 216A and a first portion 102A of the wafer support area 102, shown with shading, along with a section 104A of its outer edge 104, e.g., an arc, that are visible within the cutout 216A.

As noted above, various gaps may be defined between fiducials of the calibration wafer and fiducials of the wafer support. The measurement of these various gaps may be made and used to determine the center-to-center offset between the calibration wafer and the wafer support area. For example, a gap 332A exists between the section of the outer edge 104A of the wafer support area 102 (e.g., a fiducial of the wafer support area) and the outer edge 218 of the calibration wafer 214 (e.g., a fiducial of the calibration wafer). The gap 332A and various fiducials of the calibration wafer 214 may be used to determine the distance δ₁ between the outer edge 104A of the wafer support area 102 and the outer edge 218 of the calibration wafer 214. These fiducials include, for instance, the fiducial markers 222A and/or 223A which may provide size, scale, and/or orientation references in images containing them, the visible outer edge 218 of the calibration wafer 214 itself, and/or one or more edges of the cutout 216A.

In yet another such example, the calibration wafer fiducial may be one of the edges of the cutout, such as the edge 217B of cutout 216A in FIG. 2B, and the gap between the calibration wafer and the wafer support area is the gap that spans between the calibration wafer's cutout edge 217B and the edge 104 of the wafer support area. In yet another example, the calibration wafer fiducial may be one of the fiducial markers 222A-C or 223A-C, such as the bottom section 231B of the fiducial marker 222A of cutout 216A in FIG. 2B, and the gap between the calibration wafer and the wafer support area is the gap that spans between the calibration wafer's fiducial section 231B and the edge 104 of the wafer support area.

In FIGS. 3C and 3D, the cutouts 216B and 216C, respectively, are shown along with the portions 102B and 102C of the wafer support area 102 and sections 104B and 104C of the outer edge 104 that are visible within each respective cutout 216B and 216C. Gaps 332B and 332C are also shown in these Figures with distances 82 and 83 between the calibration wafer's 214 outer edge 218 and the wafer support's 102 outer edge 104. As provided above, other fiducials of the calibration wafer and/or the wafer support area may be used, such as the fiducial markers 222A-C or fiducial markers 223A-C and/or the one or more edges of the cutout for the calibration wafer, or the outer edge 104 or other fiducial marker on the wafer support area 102.

The gaps 332A-C and distances δ₁ to δ₃, in conjunction with the radius r_{wsa} of the wafer support area 102 and the angle along which each gap 332A-C may be used to determine the locations of three points along the outer edge 104 of the wafer support area 102. For example, for the gap 332A and distance δ₁, the distance δ₁ may be added to the radius r_{wsa} to obtain a radial distance from the wafer support area origin/center to the outer edge 218 of the calibration wafer 214. An XY coordinate pair for the point where the gap terminates at the outer edge 218 of the calibration wafer 214 may be determined using trigonometric relations based on the angular position of the radius extending from the center of the wafer support area to the point where the gap terminates at the outer edge 218 of the calibration wafer 214. In this example, the angular position of this radius is 0 degrees. Thus, the XY coordinates for such a point may be determined according to:

$$X = ( {r}_{w s a} + {δ}_{x} ) \cdot sin ( θ )$$

$$Y = ( {r}_{w s a} + {δ}_{x} ) \cdot cos ( θ )$$

where δₓ is the relevant gap distance, r_{wsa} is the wafer support area radius, and θ=the angle between a radius extending from the wafer support area origin to the gap and polar axis extending from the origin. Thus, for example, if r_{wsa}=145 mm, δ₁=22.823 mm, δ₂=17.338 mm, and δ₃=37.69 mm, then:

| Gap | δ | r_{wsa} | θ | X | Y |
|---|---|---|---|---|---|
| 1 | 22.823 mm | 145 mm | 0° | 0 mm | 167.823 mm |
| 2 | 17.338 mm | 145 mm | 120° | 140.589 mm | −81.169 |
| 3 | 37.69 mm | 145 mm | 240° | −158.214 mm | −91.345 mm |

It will be understood that the dimensions provided above are scaled larger than the proportions of FIG. 3A, and that such values for 8 are unrealistically large for a typical semiconductor processing tool and wafer-handling robot. In actual practice, the & values that may be obtained may frequently be on the order of less than 1 mm, e.g., less than 800 μm.

Once three pairs of XY coordinates are known for locations along the outer edge of the calibration wafer, a determination may be made as to the location of the center of the calibration wafer relative to the coordinate system origin (the center of the wafer support area) using the following equations:

$${x}_{c} = \frac{( {y}_{2} - {y}_{3} ) ( {x}_{1}^{2} + {y}_{1}^{2} ) + ( {y}_{3} - {y}_{1} ) ( {x}_{2}^{2} + {y}_{2}^{2} ) + ( {y}_{1} - {y}_{2} ) ( {x}_{3}^{2} + {y}_{3}^{2} )}{2 \cdot [ {x}_{1} ( {y}_{2} - {y}_{3} ) - {y}_{1} ( {x}_{2} - {x}_{3} ) + {x}_{2} {y}_{3} - {x}_{3} {y}_{2} ]}$$

$${y}_{c} = \frac{( {x}_{3} - {x}_{2} ) ( {x}_{1}^{2} + {y}_{1}^{2} ) + ( {x}_{1} - {x}_{3} ) ( {x}_{2}^{2} + {y}_{2}^{2} ) + ( {x}_{2} - {x}_{1} ) ( {x}_{3}^{2} + {y}_{3}^{2} )}{2 \cdot [ {x}_{1} ( {y}_{2} - {y}_{3} ) - {y}_{1} ( {x}_{2} - {x}_{3} ) + {x}_{2} {y}_{3} - {x}_{3} {y}_{2} ]}$$

where (x₁, y₁), (x₂, y₂), and (x₃, y₃) are each coordinate pairs, and (x_{c}, y_{c}) is the coordinate pair of the center of the calibration wafer. Thus, in the present example, (x_{c}, y_{c})=(−11.65 mm, 36.0 mm). After establishing the center offset between the wafer support area and the calibration wafer, appropriate actions may be taken to reduce the center offset between these two components. For example, in the present scenario, the calibration wafer could be retrieved by the wafer-handling robot and then moved by the reverse of the offset, e.g., (11.65 mm, −36.0 mm), in order to center the calibration wafer on the wafer support area. If the autocalibration wafer coordinate system is not aligned with the coordinate system used by the wafer-handling robot, the center-to-center offsets obtained using the autocalibration wafer may be transformed into equivalent offsets in the coordinate system used by the wafer-handling robot prior to using the wafer-handling robot to correct the placement of, for example, the edge ring. Once the calibration wafer is acceptably centered, the calibration wafer may then be used to train the AWC of the semiconductor processing tool. Various techniques involving the use of an autocalibration wafer for enhancing centering operations in a semiconductor processing tool are discussed in more detail further below.

Although the reference to the radius of the wafer support area was used in the above example, other reference features may be used and have similar results as long as each gap is referenced to the same equivalent feature. This may include, for example, a distance from a fiducial marker on the wafer support area that has a known distance. For instance, in the above example, 145 mm could be changed to 200 mm and the same eccentricity data should result, although the calculated X-Y points will be different than above.

The above equations and formulas are exemplary, illustrative, non-limiting examples. Other techniques for using the acquired data and measurements may be used for determining the relative centers and/or offsets between the calibration wafer, the substrate support, and/or the edge ring.

In another example, a gap between the fiducial markers 222A-C and a fiducial marker of the support area 102, such as its outer edge 104, may be used. FIGS. 3E-G depict magnified views of the three areas in FIG. 3A; these dotted circles in FIG. 3A represent the field of view in FIGS. 3E-3G. These FIGS. 3E-3G are similar to FIGS. 3B-3D, except for noted differences herein. FIG. 3E depicts cutout 216A and a first portion 102A of the wafer support area 102, shown with shading, along with a section 104A of its outer edge 104, e.g., an arc, that are visible within the cutout 216A. Here, a gap 347A is defined between the outer edge 104A and the bottom edge 231A of fiducial marker 222A along a line 341A that is collinear with the fiducial marker 223A, as illustrated. The gap 347A and its distance 84 is measured between a first intersection point 343A where the line 341A intersects the bottom edge 231A of fiducial marker 222A and a second intersection point 345A where the line 341A intersects the outer edge 104A.

Similarly, in FIG. 3F, cutout 216B is depicted with a gap 347B defined between the outer edge 104B and the bottom edge 231B of fiducial marker 222B along a line 341B that is collinear with the fiducial marker 223B. The gap 347B and its distance 85 is measured between a first intersection point 343B where the line 341B intersects the bottom edge 231B of fiducial marker 222B and a second intersection point 345B wherein the line 341B intersects the outer edge 104B. In FIG. 3G, cutout 216C is depicted with a gap 347C defined between the outer edge 104C and the bottom edge 231C of fiducial marker 222C along a line 341C that is collinear with the fiducial marker 223C. The gap 347C and its distance 86 is measured between a first intersection point 343C where the line 341C intersects the bottom edge 231C of fiducial marker 222C and a second intersection point 345C wherein the line 341C intersects the outer edge 104C. By measuring these gaps along the direction of fiducial markers 223A-C, the gap values are able to converge on the same coordinate system. In some embodiments, the gaps, and other features, may be measured with respect to and along a line (or axis) 341A-C in FIGS. 3B-G that is collinear with fiducial markers 223A-C, respectively.

These gaps 347A-C and distances 84 to 86 may be used with the techniques provided herein to determine the location of the center of the calibration wafer relative to the coordinate system origin, e.g., the center of the wafer support area. For example, similar to above, these gaps 347A-C and distances 84 to 86 may be used in conjunction with the radius r_{wsa} of the wafer support area 102, or other reference feature, and the angle along which each gap 347A-C is measured may be used to determine the locations of three points along the outer edge 104 of the wafer support area 102. For example, for the gap 347A and distance 84, the distance 84 may be subtracted from the radius r_{wsa} to obtain a radial distance from the wafer support area origin/center to a point, e.g., the first intersection point 343B, of the calibration wafer 214. An XY coordinate pair for the point where the gap 347A terminates on the calibration wafer 214 may be determined using trigonometric relations based on the angular position of the radius extending from the center of the wafer support area to the point where the gap terminates on the calibration wafer 214 as described above. Once the XY coordinates are determined, then the location of the center of the calibration wafer relative to the coordinate system origin may be determined as provided herein.

The cutouts of the calibration wafer also enable visibility and measurements of other elements and features, including one or more fiducials of an edge ring positioned on the wafer support, e.g., the pedestal or ESC. Referring back to FIGS. 1A and 1B, some implementations use an edge ring 106 that has one or more surfaces, including the inner edge 108, that is obscured and not visible when a conventional wafer is placed on the wafer support area 102 as illustrated in FIG. 1B. However, the calibration wafer with the plurality of cutouts described herein provides concurrent visibility to portions of both the wafer support area and the edge ring which allow for the simultaneous imaging and determinations of the center of the calibration wafer with respect to the wafer support area, and the center of the edge ring with respect to the wafer support area.

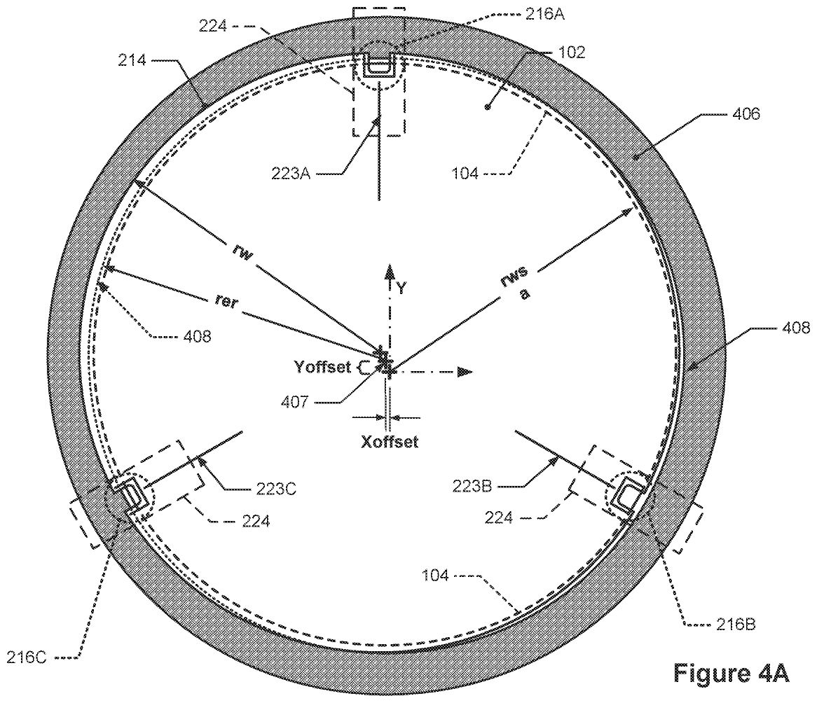

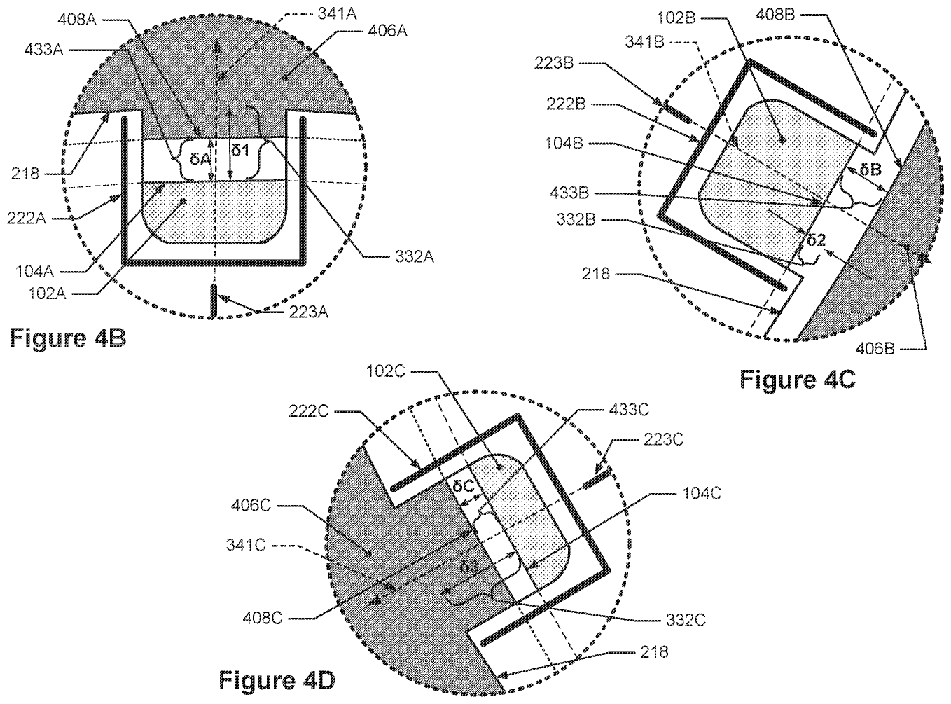

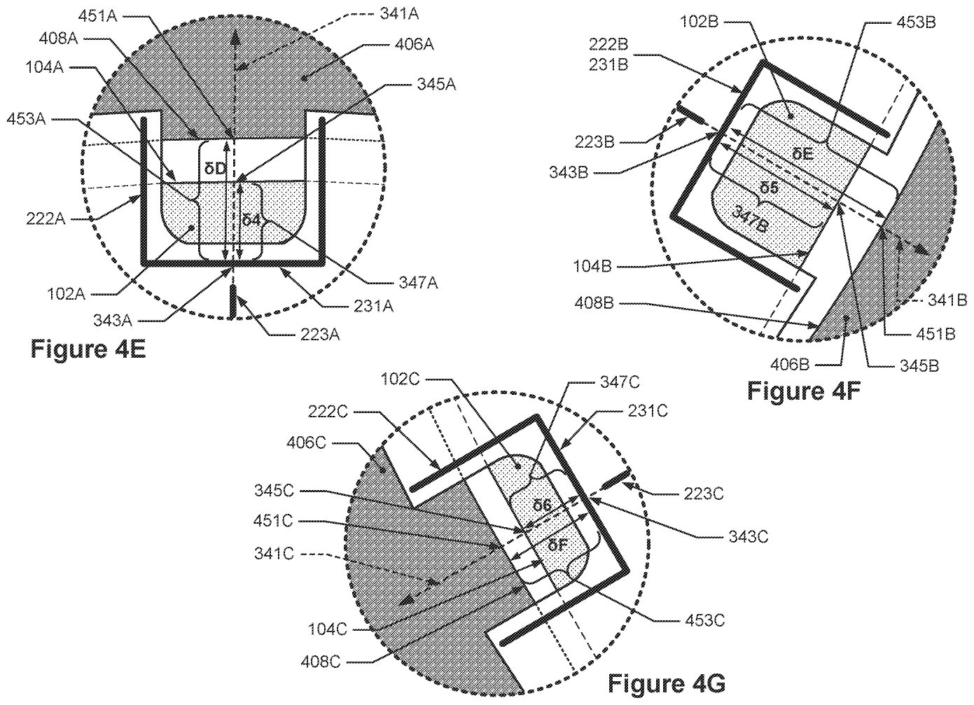

FIG. 4A depicts an edge ring 406 and the calibration wafer 214 of FIG. 2A placed relative to a wafer support area 102. FIG. 4A is the same as FIG. 3A except that the edge ring 406 is also shown positioned on the wafer support around the wafer support area 102 and having one or more portions under the calibration wafer 214. Here, the calibration wafer 214 is positioned on the wafer support area 102 with an outer edge 104 that has a diameter smaller than the outer edge 218 of the calibration wafer 214. The edge ring 406 has an inner edge 408 that is larger than the outer edge 104 of the wafer support area 102, and smaller than the outer edge 218 of the calibration wafer 214. The calibration wafer 214 covers the wafer support area 102 and sections of the edge ring 406 except at the cutouts 216A-C where portions of the wafer support area 102, including portions of its outer edge 104, and portions of the edge ring 406, including sections of its inner edge 408, are visible and depicted as solid lines; the sections of the outer edge 104 of the wafer support area 102 that are covered by the calibration wafer 214 are depicted in dashed lines and the sections of the inner edge 408 of the edge ring 406 that are covered by the calibration wafer 214 are depicted in dotted lines.

The calibration wafer 214, edge ring 406, and the wafer support area 102 are not shown to scale in FIG. 4A to make it easier to see, for example, the misalignment between the centers (shown with crosshairs) of the calibration wafer 214, the edge ring 406 (its center is labeled with 407), and the wafer support area 102 and the gaps in between the fiducials of the calibration wafer 214, the edge ring 406, and the wafer support area 102. In some implementations, the fiducial of the edge ring 406 may be considered its inner edge 408.

In such a technique, as with FIGS. 3A-D, certain assumptions may be made regarding various factors—for example, the diameter of the calibration wafer may be assumed to be a known quantity, e.g., 300 mm, the diameter of the inner edge 408 of the edge ring 406 may be assumed to be a known quantity, e.g., less than 300 mm and greater than 275 mm, such as 285 mm, and the diameter of the wafer support area 102 may be assumed to be a known quantity, e.g., 275 mm. Thus, the radius r_{w} from the center point of the calibration wafer 214 to the outer edge 218 of the calibration wafer 214 may be assumed to be constant, except at the cutouts 216A-C (there may be some portions along the outer edge of the calibration wafer where the radius may be shorter, e.g., if there is an indexing flat or notch along the edge). Further, the radius r_{wsa} from the center point of the wafer support area 102 to its outer edge 104, may be assumed to be constant, and the radius rₑᵣ from the center point of the edge ring 406 to its inner edge 408 may be assumed to be constant.

As illustrated above, if one assumes that the center of the calibration wafer 214 also serves as the origin of a coordinate system in which the center-to-center offset between the wafer support area 102 and the edge ring 406 is to be determined, solving for the center location of the wafer support area 102 may be done by determining the location of three points along the outer edge 104 of the wafer support area 102 (which may be considered a fiducial and wafer support area 102) then determining the center location of a circle defined by those three points. Once the center location of the wafer support area 102 in the coordinate system of the calibration wafer 214 is known, then it is a simple process to extract the center-to-center offset between the wafer support area 102 and the edge ring 406.

As shown in FIG. 4A, portions of the wafer support area 102 and its outer edge 104, and portions of the edge ring 406 and its inner edge 408, are visible within each of the cutouts 216A-C. Further, these cutouts, portions of the wafer support area 102, and portions of the edge ring 406 are within the fields of view 224 (depicted as dash rectangles) of imaging sensors on the autocalibration wafer. The cutouts and the portions of the wafer support and edge ring are further illustrated in FIGS. 4B-4D which depict magnified views of three areas in FIG. 4A. FIG. 4B depicts cutout 216A, and similar to FIG. 3B, the first portion 102A of the wafer support area 102, shown with light shading, along with the section 104A of its outer edge 104 visible within the cutout 216A is shown. Also depicted in FIG. 4A is a first portion 406A of the edge ring 406, shown with dark shading, along with a section 408A of its inner edge 408, e.g., an arc that is visible within the cutout 216A.

As noted above, various gaps may be defined between fiducials of the calibration wafer and fiducials of the wafer support, and fiducials between the edge ring and fiducials of the wafer support. The measurement of these various gaps may be made and used to determine the center-to-center offset between the calibration wafer and the wafer support area, and between the edge ring and the wafer support area.

For example, a gap 332A exists between the section of the outer edge 104A and the outer edge 218 of the calibration wafer 214 (as shown in FIG. 4B), and another gap 433A exists between the section of the edge ring 406A and the section of the wafer support area 102A, including between the outer edge 104A and the inner edge section 408A (as shown in FIG. 4B). The gaps 332A and 433A, and various fiducials of the calibration wafer 214 may be used to determine the distance δ₁ between the outer edge 104A of the wafer support area 102 and the outer edge 218 of the calibration wafer 214, and the distance δ_{A} between the outer edge 104A of the wafer support area 102 and the inner edge 408A of the edge ring 406. These fiducials include, for instance, the fiducial markers 222A and/or 223A which may provide size, scale, and/or orientation references, the visible outer edge 218 of the calibration wafer 214 itself, and/or one or more edges of the cutout 216A. In some embodiments, the gaps, and other features, may be measured with respect to and along a line (or axis) 341A-C in FIGS. 4B-G that is collinear with fiducial markers 223A-C, respectively. In this example, without the cutout 216A of the calibration wafer 214, this section 408A of the edge ring's inner edge 408 would not be visible and measurable, and it would not be possible to directly measure the gap between the wafer support area and the edge ring while a wafer is positioned on the wafer support area.

In FIG. 4C, the cutout 216B is shown along with the portion 102B of the wafer support area 102 and the section 104B of its outer edge 104, and the portion 406B of the edge ring 406 and the section 408B of its inner edge 408. Also visible are the gap 332B between calibration wafer 214 and the wafer support area section 104B, the distance δ₂ between the calibration wafer's 214 outer edge 218 and the section 104B of the portion 102B of the wafer support area 102, the gap 433B between the section 104B of the outer edge 104 of the portion 102B of the wafer support area 102 and the inner edge section 408B of the edge ring portion 406B, and the distance 8B between these two edges. In some implementations, such as this example, the edge ring and calibration wafer may be positioned such that some aspects of the edge ring are not visible within the cutout of the calibration wafer, but still within the field of view of the autocalibration wafer's imaging sensor. In some other implementations, the edge ring may be visible within all of the calibration wafer's cutouts.

Similarly, in FIG. 4D, the cutout 216C is shown along with the portion 102C of the wafer support area 102 and the section 104C of its outer edge 104, and the portion 406C of the edge ring 406 and the section 408C of its inner edge 408. Also visible are the gap 332C between calibration wafer 214 and the wafer support area section 104C, the distance δ₃ between the calibration wafer's 214 outer edge 218 and the section 104C of the portion 102C of the wafer support area 102, the gap 433C between the section 104C of the outer edge 104 of the portion 202C of the wafer support area 102 and the inner edge section 408C of the edge ring portion 206C, and the distance δ_{C} between these two edges.

The gaps 433A-C and distances δ_{A} to δ_{C}, in conjunction with the radius r_{wsa} of the wafer support area 102 and the angle along which each gap 433A-C may be used to determine the locations of three points along the outer edge 104 of the wafer support area 102. For example, for the gap 433A and distance δ_{A}, the distance δ_{A} may be added to the radius r_{wsa} to obtain a radial distance from the wafer support area origin/center to the inner edge 408 of the edge ring 406. An XY coordinate pair for the point where the gap terminates at the inner edge 408 of the edge ring 406 may be determined using trigonometric relations based on the angular position of the radius extending from the center of the wafer support area to the point where the gap terminates at the inner edge 408 of the edge ring 406. In this example, the angular position of this radius is 0 degrees. Thus, the XY coordinates for such a point may be determined according to:

$$X = ( {r}_{w s a} + {δ}_{x} ) \cdot sin ( θ )$$

$$Y = ( {r}_{w s a} + {δ}_{x} ) \cdot cos ( θ )$$

where δₓ is the relevant gap distance, r_{wsa} is the wafer support area radius, and θ=the angle between a radius extending from the wafer support area origin to the gap and polar axis extending from the origin. The same equations and relations described above may again be used to determine the XY coordinate pairs of the inner edge of the edge ring. Once three pairs of XY coordinates are known for locations along the inner edge of the edge ring, a determination may be made as to the location of the center of the edge ring relative to the coordinate system origin (the center of the wafer support area) using the following equations:

$${x}_{c} = \frac{( {y}_{2} - {y}_{3} ) ( {x}_{1}^{2} + {y}_{1}^{2} ) + ( {y}_{3} - {y}_{1} ) ( {x}_{2}^{2} + {y}_{2}^{2} ) + ( {y}_{1} - {y}_{2} ) ( {x}_{3}^{2} + {y}_{3}^{2} )}{2 \cdot [ {x}_{1} ( {y}_{2} - {y}_{3} ) - {y}_{1} ( {x}_{2} - {x}_{3} ) + {x}_{2} {y}_{3} - {x}_{3} {y}_{2} ]}$$

$${y}_{c} = \frac{( {x}_{3} - {x}_{2} ) ( {x}_{1}^{2} + {y}_{1}^{2} ) + ( {x}_{1} - {x}_{3} ) ( {x}_{2}^{2} + {y}_{2}^{2} ) + ( {x}_{2} - {x}_{1} ) ( {x}_{3}^{2} + {y}_{3}^{2} )}{2 \cdot [ {x}_{1} ( {y}_{2} - {y}_{3} ) - {y}_{1} ( {x}_{2} - {x}_{3} ) + {x}_{2} {y}_{3} - {x}_{3} {y}_{2} ]}$$

where (x₁, y₁), (x₂, y₂), and (x₃, y₃) are each coordinate pairs, and (x_{c}, y_{c}) is the coordinate pair of the center of the calibration wafer. After establishing the center offset between the wafer support area and the edge ring, appropriate actions may be taken to reduce the center offset between these two components. For example, in the present scenario, the edge ring could be retrieved by the wafer-handling robot and then moved by the reverse of the offset, in order to center the edge ring on the wafer support area. If the autocalibration wafer coordinate system is not aligned with the coordinate system used by the wafer-handling robot, the center-to-center offsets obtained using the autocalibration wafer may be transformed into equivalent offsets in the coordinate system used by the wafer-handling robot prior to using the wafer-handling robot to correct the placement of, for example, the edge ring. Once the calibration wafer is acceptably centered, the calibration wafer may then be used to train the AWC of the semiconductor processing tool. Various techniques involving the use of an autocalibration wafer for enhancing centering operations in a semiconductor processing tool are discussed in more detail further below.

Although the reference to the radius of the wafer support area was used in the above example, other reference features may be used and have similar results as long as each gap is referenced to the same equivalent feature. This may include, for example, a distance from a fiducial marker on the wafer support area that has a known distance. For instance, in the above example, 145 mm could be changed to 200 mm and the same eccentricity data should result, although the calculated X-Y points will be different than above.

In another example, similar to FIGS. 3E-3G and 4B-4D, a gap between the fiducial markers 222A-C on the calibration wafer 214 and a fiducial marker of the edge ring, such as its inner edge 408, may be used. FIGS. 4E-4G depict magnified views of the three areas in FIG. 4A; these dotted circles in FIG. 4A represent the field of view in FIGS. 4E-4G. These FIGS. 4E-4G are similar to FIGS. 4B-4D, except for noted differences herein. FIG. 4E, similar to FIG. 4B, depicts cutout 216A, the first portion 102A of the wafer support area 102, shown with shading, a section 104A of its outer edge 104, e.g., an arc, that are visible within the cutout 216A, as well as the first portion 406A of the edge ring 406, shown with dark shading, along with the section 408A of its inner edge 408, e.g., an arc that is visible within the cutout 216A.

In this example, the gap 347A and its distance δ₄ that is measured between the first intersection point 343A where the line 341A intersects the bottom edge 231A of fiducial marker 222A and the second intersection point 345A wherein the line 341A intersects the outer edge 104A is shown. Also shown is another gap 453A that exists between the fiducial marker 222A on the calibration wafer 214 and the inner edge 408A of the edge ring 406. This gap 453A is defined between the inner edge 408A and the bottom edge 231A of fiducial marker 222A along the line 341A that is collinear with the fiducial marker 223A, as illustrated. The gap 453A and its distance δ_{D} is measured between the first intersection point 343A where the line 341A intersects the bottom edge 231A of fiducial marker 222A and another intersection point 451A where the line 341A intersects the inner edge 408A.

Similarly, in FIG. 4F, cutout 216B is depicted with the gap 347B defined between the outer edge 104B and the bottom edge 231B of fiducial marker 222B along the line 341B that is collinear with the fiducial marker 223B. The gap 347B and its distance δ₅ is measured between the first intersection point 343B where the line 341B intersects the bottom edge 231B of fiducial marker 222B and the second intersection point 345B wherein the line 341B intersects the outer edge 104B. Also illustrated is a gap 453B that exists between the fiducial marker 222B on the calibration wafer 214 and the inner edge 408B of the edge ring 406. This gap 453B is defined between the inner edge 408B and the bottom edge 231B of fiducial marker 222B along the line 341B that is collinear with the fiducial marker 223B. The gap 453B and its distance δ_{E} is measured between the first intersection point 343B where the line 341B intersects the bottom edge 231B of fiducial marker 222B and another intersection point 451B where the line 341B intersects the inner edge 408B.

In FIG. 4G, cutout 216C is depicted with the gap 347C defined between the outer edge 104C and the bottom edge 231C of fiducial marker 222C along the line 341C that is collinear with the fiducial marker 223C. The gap 347C and its distance δ₆ is measured between the first intersection point 343C where the line 341C intersects the bottom edge 231C of fiducial marker 222C and the second intersection point 345C wherein the line 341C intersects the outer edge 104C. Gap 453C is also shown which exists between the fiducial marker 222C on the calibration wafer 214 and the inner edge 408C of the edge ring 406. This gap 453C is defined between the inner edge 408C and the bottom edge 231C of fiducial marker 222C along the line 341C that is collinear with the fiducial marker 223C. The gap 453C and its distance δ_{F} is measured between the first intersection point 343C where the line 341C intersects the bottom edge 231C of fiducial marker 222C and another intersection point 451C where the line 341C intersects the inner edge 408C. By measuring these gaps along the direction of fiducial markers 223A-C, the gap values are able to converge on the same coordinate system.

These gaps 453A-C and distances δ_{D} to δ_{F} may be used with the techniques provided herein to determine the location of the center of the calibration wafer relative to the coordinate system origin, e.g., the center of the wafer support area. For example, similar to above, these gaps 453A-C and distances δ_{D} to δ_{F} may be used in conjunction with the radius r_{wsa} of the wafer support area 102, or other reference feature, and the angle along which each gap 453A-C is measured may be used to determine the locations of three points along the outer edge 104 of the wafer support area 102. For example, for the gap 453A and distance δ_{D}, the distance δ_{D} may be added to the radius r_{wsa} to obtain a radial distance from the wafer support area origin/center to a point, e.g., the second intersection point 451A, of the edge ring 406. An XY coordinate pair for the point where the gap terminates at the inner edge 408 of the edge ring 406 may be determined using trigonometric relations based on the angular position of the radius extending from the center of the wafer support area to the point where the gap terminates at the inner edge 408 of the edge ring 406 as described above. Once the XY coordinates are determined, then the location of the center of the edge ring relative to the coordinate system origin may be determined as provided herein.

In some embodiments, additionally or alternatively, the gaps 347A-C between the wafer support area 102 and the calibration wafer 214 of FIGS. 4E-4G may be used and the gaps 433A-C between the wafer support area and the edge ring 406 of FIGS. 4B-D may be used for the determinations and techniques made herein.

As provided above, by using a calibration wafer with a plurality of cutouts, the center-to-center offsets between the calibration wafer and the wafer support area, and between the edge ring and the wafer support area can be determined using concurrently obtained images of the wafer support area edge, calibration wafer and/or edge ring. The cutouts enable the autocalibration wafer's imaging sensors to concurrently view the calibration wafer and components underneath it, including the wafer support area, the edge ring placed on the wafer support, and one or more fiducials of these components. This advantageously allows for direct measurements of the two moveable structures, the calibration wafer and the edge ring, with respect to the fixed wafer support and for concurrent, instead of sequential, measurements of these movable structures with respect to the wafer support. This provides for more accurate, precise, efficient, and expedient measurements.

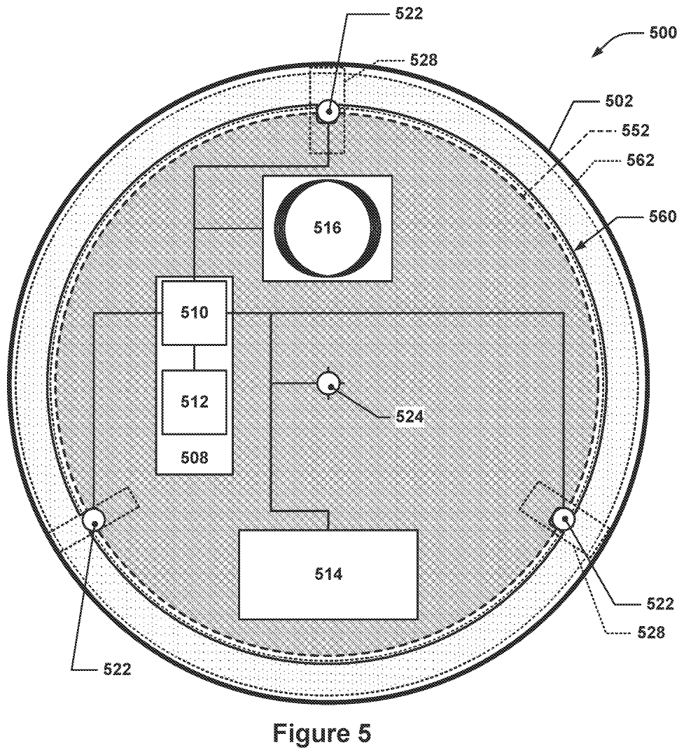

While the above discussion has focused largely on calibration wafers, features of the autocalibration wafer will now be discussed. FIG. 5 depicts a schematic of an example autocalibration wafer with broken lines/shaded regions showing a wafer support, edge ring, and calibration wafer positioned there beneath. In FIG. 5, an autocalibration wafer 500 is shown that includes a substrate 502 to which a plurality of different sensors and other electrical components are mounted. Also shown in FIG. 5, although not part of the autocalibration wafer 500, are a calibration wafer 560 as described above and shown in FIG. 2A (the calibration wafer 560 may be the same as calibration wafer 214; the cutouts are not visible in FIG. 5 because they are under and therefore covered by the imaging sensors 522), an annular edge ring 562, and a wafer support 552 (which may be the same as the wafer support area 102 described above); these additional components are shown arranged concentrically with the autocalibration wafer 500, as would be the case during some stages of normal use if the calibration wafer 560, the edge ring 562, the wafer support 552, and the autocalibration wafer 500 are all centered with respect to one another. In the depicted example, the autocalibration wafer 500 is shown as being larger in diameter than the wafer support 552, the edge ring 562, and the calibration wafer 560—in actual practice, the autocalibration wafer 500 may be similar in size to the calibration wafer 560. As noted earlier, the wafer support 552 may include multiple components, e.g., an wafer support that may be slightly smaller in diameter than the calibration wafer 560, as well as a support structure that extends beyond the wafer support and supports the edge ring 562. For simplicity, such separate structures are not shown in FIG. 5. Further, FIG. 5 is shown at a smaller scale than the other Figures, such as FIGS. 1A to 3D.

The sensors shown as being part of the example autocalibration wafer of FIG. 5 may include, for example, a plurality of first imaging sensors 522, which may, for example, be CCDs or CMOS devices. The first imaging sensors 522 may be configured with optics or other focusing systems and arranged to provide a downward-looking field of view. As shown in FIG. 5 (similar to FIGS. 2A and 3A), the fields of view 528 of the first imaging sensors 522 are shown as being elongated rectangular areas that span across the outer edge of the calibration wafer 560, including across and over the calibration wafer's cutouts as illustrated in FIGS. 2A and 3A, although they are not visible in FIG. 5, the inner and outer edges of the edge ring 562, and the outer edge of the wafer support 552 when the autocalibration wafer 500 is positioned at a predefined height or range of heights above the calibration wafer 560, edge ring 562, and wafer support 552 (for example, at the height that the end effector of a wafer-handling robot would normally be at when delivering wafers to the wafer support 552).

The field of view 528 of each first imaging sensor 522 may be any of a variety of shapes, e.g., circular or elliptical, as well, and may also extend radially outward to a lesser degree than shown. For example, in some implementations, the fields of view 528 of the first imaging sensors 522 may only extend out far enough to capture the inner edge of the edge ring 562 but not the outer edge of the edge ring 562. By positioning the first imaging sensors 522 such that the first imaging sensors 522 are located generally directly over the outer edge of the calibration wafer 560 and the inner edge of the edge ring 562, if used, and over the cutouts 216A-C of the calibration wafer 560 (although not visible in FIG. 2A), the first imaging sensors 522 may be positioned to obtain image data that may more accurately reflect the size of any gaps that may exist between various fiducials in the images, such as the edges of such components. In particular, such imaging sensor placement may reduce the effect that height mismatches may have on gap size determination, leading to more accurate gap size estimation. For example, if an imaging sensor obtains image data of a gap along a line of sight that is at a very shallow angle with reference to the autocalibration wafer, e.g., as may be the case with an imaging sensor that is mounted near the center of the autocalibration wafer, then any slight variance in height in either the edge ring or the calibration wafer may be magnified and cause the gap size to fluctuate in an unpredictable manner. Locating the imaging sensors near the periphery of the autocalibration wafer may act to significantly reduce the impact such effects may have.

In addition to the first imaging sensors 522, the autocalibration wafer 500 may, in some instances, include further imaging sensors, such as centrally-located, downward-facing second imaging sensor 524, which may be configured to obtain images directly below the center of the autocalibration wafer. Such an imaging sensor may be used in calibration routines in which the fiducial to be imaged is located near where the center of a semiconductor wafer is typically placed, e.g., a wafer support for receiving a wafer may have cross-hair fiducial marks located at the center of the wafer support that may be imaged by the second imaging sensor in order to assist in locating the center of the wafer support relative to the autocalibration wafer. For example, the wafer support may have a fiducial in the middle that may be imaged by the second imaging sensor 524 when the autocalibration wafer 500 is positioned over the wafer support by an end effector of a wafer-handling robot in order to facilitate teaching the wafer-handling robot the location of the wafer support. Such a sensor may also be used to center the autocalibration wafer on the end effector of the wafer-handling robot as well.

For example, the end effector of a wafer-handling robot may include a fiducial that is generally positioned in a location that is observable by the second imaging sensor 524 when the autocalibration wafer 500 is generally centered over the end effector. When the wafer-handling robot is actuated to retrieve the autocalibration wafer, the end effector may be moved underneath the autocalibration wafer such that the fiducial is within the field of view of the second imaging sensor 524. The second imaging sensor 524 may then be caused to obtain images of the fiducial, which may be analyzed to determine how far off-center the fiducial is with respect to the center of the autocalibration wafer 500. The wafer-handling robot may then be caused to reposition the end effector such that the off-centeredness of the fiducial with respect to the autocalibration wafer 500 is reduced to an acceptable limit.

It will be understood that other implementations of the autocalibration wafer 500 discussed herein may use sensors other than imaging sensors to obtain radial gap data and/or centeredness data. For example, ultrasonic sensors may be used to obtain a contour map that may show three-dimensional fiducials and the above-referenced distances and gaps may be determined from those contour maps in a manner similar to how such distances and gaps may be determined from imaging data. It will thus be understood that any sensor that is able to be used to evaluate the gaps between fiducials discussed above and/or the centeredness of the autocalibration wafer 500 relative to the wafer support may be used in place of the above-discussed imaging sensors. These sensors may be configured to obtain such data through the cutouts of the calibration wafer in order to simultaneously obtain data of the calibration wafer, the wafer support area, and the edge ring, if used.

The various sensors included in an autocalibration wafer may be communicatively connected with a first controller 508 that may include one or more first processors 510 and one or more first memories 512. The first controller 508 may also be electrically connected with a power source 514, e.g., a battery, capattery, or other power source. In some implementations, the power source 514 may be operatively connected with a charging feature, e.g., with electrical contact pins that are placed in a location that aligns with charging features located at, for example, a docking station used to store the autocalibration wafer 500 when the autocalibration wafer 500 is placed into the docking station. In the implementation shown in FIG. 5, a wireless charging feature 516 is shown, which may, for example, be an inductive charging coil, such as a Qi-compatible inductive charging coil or other suitable wireless charging interface. In such cases, a docking station used to store the autocalibration wafer 500 may have a similar wireless charging interface configured to charge the autocalibration wafer 500 when the autocalibration wafer 500 is placed therein.

The first controller 508 may also be communicatively connected with a first wireless communications interface, e.g., a WiFi, Bluetooth, or other wireless communications interface, so that commands and/or data may be sent from or receive by the first controller 508, and thus the autocalibration wafer 500. For example, a semiconductor processing tool that interfaces with the autocalibration wafer 500 may include a second controller having one or more second processors and one or more second memories. The second controller may be communicatively connected with a second wireless communications interface that may, in turn, be configured to interface with the first wireless communications interface of the autocalibration wafer. Thus, the autocalibration wafer 500 may be able to wirelessly communicate with the semiconductor processing tool, allowing information, commands, and other data to be transmitted between the autocalibration wafer 500 and the semiconductor processing tool.

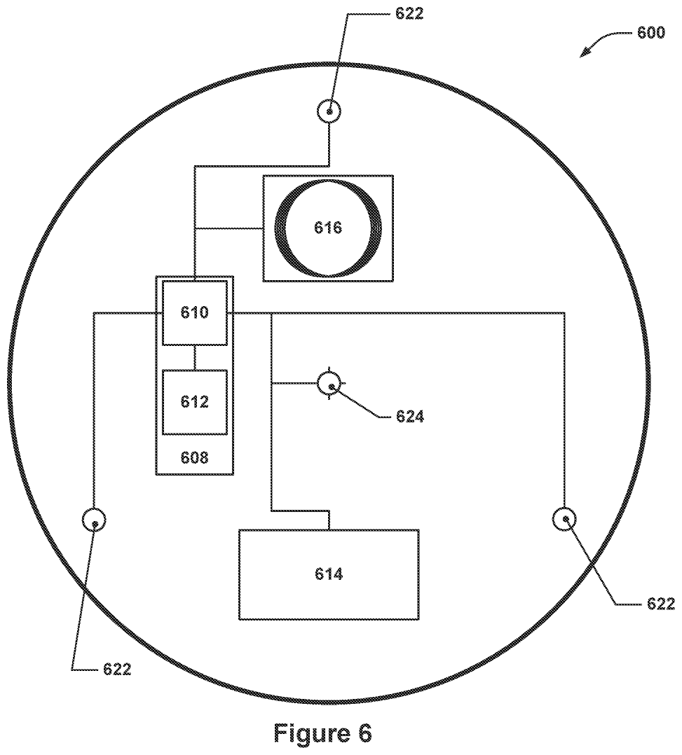

FIG. 6 is another illustration of an example autocalibration wafer. The autocalibration wafer 600 includes a substrate 602 that has printed circuit traces that provide electrical connectivity between a variety of components, including power sources 614, which are rechargeable batteries in this example, a processor 610, a memory device 612, and wireless charging feature 616, which may be used to inductively transfer power to the rechargeable batteries during wireless charging. Also visible in FIG. 6 are three first imaging sensors 622 mounted at equidistantly spaced locations around the perimeter of the substrate 602, as well as a centrally mounted second imaging sensor 624.

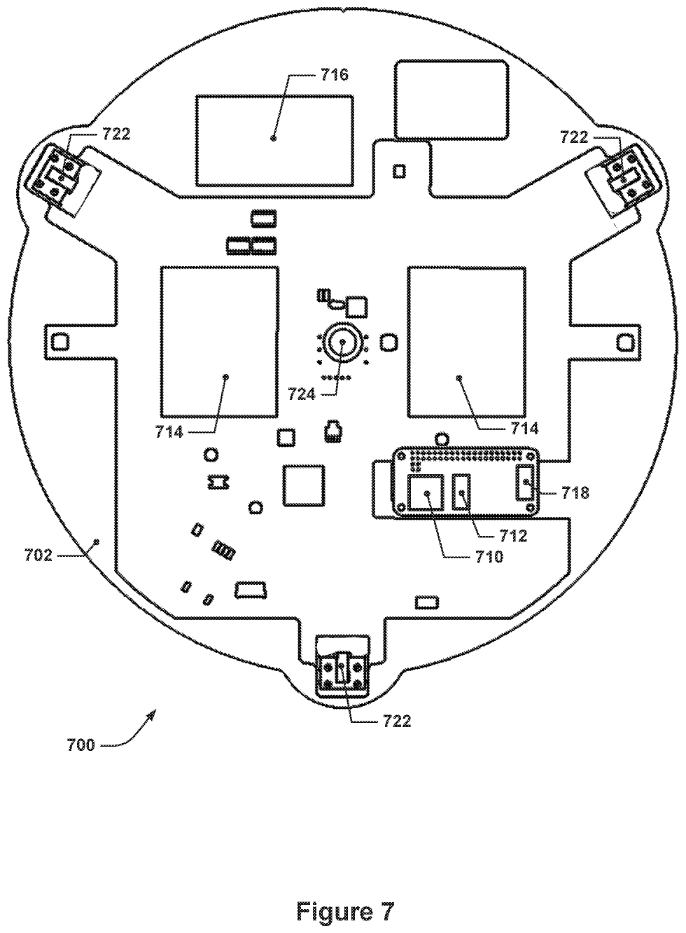

FIG. 7 depicts a line drawing plan view of another example autocalibration wafer 700. The autocalibration wafer 700, in this example, has a generally circular substrate 702 that has three lobes spaced around the outer circumference, each lobe housing a corresponding first imaging sensor 722. In this example, the substrate 702 generally has a diameter that is the same as a typical semiconductor wafer; the lobes extend beyond this diameter and allow the first imaging sensors 722 to be positioned such that the photosensitive areas of the first imaging sensors 722 may be centered, for example, over the outer edge of a semiconductor wafer placed beneath, and centered under, the autocalibration wafer 700. The autocalibration wafer 700 in this example also includes two power sources 714, e.g., rechargeable batteries, that may be charged using a wireless charging feature 716, e.g., an inductive charging coil. The batteries may provide power to various electrical components of the autocalibration wafer 700, such as processor 710, memory 712, wireless communications interface 718, the first imaging sensors 722, and the second imaging sensor 724.

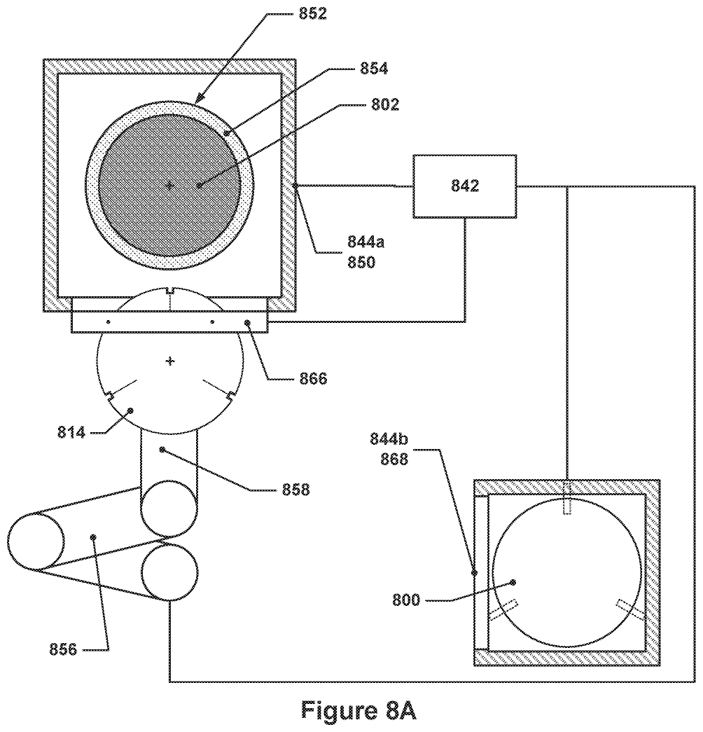

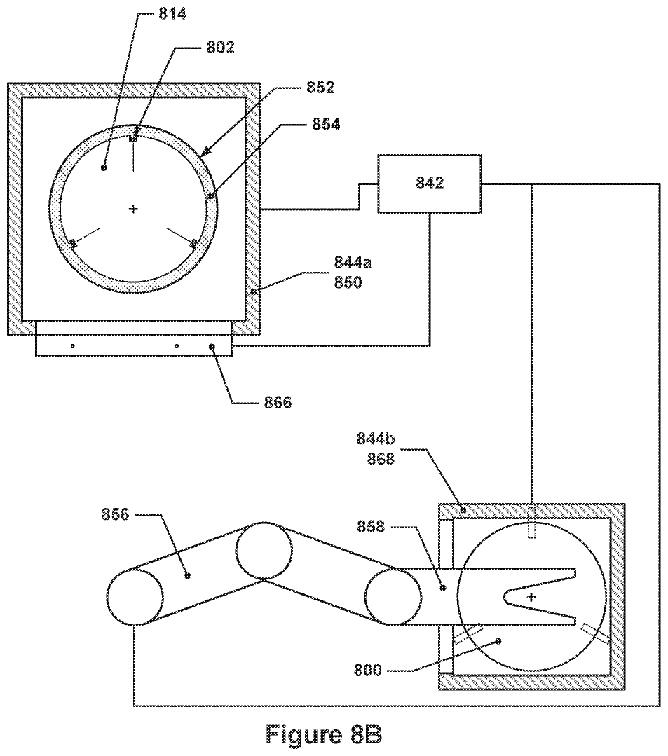

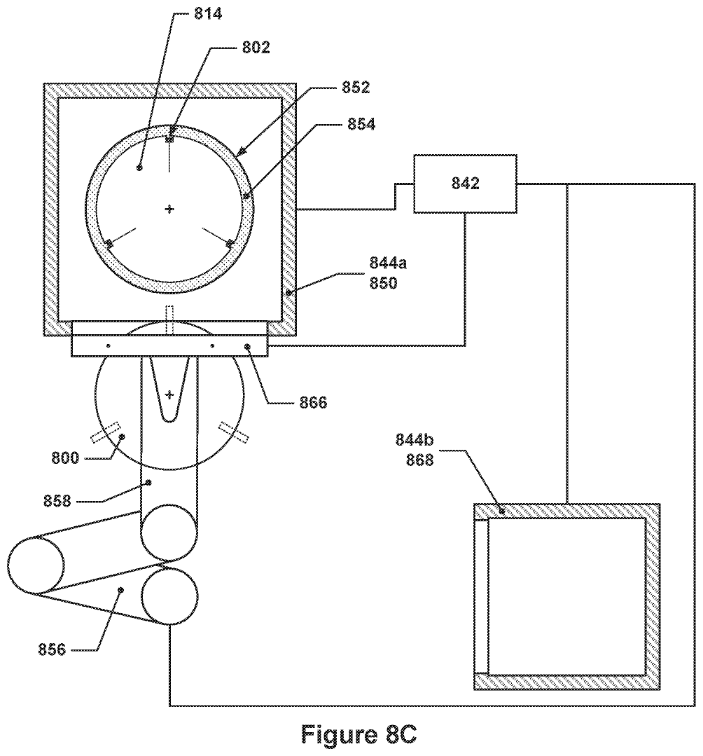

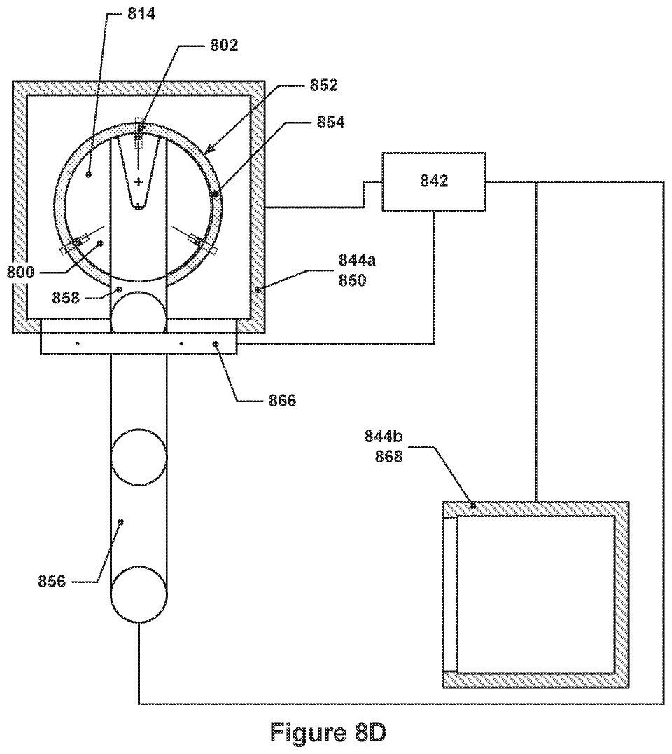

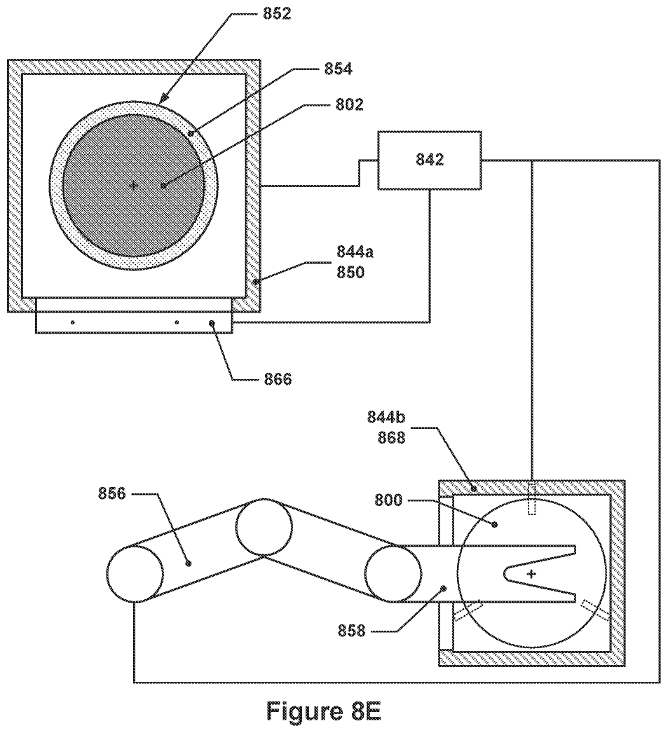

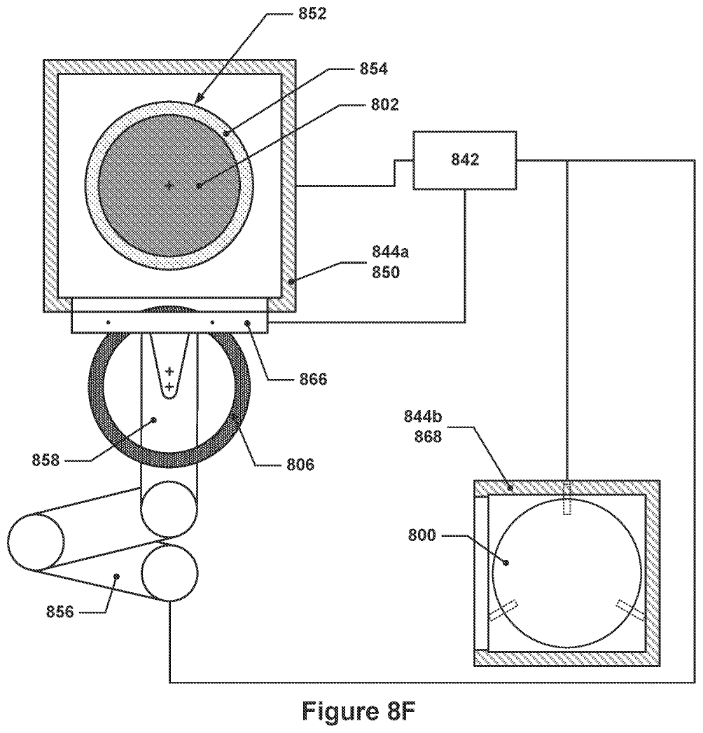

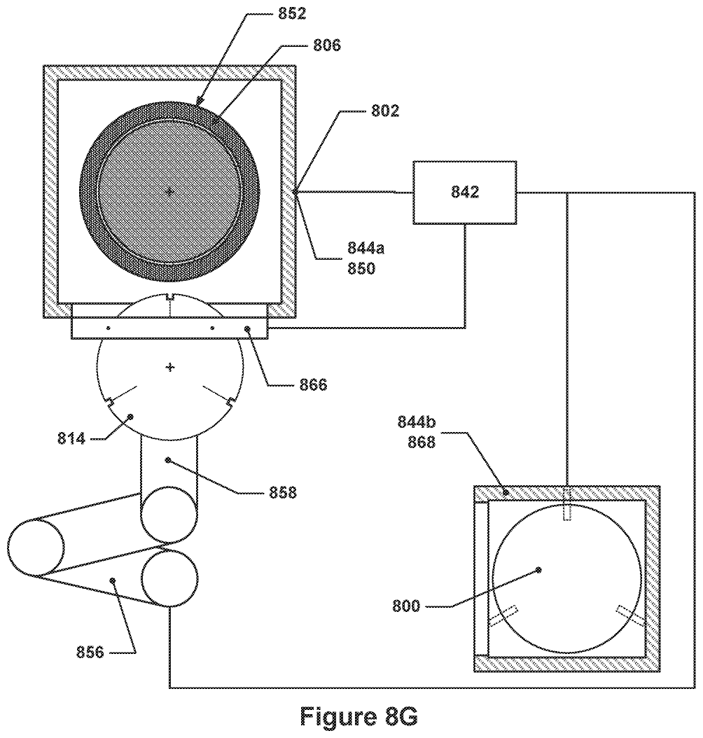

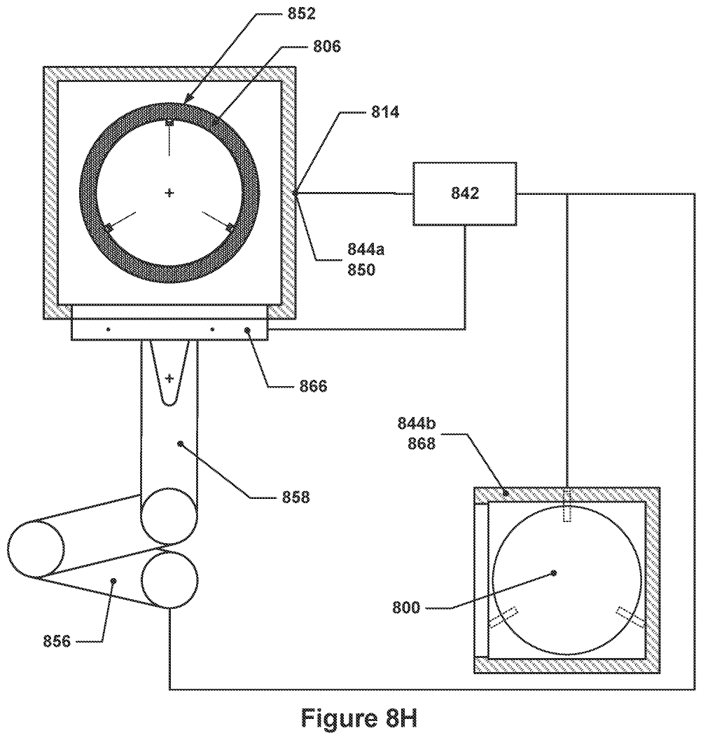

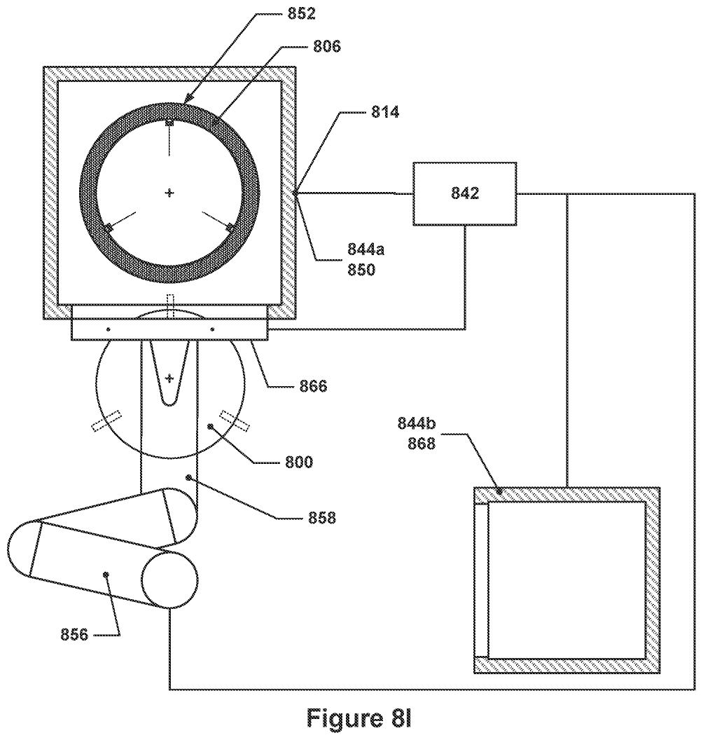

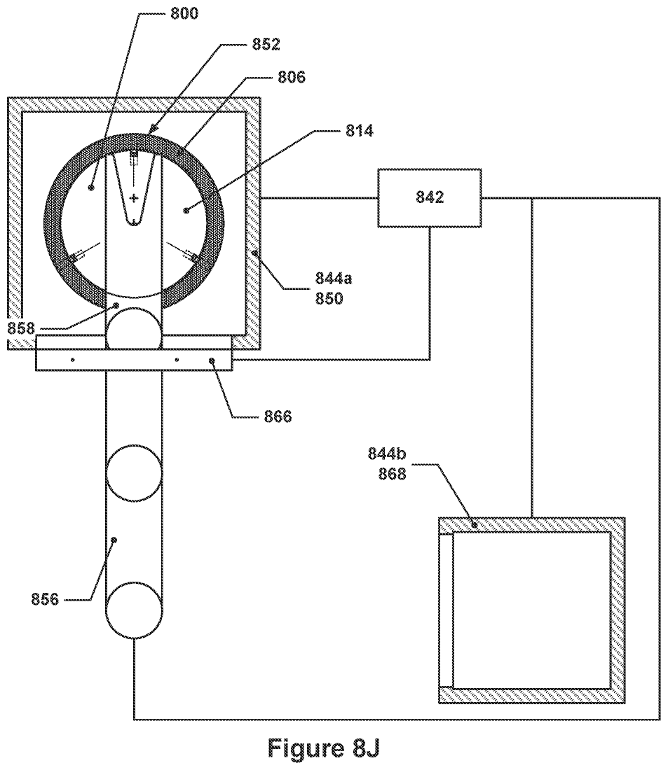

FIGS. 8A through 8J depict a schematic of a semiconductor processing tool during various stages of using an autocalibration wafer and calibration wafer with a plurality cutouts as described herein. In FIG. 8A, a portion of a semiconductor processing tool is shown. The depicted portion of the semiconductor processing tool includes two wafer stations 844a and 844b, although the tool may include further wafer stations as well. Each wafer station corresponds with a location in which one or more wafers may be placed during various operations performed by the semiconductor processing tool. Wafer stations may, for example and without limitation, exist within a process chamber or process chambers of the tool, in buffers used to store wafers before or after processing, in airlocks or loadlocks that allow wafers to be transferred between environments at different pressures, load ports, front-opening unified pods (FOUPs) that may be docked to a load port, etc.

In FIG. 8A, the wafer station 844a is provided by a semiconductor processing chamber 850; in contrast, the wafer station 844b is provided by a docking station 868 that is dedicated for storage of an autocalibration wafer 800 and/or calibration wafer 814 which is shown on an end effector 858 of a wafer-handling robot 856 (although such a dedicated docking station may not be included in some implementations). The docking station 868 may have features (not shown) for charging the autocalibration wafer 800 or otherwise be configured to interface with various aspects of the autocalibration wafer 800. In some implementations, the docking station, may be located in a vacuum transfer module (VTM) (or be attached thereto) to allow it to be accessed by a wafer-handling robot in the vacuum transfer module, which may then be trained using the autocalibration wafer. In other implementations, the docking station may be located in an equipment front-end module (EFEM) or other atmospheric or near-atmospheric pressure location, in which case the autocalibration wafer may first be retrieved using a wafer-handling robot located in the EFEM and then transferred to another wafer-handling robot located in a VTM.

Each wafer station 844 may have an associated wafer support 852 that has the wafer support area 802 described above. Here, the wafer support area 802 is highlighted with dark shading while an annular surface 854 of the wafer support 852 that extends around the wafer support area 802 is seen with light shading. The annular surface 854 may be configured to receive and support an edge ring as described herein. Although shown as an annular surface for simplicity, the wafer support 852 may be configured with other features or surfaces that receive and support the edge ring. In some instances, a wafer station may be associated with an active wafer centering (AWC) system 866, which may allow measurements of wafer center locations to be obtained as wafers are introduced to, or removed from, an associated wafer station 844. In this example, the AWC system 866 is associated with the wafer station 844a and includes two vertically oriented optical beam sensors (represented by the dots within the AWC system 866) that may detect when an edge of a wafer crosses through either optical beam. As discussed earlier, in some instances the AWC system 866 may be used to determine the center location of a wafer supported by an end effector 858 of the wafer-handling robot 856 of the tool relative to a particular, known frame of reference, thereby allowing a determination to be made as to any positioning corrections that may need to be made before placing the wafer at a desired location.

As also shown in FIG. 8A, the wafer-handling robot 856 is supporting the calibration wafer 814 described herein on the end effector 858 in preparation for placing the calibration wafer 814 on the wafer support area 802 of the wafer support 852. The autocalibration wafer 800, in the interim, is in temporary storage in the wafer station 844b/docking station 868.

In FIG. 8B, the wafer-handling robot 856 has been actuated to place the calibration wafer 814 in a location that is nominally centered on the wafer support area 802 and has been further actuated to retrieve the autocalibration wafer 800 from the wafer station 844b/docking station 868. As illustrated in FIGS. 3A through 3D, in FIG. 8B, features underneath the calibration wafer 814 are visible, including the outer edge of the wafer support area 802 and the annular surface 854 of the wafer support 852. For illustration purposes, the autocalibration wafer 800 is transparent in order to show features underneath it.

In FIG. 8C, the wafer-handling robot 856 has retrieved the autocalibration wafer 800 from the wafer station 844b/docking station 868 and is preparing to position the autocalibration wafer 800 over the wafer support area 802 of the pedestal/wafer support 852 and the calibration wafer 814.

In FIG. 8D, the wafer-handling robot 856 has extended the end effector 858 so as to position the autocalibration wafer 800 over the calibration wafer 814, the wafer support area 802, and the annular surface 854 of the wafer support 852. The autocalibration wafer 800 is thus positioned such that the fields of view of downward-facing first imaging sensors of the autocalibration wafer 800, which are indicated by the three dotted rectangles spaced along the outer edge of the autocalibration wafer 800, are over the calibration wafer 814 and the wafer support area 802, including the portion of the cutouts of the calibration wafer 814 and one or more features or fiducials of the wafer support area 802. For example, this includes positioning the autocalibration wafer 800 as illustrated in FIG. 3A through 3D such that the field of view of the first imaging sensors of the autocalibration wafer 800 includes the fiducial markers 222A-C and 223A-C and the outer edge 218 of the calibration wafer 814, as well as one or more fiducials of the wafer support area 102, such as its outer edge 104, that are underneath the calibration wafer and visible through the calibration wafer's cutouts.

A first controller of the autocalibration wafer 800 may then be caused by the second controller 842 to obtain image data from the first imaging sensors of, for example, the fiducial markers 222 and 223 and the outer edge 218 of the calibration wafer 814, as well as one or more fiducials of the wafer support area 102, such as its outer edge 104, and gaps and spaces between such features, including gaps 332A-C of FIGS. 3B-3D between the outer edge of the wafer support area and calibration wafer. As discussed earlier, these gaps may be used to determine the amount by which the center of the calibration wafer 814 is offset with respect to the center of the wafer support area 802. In some implementations, as also discussed above, gaps between a fiducial marker on the calibration wafer, such as the edge of its cutout and/or a fiducial marker 222 adjacent to the cutout, and a fiducial marker on the wafer support, may be used for the center-to-center determinations. If this offset exceeds a permissible threshold, then the calibration wafer may be repositioned to reduce the offset. In this example, the calibration wafer 814 has been acceptably placed, and the wafer-handling robot 856 may, as shown in FIG. 8E, remove the autocalibration wafer 800 and the calibration wafer 814 from the wafer station 844a and return them to the wafer station 844b (only the autocalibration wafer 800 is shown in this Figure for clarity; both the autocalibration wafer 800 and the calibration wafer 814 may be stored in the wafer station 844b).

In FIG. 8F, the wafer-handling robot 856 has retrieved and is supporting an edge ring 806 on the end effector 858 in preparation for placing the edge ring 806 on the annular surface 854 of the wafer support 852. The autocalibration wafer 800 and the calibration wafer 814, in the interim, are in temporary storage in the wafer station 844b/docking station 868.

In FIG. 8G, the wafer-handling robot has been actuated to retrieve the calibration wafer 814 from the docking station 868, e.g., from underneath or above the autocalibration wafer 800, or may be obtained from a different location entirely, e.g., from a loadlock or airlock. As described above, including in FIGS. 8A and 8B, the calibration wafer 814 may then be placed in the wafer station 844a/semiconductor processing station 850 and transferred to the wafer support area 802 of the wafer support 852 such that it is nominally centered with respect to the wafer support area, as shown in FIG. 8H. This positioning of both the edge ring and the calibration wafer positioned onto the wafer support 852 may be the same as provided above with respect to FIGS. 4A-D. For example, the outer edge of the wafer support area and the inner edge of the edge ring may be visible within each cutout of the calibration wafer. These cutouts of the calibration wafer 814 enable visibility of the wafer support and edge ring features underneath the calibration wafer which enables the concurrent imaging and measurement of the calibration wafer with respect to the wafer support and the edge ring with respect to the wafer support area thereby allowing simultaneous determinations of the centers of these structures.

In FIG. 8I, the wafer-handling robot has again been actuated to retrieve the autocalibration wafer 800 from the wafer station 844b/docking station 868. In FIG. 8J, the wafer-handling robot has been further actuated to position the autocalibration wafer 800 over the wafer support 852, the calibration wafer 814, and the edge ring 806. Similar to FIG. 8D, the autocalibration wafer 800 may then be controlled to simultaneously obtain image data of the gaps between the edge ring 806 and the wafer support area 802, and between the calibration wafer 814 and the wafer support area 802, such as gaps 332A-C and 433A-C in FIGS. 4B-D, respectively, thereby allowing a determination to be made as to any offset between the center of the calibration wafer 814 and the wafer support area 802, and between the center of the edge ring 806 and the wafer support area 802.

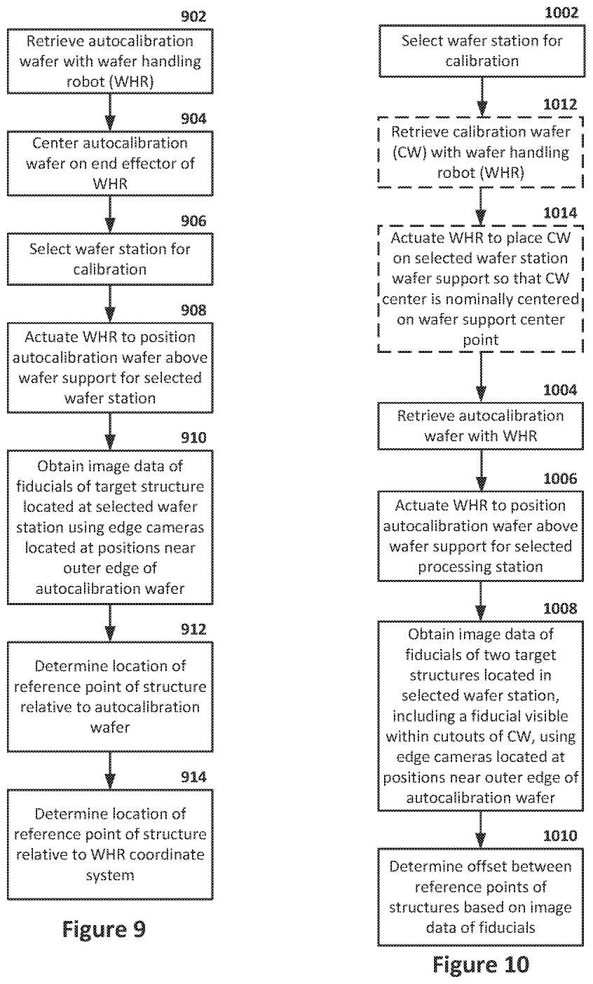

Various techniques that may be practiced with an autocalibration wafer and calibration wafer such as those discussed above are explored in more detail below with reference to FIGS. 9 through 14. As provided herein, these techniques of FIGS. 9-14 are enabled, at least in part, by the use of the calibration wafer with cutouts that allow for the simultaneous imaging of the calibration wafer and its fiducials, the wafer support's fiducials, e.g., the outer edge of the wafer support area, and the edge ring's fiducials, e.g., the inner edge of the edge ring. This concurrent imaging further allows the simultaneous and direct determinations of the relative offset of the calibration wafer with respect to the wafer support, and the relative offset of the edge ring with respect to the wafer support. These simultaneous imaging and determinations may advantageously be made without the use of intermediary or “proxy” fiducials and without removing the calibration wafer to view the structures underneath it.

FIG. 9 depicts a flow chart of a technique for determining the location of a reference point of a structure at a wafer station using an autocalibration wafer. Such a technique may be used, for example, in teaching a wafer-handling robot the various locations at which wafers may be placed (or retrieved from). In block 902, an autocalibration wafer may be retrieved using an end effector of a wafer-handling robot; in block 904, the autocalibration wafer may be centered on the end effector of the wafer-handling robot (blocks 902 and 904 may be performed simultaneously in some implementations). For example, the autocalibration wafer may be caused to be placed on the end effector such that the center of the autocalibration wafer (or some other known reference point on the autocalibration wafer) is centered on a known reference point of the end effector, thereby establishing a spatial relationship between the two reference points and allowing measurements that are obtained using the autocalibration wafer to be mapped or transformed into the coordinate system used by the wafer-handling robot.

Such placement of the autocalibration wafer on the end effector may be accomplished through any suitable mechanism, including through the use of a physical indexing feature or other contact-based approach for ensuring that the autocalibration wafer is properly positioned on the end effector. However, the imaging features of the autocalibration wafer itself may alternatively be used, in some instances, to ensure proper autocalibration wafer centering on the end effector. For example, just prior to loading of the autocalibration wafer onto the end effector, the autocalibration wafer may be positioned above the end effector, and one or more of the imaging sensors of the autocalibration wafer may be activated to cause an image of the end effector, or a region thereof, to be obtained. The imaged portion of the end effector may, for example, include a fiducial that defines a reference point on the end effector, e.g., a location on the end effector that coincides with the XY center point of a theoretical semiconductor wafer that is perfectly placed on the end effector. This image data may then be analyzed to determine the degree to which the reference point of the autocalibration wafer, e.g., the center of the autocalibration wafer, is offset from the reference point/fiducial of the end effector. The wafer-handling robot can then be actuated to cause the end effector to move in a manner that reduces or cancels out this offset before the autocalibration wafer is placed on the end effector, thereby centering the autocalibration wafer on the end effector.

In block 906, a wafer station may be selected for calibration, e.g., determination of a reference point on a structure, e.g., a wafer support, of the wafer station where the centers of wafers delivered to the wafer station are intended to be located. In block 908, the wafer-handling robot may be actuated to cause the end effector and autocalibration wafer to be positioned above the selected wafer station such that the autocalibration wafer is generally centered, for example, over the reference point of the wafer support for the selected wafer station. Such initial positioning may be based on, for example, an estimate of the wafer support reference point location determined based on the as-designed locations of the various components in the system, which may generally allow for placement accuracy within a millimeter or a few millimeters in most cases.

In block 910, the autocalibration wafer may be caused to obtain image data of a fiducial or fiducials on a target structure located at the selected wafer station; the fiducial or fiducials may be associated with the reference point of the wafer station where, for example, the centers of wafers delivered to the wafer station are intended to be located. For example, the outer edge of an ESC of a wafer support area at the selected wafer station may serve as the fiducial; such a fiducial may not directly indicate the reference point of the wafer station, but may nonetheless unambiguously define it, e.g., a circular or arcuate edge of an ESC may define a center point that serves as the reference point. In another example, a wafer support may include some type of fiducial, e.g., an etched “+” or other marking, that directly marks the reference point, e.g., the center of the wafer support may be the reference point and the intersection of the two lines in the “+” may indicate the reference point. In such an example, an imaging camera at the center of the autocalibration wafer, such as imaging sensor 524 described above, may be used to capture the fiducial at the center of the wafer support.

In block 912, the location of the reference point of the structure, e.g., wafer support, of the selected wafer station relative to the autocalibration wafer may be determined based on the image data of the fiducials. For example, the image data may indicate that the reference point of the structure has an XY offset from a reference point of the autocalibration wafer, e.g., the center of the autocalibration wafer, of (0.3 mm, 0.5 mm) in the coordinate system of the autocalibration wafer.

In block 914, the location of the reference point of the structure may then be determined relative to the wafer-handling robot coordinate system. For example, the XY offsets determined in block 912 relative to the autocalibration wafer coordinate system may be subjected to a coordinate system transform in order to translate them into equivalent coordinates in the coordinate system of the wafer-handling robot, e.g., to account for possible angular misalignment between the autocalibration wafer coordinate system and the wafer-handling robot coordinate system.

If the calibration technique of FIG. 9 is used, it may be desirable in some instances to calibrate the autocalibration wafer prior to implementing the technique. For example, it may be desirable to establish the positions of the imaging sensor or sensors used to obtain the image data relative to a reference point, e.g., the center point, of the autocalibration wafer, so that locational information determined from such sensors can be appropriately processed. Each imaging sensor may, for example, be thought of as providing XY location data (based on the rectangular or linear array of pixels each such sensor may have) in a coordinate system that is specific to each imaging sensor and is offset from the reference point of the autocalibration wafer by a particular XY distance and/or rotational angle. Calibrating the autocalibration wafer allows for such XY and angular offsets to be determined for the coordinate system each imaging sensor. Any locations that are then later determined from the imaging sensor data may then be suitably transformed so as to be accurately located with respect to the coordinate system of the reference point of the autocalibration wafer.

In an example of such a calibration, the autocalibration wafer may be placed in a fixture that has indexing pins or other alignment features that contact the outer edge of the autocalibration wafer and physically constrain the autocalibration wafer to be centered over a fiducial that is part of the fixture and that is known to be centered with respect to the constrained outer edge of the autocalibration wafer. Once the autocalibration wafer is mounted in the fixture and centered over the fiducial, a centrally mounted imaging sensor may be caused to obtain an image of the fiducial, and a determination may then be made, for example, as to which pixel or pixels coincide with the center point indicated by the fiducial, thereby providing information that may later be used to transform any locational data obtained from images of the centrally mounted imaging sensor into a coordinate system associated with the reference point. Similar fiducials may be provided in the fixture at locations that coincide with the fields of view of other imaging sensors as well, allowing for the calibration of all of the imaging sensors prior to use.

FIG. 10 depicts a flow chart of a technique for determining the relative positioning of two structures at a wafer station using an autocalibration wafer. The technique of FIG. 10 begins in block 1002, in which a wafer station of the semiconductor processing tool may be selected for calibration. The structures for which relative positioning is to be determined are assumed to already have been located at the selected wafer station, e.g., the selected wafer station may have, for example, a calibration wafer (a first structure) that is placed on a wafer support (a second structure). In some instances, the technique of FIG. 10 may therefore include blocks 1012 and 1014 that are performed after block 1002 and before block 1004, in which the calibration wafer is positioned on the wafer support. In some implementations, the calibration wafer may be positioned nominally on the center of the wafer support and such positioning may be based on the data gathered from the technique of FIG. 9. In block 1012, the calibration wafer, such as the calibration wafer with the plurality of cutouts described herein, is retrieved by the wafer handling robot and then positioned on the wafer support in block 1014. In block 1004, an autocalibration wafer is retrieved using a wafer-handling robot of a semiconductor processing tool, e.g., from a docking station or other holding area used to store the autocalibration wafer.

In block 1006, the wafer-handling robot may be actuated to position the autocalibration wafer above the wafer support of the selected wafer station. The wafer-handling robot may, for example, be positioned so that the autocalibration wafer is nominally centered above the wafer support/calibration wafer of the selected wafer station, thereby causing first imaging sensors positioned along the outer perimeter of the autocalibration wafer to be positioned over the calibration wafer and wafer support in a manner that allows the first imaging sensors to obtain images of fiducials of the two structures, e.g., the outer edge of the calibration wafer and/or other fiducial marking(s) on the calibration wafer such as fiducial markers 222A-C and/or 223A-C in FIGS. 3A-4G, and the edge of a feature of the wafer support, e.g., the outer edge of the wafer support area, that is visible within the cutouts of the calibration wafer. This may include positioning the autocalibration wafer and calibration wafer with respect to the wafer support area described above and as shown in FIGS. 3A-D.

In block 1008, the autocalibration wafer may be caused to obtain such images. In block 1010, the images may be analyzed to determine, for example, gap sizes between the fiducials in each image. For example, edge-finding algorithms may be used to identify the outer edge of the calibration wafer and the edge of the wafer support area in each image, e.g., items 218 and 104A-C illustrated in FIGS. 3B-D, respectively, and the relative distances for the gap in between each pair of edges determined. The determined gaps between each pair of fiducials, such as edges, may be estimated based on the assumed vertical distance between the first imaging sensors and the imaged structures; such estimates may be somewhat inaccurate, but will generally be similarly scaled in each image. The fiducial markings or markers provided herein may provide, for instance, a sense of scale, orientation, direction, or a combination thereof for analyzing the gaps in the images. The fiducials of the calibration wafer may include the fiducial markers described above, such as fiducial markers 222A-C and 223A-C in FIGS. 2A-3D, the outer edge 218 of the calibration wafer, or the one or more edges that at least partially define each of the cutouts 216A-C. With the first target structure being the calibration wafer with cutouts, the fiducials of the second target structure may include the fiducials of the wafer support area, e.g., the outer edge 104 of the wafer support area 102.

For example, where the fiducials for each structure are located along a common reference circle, e.g., arcuate outer edges or edges of the plurality of cutouts of the calibration wafer that are all coradial with one another (or a single circular edge thereof) may serve as fiducials for the calibration wafer, and arcuate edges of the wafer support that are all coradial with one another (or a single circular edge thereof) may serve as fiducials for the wafer support. It will be understood that other fiducials may be used to similar effect, and the techniques discussed herein may generally be applicable to any suitable fiducials and applicable algorithms for determining relative offset between such structures based on the selected fiducials.

In block 1010, a determination may be made, based on the relative gap sizes between the imaged fiducials of the two structures, as to the offset between reference points, e.g., centers, of both structures. Such an offset may be compared against a threshold offset to see if the off-centeredness of the two structures is within acceptable limits. Such a threshold offset may be established based on the non-uniformity requirements of a particular semiconductor processing technique. If off-centeredness measurements are not within acceptable limits, appropriate actions may be taken, e.g., one of the structures may be repositioned based on the measured center offsets and the procedure may be repeated until the off-centeredness measurement is within acceptable limits.

In some instances, the technique of FIG. 10 may be performed with an edge ring at the wafer support. In some such implementations, the fiducials of the structures may include fiducials of the calibration wafer, wafer support, edge ring, or a combination thereof, as provided herein. This may include, for example, using only those fiducials of the calibration wafer and the wafer support, and no fiducials of the edge ring. In some other instances, the technique FIG. 10 may be performed without an edge ring at the wafer support. The fiducials in some such embodiments may include fiducials of the calibration wafer and the wafer support.

Referring back to FIGS. 8A-J, in some implementations, these images may partially illustrate the implementation of aspects of the technique of FIG. 10. For example, FIGS. 8A and 8B may be a partial illustration of blocks 1012 and 1014, FIG. 8B may be a partial illustration of block 1004, and FIGS. 8C and 8D may be partial illustrations of 1006.

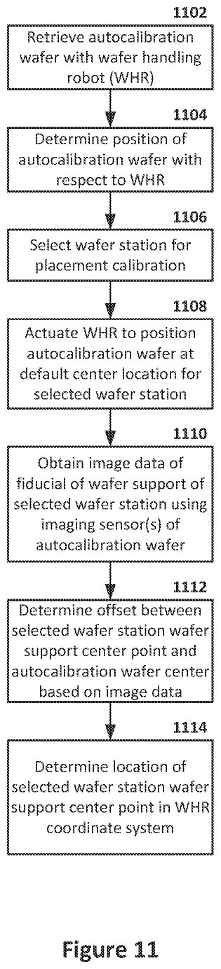

FIG. 11 depicts a flow chart of a technique for determining the location of the center point of a wafer support using an autocalibration wafer. In block 1102, an autocalibration wafer may be retrieved using the end effector of a wafer-handling robot. In block 1104, the position of the autocalibration wafer relative to the wafer-handling robot end effector may be determined. Blocks 1102 and 1104 may, in some instances, be performed in tandem, e.g., the wafer-handling robot may be controlled to cause the autocalibration wafer to be picked up by the end effector (as discussed earlier herein) such that the autocalibration wafer is centered on a reference point of the end effector, thus establishing the position of the autocalibration wafer relative to the end effector.

In block 1106, a wafer station may be selected for determination of the center point of a wafer support thereof. In block 1108, the wafer-handling robot may be actuated to cause the autocalibration wafer to be positioned above the wafer support of the selected wafer station, e.g., at a default center location associated with that wafer station.

In block 1110, image data may be obtained, for example, of a fiducial or fiducials of the wafer support using one or more imaging sensors of the autocalibration wafer. Such a fiducial may, for example, be an etched pattern located at the center of the wafer support. Alternatively, the fiducial may be a circular edge of a portion of the wafer support, e.g., of an ESC and its wafer support area that are part of the wafer support, that defines a center point of the wafer support; these fiducials of the wafer support may be visible within/through the cutouts of the calibration wafer. In the former case, an imaging sensor located near or at the center of the autocalibration wafer may be used to image the fiducial. In the latter case, imaging sensors located near the outer edge of the autocalibration wafer may be used to image the fiducials.

In block 1112, the image data may be analyzed to determine an offset between a reference point, e.g., center point, of the autocalibration wafer and the reference point of the selected wafer station defined by the fiducial. In block 1114, the offset determined in block 1112 may be transformed into the coordinate system of the wafer-handling robot. If desired, the “default” location corresponding to the center of the selected wafer support may be updated to account for the offset determined in block 1114 (alternatively, the default location may be left as-is but then adjusted based on the offset for each subsequent wafer placement at that wafer station). In some implementations, the wafer-handling robot may then be actuated to cause the wafer-handling robot to shift the autocalibration wafer so that the autocalibration wafer center is positioned at the updated center location for the wafer support (similar to block 1108). In such implementations, blocks 1110 through 1114 may be repeated, if desired, to verify that the updated centered position is adequately centered. If the updated default location (or correction of the default location) is found to still produce a center-to-center offset that is not within acceptable limits, then the process may be repeated one or more times.

While the above discussion has focused on using an autocalibration wafer to determine the absolute location of the center of a wafer support or other structure with respect to the coordinate system used by the wafer-handling robot, autocalibration wafers may also be used to determine relative positioning between two or more components, as discussed further below and above, including FIG. 10. This includes, for instance, relative positioning between the calibration wafer, the wafer support, the edge ring (if present), or any combination thereof.

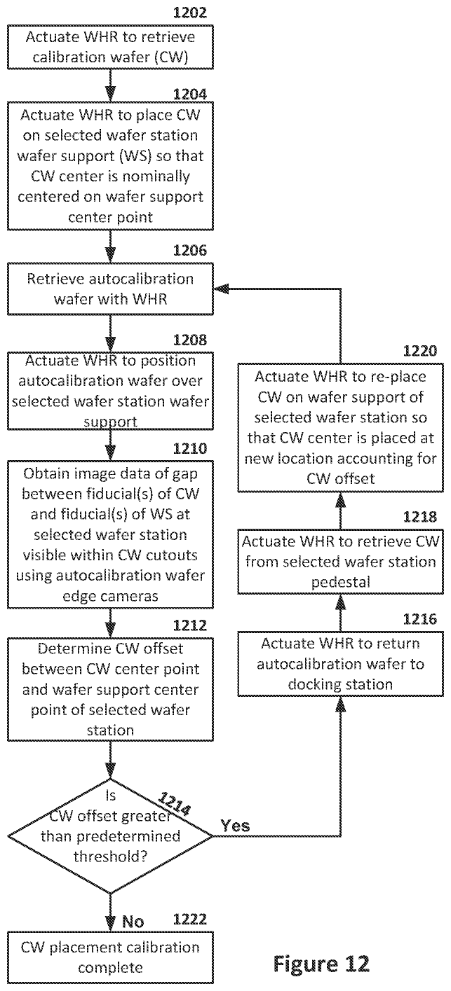

Similar to FIG. 10, FIG. 12 depicts a flow chart of a technique for calibrating the placement of a calibration wafer on a wafer support. In block 1202, a wafer-handling robot of a semiconductor processing tool may be actuated to cause the wafer-handling robot to retrieve the calibration wafer from a wafer station or other storage location. In block 1204, the wafer-handling robot may be further actuated to cause the calibration wafer to be placed on a wafer support, e.g., pedestal, of a selected wafer station of the semiconductor processing tool. Blocks 1202 and 1204 may be optional in some implementations, as the calibration wafer may have been previously placed or installed on the wafer support, e.g., during another phase of operation. Also, in some implementations the autocalibration wafer may have been used to determine or estimate the center or nominal center of the wafer support while the autocalibration wafer was not positioned on the wafer support, such as using the technique of FIGS. 9, for example.

In block 1206, the wafer-handling robot may be controlled to cause the wafer-handling robot to retrieve an autocalibration wafer from a docking station or other location. In block 1208, the wafer-handling robot may be further actuated to cause the autocalibration wafer to be positioned at a location over the wafer support of the selected wafer station and the calibration wafer positioned thereupon. This may be similar to the positioning shown in FIGS. 3A-D described above.

Once positioned over the wafer support and calibration wafer of the selected wafer station, the autocalibration wafer may be caused, in block 1210, to obtain image data of fiducials and/or features within and around the cutouts of the calibration wafer. This includes, as discussed above, for example, the gaps between a fiducial of the calibration wafer and a fiducial of the wafer support. These gaps may include gaps 332A-C between the outer edge 218 of the calibration wafer 214 and the outer edge 104A-C, respectively, of the wafer support area that are visible within, through, and/or adjacent to the cutouts of the calibration wafer as illustrated in FIGS. 3A-D; these gaps may also include gaps 347A-C between the fiducials 222A-C, respectively, and the outer edge 104A-C, respectively, of the wafer support area 102 along the line 341A-C, respectively, that is collinear with fiducial 223A-C, respectively as illustrated in FIGS. 3E-G. Block 1210, and technique 12, uses features, e.g., fiducials, of the calibration wafer and the wafer support area that are visible within and through the calibration wafer's cutouts. This may also include gaps or space between other various fiducials of the wafer support area, such as its outer edge 104, and fiducial markers 222A-C and 223A-C in FIGS. 2A-3D, the outer edge 218 of the calibration wafer, or the one or more edges that at least partially define each of the cutouts 216A-C, or a combination of any such features.

In block 1212, an estimated offset may be determined between the center of the calibration wafer and the center of the wafer support area based on the relative sizes of the gaps between the fiducials in the images. In block 1214, a determination may be made as to whether or not the estimated calibration wafer/wafer support offset exceeds a predetermined threshold offset. If the estimated calibration wafer/wafer support offset does exceed the predetermined threshold offset, then the technique may proceed to block 1216, in which the wafer-handling robot may be actuated to remove the autocalibration wafer from the position above the wafer support and returned, for example, to the docking station (or to some other temporary holding location). The wafer-handling robot may then, in block 1218, be actuated to retrieve the calibration wafer from the wafer support of the selected wafer station. For example, lift pins may be used to lift the calibration wafer off of the wafer support so that the end effector of the wafer-handling robot may be inserted beneath the calibration wafer, and the calibration wafer then lowered onto the end effector by retracting the lift pins into the wafer support.

After the wafer-handling robot has been used to retrieve the calibration wafer from the wafer support in block 1218, the wafer-handling robot may be further controlled to cause the calibration wafer to be re-placed on the wafer support such that the calibration wafer center is placed at a new location that accounts for the calibration wafer offset, thereby causing the calibration wafer and the wafer support to be more accurately centered on one another. After block 1218, the technique may return to block 1206, and a further evaluation of the calibration wafer/wafer support center offset may be obtained. If necessary, this portion of the technique may be repeated for a threshold number of times or until the estimated center offset between the calibration wafer and the wafer support is within the predetermined threshold offset. If the estimated calibration wafer/wafer support offset is found to be within the predetermined threshold offset in block 1214, then the technique may proceed to block 1222, in which the calibration wafer placement calibration may be deemed to be complete.

In some instances, the technique of FIG. 12 may be performed with an edge ring at the wafer support. In some such implementations, the fiducials of the structures may include fiducials of the calibration wafer, wafer support, edge ring, or a combination thereof, as provided herein. This may include, for example, using only those fiducials of the calibration wafer and the wafer support, and no fiducials of the edge ring. In some other instances, the technique FIG. 12 may be performed without an edge ring at the wafer support. The fiducials in some such embodiments may include fiducials of the calibration wafer and the wafer support

Referring back to FIGS. 8A-J, in some implementations, these images may partially illustrate the implementation of aspects of the technique of FIG. 12. For example, FIGS. 8A and 8B may be partial illustrations of blocks 1202 and 1204, FIG. 8B may be a partial illustration of block 1206, FIGS. 8C and 8D may be partial illustrations of block 1208, FIG. 8E may be a partial illustration of block 1216, FIG. 8A may be a partial illustration of block 1218, and FIG. 8B may be a partial illustration of block 1220.

It will be understood that using the autocalibration wafer to evaluate relative offsets between two structures may be accomplished without precise positioning of, or even knowledge of, the autocalibration wafer relative to the end effector of the wafer-handling robot. In particular, the techniques discussed herein may be used when the autocalibration wafer is sufficiently centered on the end effector such that the fields of view of the first imaging sensors of the autocalibration wafer are able to image the various gaps in between fiducials of the two structures and visible within or around the cutouts of the calibration wafer. It will also be understood that a similar technique may be used to center other components relative to the wafer support, e.g., to center a calibration wafer relative to the wafer support.

For calibration wafer centering, in addition to providing visibility to features underneath the calibration wafer, the calibration wafer acts as a stand-in or representative of wafers that will be placed in future operations. As such, once the calibration wafer is centered on a desired structure, e.g., a wafer support or wafer support with an edge ring, using the autocalibration wafer techniques discussed herein, the calibration wafer may be removed from the centered location using the wafer-handling robot and used to teach an active wafer centering (AWC) system, a dynamic alignment (“DA”) system, for instance, that may then, in turn, “learn” the desired center point of the calibration wafer relative to the end effector with respect to a given wafer-handling robot kinematic path; future placements of wafers on the end effector of the wafer-handling robot may then be evaluated using the active wafer centering system in order to determine the offset between the center points of such wafers and the learned center point. The wafer-handling robot may then be actuated to place the wafer on the wafer support in a manner that accounts for this determined offset. It will be understood that while edge rings may generally remain in position for a large number of processing operations, edge rings may occasionally be replaced; similar AWC and DA techniques may be performed, as discussed earlier, during such subsequent edge ring placements as well in order to compensate for any misalignment between such an edge ring and the end effector.

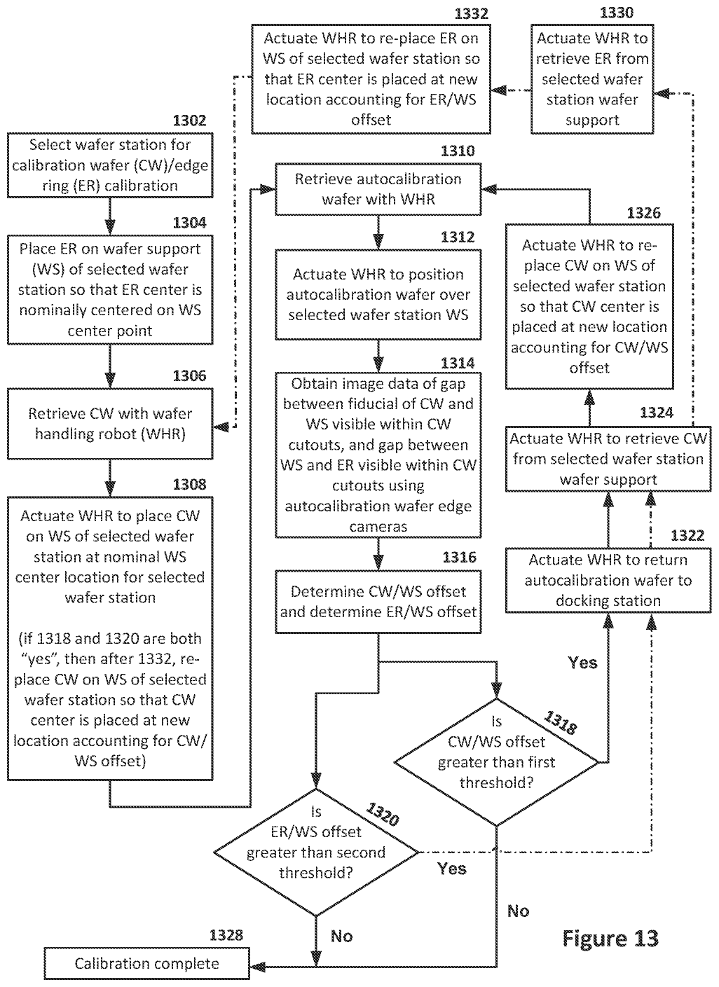

The techniques discussed herein may also be used to determine offsets between two movable components with respect to a relatively stationary component, e.g., between the calibration wafer (a first moveable component) and the wafer support (the relative stationary component), and the edge ring (a second moveable component) and the wafer support (again, the relative stationary component). As an example, FIG. 13 depicts a flow chart of a technique for concurrently calibrating the placement of a calibration wafer relative to a wafer support and an edge ring relative to the wafer support.

In block 1302, a wafer station of a semiconductor processing tool may be selected. An edge ring may be placed on a wafer support of the selected wafer station in block 1304 such that the center of the edge ring is nominally centered on the center of the wafer support. Block 1304 may be optional; the edge ring may also have been placed on the wafer support of the selected wafer station through other means, e.g., manual placement, or may have already been in place on the wafer support prior to selection of the selected wafer station. In some instances, block 1304 may include the wafer-handling robot may being caused to retrieve the edge ring and position it on the wafer support.

In block 1306, the wafer-handling robot may be caused to retrieve a calibration wafer with a plurality of cutouts, such as the calibration wafer described herein and shown, for example, in FIGS. 2A-2E. In block 1308, the wafer-handling robot may be caused to transfer the calibration wafer to the wafer support of the selected wafer station such that the center of the calibration wafer is nominally centered on the center of the wafer support. In some implementations, this centering may be based on the technique of FIGS. 10 and/or 12 described above.

In block 1310, the wafer-handling robot may be controlled to retrieve an autocalibration wafer from a storage location, such as a docking station or other location accessible to the wafer-handling robot. In block 1312, the wafer-handling robot may be controlled to position the autocalibration wafer over the wafer support of the selected wafer station such that the autocalibration wafer is generally centered over the center points of the calibration wafer and/or the edge ring, such as shown in FIGS. 4A-D and 8J. As described more below, block 1310 also includes an optional, potential further operation of re-placing the calibration wafer onto the wafer support area at a new location if both the determined calibration wafer/wafer support area offset is greater than a threshold in block 1318 and the determined edge ring/wafer support area offset is greater than a threshold in block 1320.

In block 1314, the autocalibration wafer may be controlled to cause the edge cameras of the autocalibration wafer, e.g., the first imaging sensors, to obtain image data of the features and/or fiducials of the calibration wafer, the wafer support, the edge ring, or any combination thereof. This includes, as provided above, for example, the gap between the outer edge of the calibration wafer and the outer edge of the wafer support area (e.g., gaps 332A-C in FIGS. 3B-D), the gap between the edge ring and the wafer support area (e.g., gaps 433A-C in FIGS. 4B-D), the gap between a fiducial marker of the calibration wafer and the outer edge of the wafer support area (e.g. gaps 347A-C illustrated in FIGS. 3E-3G and 4E-4G), the gap between a fiducial marker of the calibration wafer and the inner edge of the edge ring (e.g., gaps 453A-C illustrated in FIGS. 4E-4G), or a combination thereof. Similar to above, block 1314, and technique 13, images and uses features, e.g., fiducials, of the edge ring and the wafer support area that are visible within and through the calibration wafer's cutouts; without these cutouts, such fiducials of the edge ring and wafer support area would not be visible. Although block 1314 refers to the gap between the wafer support and edge ring that is visible within the calibration cutouts, the measured and determined gap with respect to the edge may be any of those provided herein, including the gaps 433A-C between the edge ring and wafer support in FIGS. 4B-4D, and/or gaps 453A-C between the edge ring and fiducial marker on the calibration wafer illustrated in FIGS. 4E-4G.

In block 1316, the image data may be analyzed to determine a center-to-center calibration wafer/wafer support area offset (which may also be referred to herein as the calibration wafer/wafer support offset) between the centers of the calibration wafer and wafer support area, and to determine a center-to-center edge ring/wafer support area offset (which may also be referred to herein as the edge ring/wafer support offset) between the centers of the edge ring and wafer support area. The center-to-center offset between the calibration wafer and wafer support area is based on offsets between the fiducials of the calibration wafer and the wafer support, such as between the outer edge of the calibration wafer and the outer edge of the wafer support, and the relative gap sizes in the images; as noted above, the fiducials of the wafer support area are visible within/through the cutouts of the calibration wafer. The center-to-center offset between the edge ring and wafer support area is based on, for example, offsets between the fiducials of the edge ring and the wafer support, such as between the inner edge of the edge ring and the outer edge of the wafer support, and the relative gap sizes in the images; as noted above, the fiducials of both the edge ring and the wafer support area are visible within/through the cutouts of the calibration wafer. Determinations may then be made as to whether one or both of the center-to-center offsets exceed various thresholds. In block 1318 a determination may be made as to whether the calibration wafer/wafer support offset exceeds a first predetermined threshold offset and in block 1320 a determination may be made as to whether the edge ring/wafer support offset exceeds a second predetermined threshold offset.

In the event that it is determined in both blocks 1318 and 1320 that the calibration wafer with respect to the wafer support, and the edge ring with respect to the wafer support, are both sufficiently centered on the wafer support, i.e., the determined calibration wafer/wafer support offset is within the first predetermined threshold and the determined edge ring/wafer support offset is within the second predetermined threshold, then the technique may proceed to block 1328, where the calibration wafer and edge ring placement calibration may be deemed complete. At this point, the calibration wafer may be removed from the wafer station using the wafer-handling robot and used to train, for example, an active wafer centering system-much in the same manner that a calibration wafer that is manually centered with respect to a wafer support, e.g., through using a fixture or other mechanical centering system, would be used. The training of an active wafer centering system based on a centered wafer or a wafer that has otherwise been placed on a wafer-handling robot end effector in a calibrated wafer is well-known in the industry and is not described in depth in this disclosure in the interest of brevity. In some instances, the ring position may be used, additionally or alternatively, to teach the active ring centering system.

If yes to either or both of blocks 1318 and 1320, then additional and/or repeated blocks may be performed. For example, if block 1318 is yes, then a sequence of operations following the solid arrows thereafter is performed. This sequence includes proceeding to block 1322, in which the wafer-handling robot may be actuated to return the autocalibration wafer to the docking station (or some other temporary holding location), and then to block 1324, in which the wafer-handling robot may be further actuated to retrieve the calibration wafer from the wafer support of the selected wafer station. For example, lift pins for the wafer support may be caused to raise the calibration wafer off of the edge ring so that the wafer-handling robot end effector may be positioned beneath the calibration wafer. Once so positioned, the lift pins may be further controlled to lower the calibration wafer onto the end effector.

In this sequence of operations following a “yes” to block 1318, block 1326 may then be performed in which the wafer-handling robot may be actuated to re-place the calibration wafer onto the wafer support of the selected wafer station such that the calibration wafer center is placed at a new location that accounts for the calibration wafer/wafer support offset determined in block 1318. The technique may then return to block 1310 to initiate a further autocalibration wafer imaging operation of the gap sizes between the calibration wafer and the wafer support; this re-placement and re-analysis of the centeredness of the calibration wafer with respect to the wafer support may be performed multiple times, e.g., until the determined calibration wafer/wafer support offset falls below the first predetermined threshold or until a predetermined number of such repetitions has occurred.

Referring back to block 1320, if the edge ring/wafer support (“ER/WS”) offset is greater than the second threshold, then both the calibration wafer and the edge ring are to be removed from the wafer support and positioned back onto the wafer support. Depending on whether the block 1318 determination regarding the calibration wafer/wafer support is a yes or a no, then different sets of additional operations may be performed. For example, in the event that the edge ring/wafer support offset is greater than the second threshold, then the edge ring may follow the sequence of operations after block 1320 indicated by the dashed lines, including blocks 1322, 1324, and after 1324 to blocks 1330, 1332, and back to 1306. Following blocks 1322 and 1324, in block 1330 the wafer-handling robot may be actuated to retrieve the edge ring from the wafer support; generally speaking, the edge ring cannot be removed from the wafer support without removing the calibration wafer; the edge ring and calibration wafer could be removed concurrently or the calibration wafer could be removed before the edge ring is removed. In block 1332, the wafer-handling robot may be actuated to re-place the edge ring onto the wafer support of the selected wafer station such that the edge ring center is placed at a new location that accounts for the edge ring/wafer support offset determined in block 1320. After block 1332, blocks 1306 through 1316 may be repeated.

In some implementations, blocks 1318 and 1320 may again be repeated even if its previous determination was a “no.” This may ensure that the edge ring and/or calibration wafer remain within their desired offset threshold and to ensure their respective centeredness to the wafer support. For example, the calibration wafer and/or the edge ring may have been caused to move during the execution of blocks after 1320 and 1318 and rechecking the centeredness of each movable component ensures that they remain adequately centered as one or both become adjusted and better centered.

As noted above, if both blocks 1320 and 1318 are “yes”, then block 1308 may be performed such that the wafer-handling robot may be actuated to re-place the calibration wafer onto the wafer support of the selected wafer station such that the calibration wafer center is placed at a new location that accounts for the calibration wafer/wafer support offset determined in block 1318. The re-placement is similar to the operation of block 1326 which positions the calibration wafer in a new location. However, if block 1320 was “yes,” but block 1318 was “no”, then the re-execution of block 1308 may include positioning the calibration wafer at the previous position, not at a new location because the calibration wafer's offset did not exceed the first threshold.

In some embodiments, the one or more controllers executing instructions to perform the techniques herein, such as FIG. 13, may be configured to have separate instructions for executing the blocks of FIG. 13, including, for example, separately executing blocks 1304, 1306, and 1308. In some other embodiments, two or more of these blocks may be combined into a single instruction, such as blocks 1304 and 1306 are a part of a single instruction in which the wafer-handling robot may be caused to transfer the edge ring onto the selected wafer station and then caused to transfer the calibration wafer onto that selected wafer station. Similarly, block 1314 may be encompassed by a single instruction to cause each imaging sensor of the autocalibration wafer to obtain a corresponding first image of a fiducial marker on the calibration wafer, a fiducial of the first wafer support within the cutout of the calibration wafer, and a fiducial of the first edge ring within the cutout of the calibration wafer while the autocalibration wafer is positioned over the first wafer support, the calibration wafer, and the first edge ring.

It will be understood that the above techniques may be practiced in a variety of different ways to achieve similar results. For example, in tools having multiple wafer-handling robots or wafer-handling robots that have dual arms/end effectors, one wafer-handling robot arm/end effector may be used to place or re-position objects, e.g., calibration wafers and/or edge rings, on wafer supports, whereas the other wafer-handling robot arm/end effector may be used to hold the autocalibration wafer. Thus, for example, the first arm may be used to place an edge ring on a wafer support and then retracted; the second arm may then move the autocalibration wafer over the placed edge ring to obtain a measurement of center-to-center offset between the edge ring and the wafer support. The second arm may then be retracted and, if necessary, the edge ring may be lifted clear of the wafer support, e.g., through use of lift pins, and the first arm may be used to reposition the edge ring to correct for the center-to-center offset between the edge ring and the wafer support. The first arm may then be withdrawn, and the second arm may move the autocalibration wafer over the edge ring and wafer support again to obtain a second measurement of center-to-center offset; this process may be repeated as needed until the desired amount of center-to-center offset between the edge ring and wafer support is achieved.

It will be further understood that autocalibration wafer-guided placement of wafers and/or edge rings on wafer supports may be an iterative process in which estimates of the relative offset between two structures, e.g., the wafer and the wafer support, the edge ring and the wafer support, or the edge ring and the wafer, may be obtained using the autocalibration wafer and then used to guide re-placement of one of the two structures relative to the other structure, which may stay stationary. Such autocalibration wafer-assisted placement and evaluation may generally be repeated until the measured offset is within a predetermined maximum allowable offset for a given set of components for a given semiconductor processing tool.

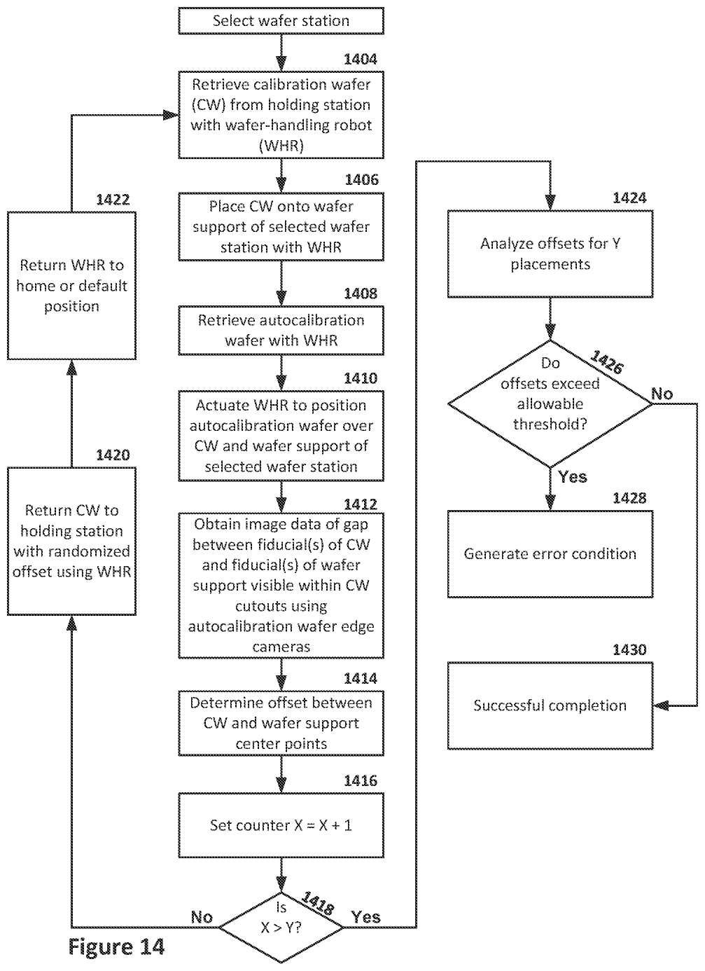

Once the calibration wafer, or both the calibration wafer and the edge ring, have been centered on a wafer support and then used to train an active wafer centering system, the trained active wafer centering system may then optionally be tested using the autocalibration wafer to ensure that the trained active wafer centering system will provide reliably centered wafer placements. FIG. 14 depicts a flow chart of such a technique for verifying repeatability of wafer placement (the technique of FIG. 14, in some implementations, is intended to be practiced after an active wafer centering system has already been taught); this technique assumes that the active wafer centering system has been trained with the calibration wafer that is centered relative to the wafer support, but may also be used, with appropriate modification.

In block 1402, a wafer station of a semiconductor processing tool may be selected; the selected wafer station will have had the calibration wafer previously centered on the wafer support thereof, e.g., using the techniques discussed above, such as in FIG. 12, and an active wafer centering system associated with that wafer station will have been trained based on that calibration wafer's centered location. In block 1404, a wafer-handling robot of the semiconductor processing tool may be caused by a controller of the semiconductor processing tool to retrieve the calibration wafer with a plurality of cutouts from a holding station, e.g., a buffer, FOUP, or other location, of the semiconductor processing tool. In block 1406, the wafer-handling robot may be controlled to cause the calibration wafer to be placed onto a wafer support of the selected wafer station.

Subsequent to the placement of the calibration wafer onto the wafer support, the wafer-handling robot may be caused, in block 1408, to retrieve an autocalibration wafer from, for example, a docking station or other storage location. In block 1410, the wafer-handling robot may be actuated to cause the autocalibration wafer to be positioned over the calibration wafer and the wafer support of the selected wafer station such that each first imaging sensor of the autocalibration wafers has the edge of the calibration wafer, including one of the cutouts in the plurality of cutouts, and an edge of the wafer support visible through that cutout within that imaging sensor's field of view. This may be similar to FIGS. 3A-D discussed above.

In block 1412, the autocalibration wafer may be caused to obtain image data of the fiducials of the calibration wafer, such as those discussed above with respect to FIGS. 3A-D above including the fiducial markers 322A-C and 323A-C, one or more edges of each cutout 216A-C, the outer edge 218 of the calibration wafer, or a combination thereof, and one or more fiducials of the wafer support, such as its outer edge 104 visible within each cutout. In block 1414, a determination may be made as to the offset between the center of the wafer support and the center of the calibration wafer; this offset may be stored for later reference. In block 1416, a counter X may be incremented to X+1, and in block 1418, a determination may be made if X exceeds a given threshold Y. X may represent the number of test placements that has been performed as part of the technique, and Y may represent the total number of test placements that are to be performed as part of the technique.

If it is determined in block 1418 that X is not greater than Y, then the technique may proceed to block 1420 before returning to block 1404. In block 1420, the calibration wafer may be returned to its original location in the holding station or other location with a randomized offset before the wafer-handling robot is returned to a default or “home” position in block 1422. The randomized offset may be selected so as to be within the typical expected offsets for a wafer under normal operational use, e.g., offsets less than 0.8 mm. Thus, when the calibration wafer is again retrieved by the wafer-handling robot in block 1404 (which will generally be caused to return to the same position to retrieve the calibration wafer each time), the calibration wafer will have a correspondingly random offset position with respect to the end effector of the wafer-handling robot. It will also be understood that the randomization of the wafer placement may instead occur at other times, e.g., just prior to retrieving the calibration wafer from the holding station or other location, the wafer-handling robot may be caused to undergo a random displacement such that the calibration wafer's position with respect to the end effector is similarly randomized. Such randomization may serve to be representative of slight misalignments of wafers that are placed in the holding station during normal operation.

If it is determined in block 1418 that sufficient test wafer placements have been performed, the technique may proceed to block 1424, in which the center offsets for the Y wafer placements may be evaluated or analyzed. Such analysis may include any of a variety of different analysis techniques or tests, e.g., statistical parameters of the captured population of test wafer center offsets may be determined and compared against corresponding thresholds. For example, the mean, median, and standard deviation of the offsets may be determined and evaluated against corresponding thresholds for such values to determine if an acceptable consistency of wafer placement resulted from the test technique. In block 1426, the offsets may be compared against those thresholds (or, more accurately, the statistical parameters derived from the offsets may be compared against their corresponding thresholds) to determine if the test was successful or not. If the comparison of block 1426 indicates that one or more allowable parameters was exceeded, then the technique may proceed to block 1428, in which an error condition may be generated. If the comparison of block 1426 indicates that the one or more parameters are all within acceptable limits, then the technique may proceed to block 1430, in which the technique may be successfully completed.

It will be understood that similar techniques may also be practiced using edge rings, e.g., performing repeated edge ring placements and randomizing the end effector/edge ring offset between each placement in order to evaluate the repeatability of edge ring placement.

It will be appreciated that the various techniques described herein may be combined in various ways to provide a completely automated system for configuring a semiconductor processing tool. For example, a semiconductor processing tool may be configured to have an “initial setup” mode that it may be placed in where the tool may retrieve and center the calibration wafer with the plurality of cutouts on each wafer support in a semiconductor processing chamber using the autocalibration wafer and then, for each wafer support, center an edge ring and calibration wafer associated with the edge ring using the autocalibration wafer, train an active wafer centering system and wafer-handling robot with the centered calibration wafer, and then verify that the trained active wafer centering system produces reliable wafer placement. The semiconductor processing tool may also periodically perform various health checks, such as checking to see if the center-to-center offset for an edge ring and/or calibration wafer has drifted to an unacceptable distance.

For example, one sequence of operations may include performing a technique to use the autocalibration wafer to determine a center of the wafer station while neither the edge ring or calibration wafer are at the wafer station, such as the technique of FIG. 9 or 11. After this, the calibration wafer may be used to determine and refine its positioning to within a desired tolerance, such as performing the technique of FIGS. 10, 12, 14, or a combination thereof including, for example, performing the techniques of FIGS. 12 and 14. After performing these techniques, the edge ring and calibration wafer may both be positioned at the wafer station and the relative offsets between edge ring and wafer station, and calibration wafer and wafer station may be performed as illustrated with FIG. 13. Accordingly, some implementations may perform the technique of FIG. 9 or 11, followed by the technique of FIGS. 10, 12, and/or 14, followed by the technique of FIG. 13.

In some embodiments, this may include performing the following operations: (a) causing, before causing a wafer-handling robot to transfer the calibration wafer to the first wafer support, the wafer-handling robot to position the autocalibration wafer above the first wafer station, (b) causing each first imaging sensor to obtain a corresponding first image of a fiducial of the first wafer support while the autocalibration wafer is positioned above the first wafer support and while the calibration wafer is not positioned on the first wafer support and/or cause a centrally-located, downward-facing second imaging sensor of the autocalibration wafer to obtain a corresponding second image of a fiducial of the first wafer support while the autocalibration wafer is positioned above the first wafer support and while the calibration wafer is not positioned on the first wafer support, (c) determining a center point of the first wafer support based, at least in part, on the first images and/or second image, (d) causing, after (a) and (b), the wafer-handling robot to transfer the calibration wafer to a first wafer support of the one or more wafer supports of the first wafer station of the one or more wafer stations, (e) causing, after (d), the wafer-handling robot to position the autocalibration wafer above the first wafer station and the calibration wafer positioned thereon such that at least a part of each cutout is within a field of view of a corresponding first imaging sensor, (f) causing each first imaging sensor to obtain a corresponding third image of a fiducial marker on the calibration wafer and a fiducial of the first wafer support within the corresponding cutout of the calibration wafer while the autocalibration wafer is positioned over the first wafer support and the calibration wafer, (g) causing the wafer-handling robot to transfer the calibration wafer off the first wafer support, (h) causing, while the calibration wafer is not positioned on the first wafer support, the wafer-handling robot to transfer a first edge ring to the first wafer support such that a center point of the first edge ring is nominally centered on the center point of the first wafer support when viewed along a vertical axis, (i) causing the wafer-handling robot to transfer the calibration wafer to the first wafer support after transferring the first edge ring to the first wafer support, (j) causing the wafer-handling robot to position the autocalibration wafer above the first wafer station, the first edge ring, and the calibration wafer positioned thereon such that each cutout is within a field of view of a corresponding first imaging sensor, and (k) causing each first imaging sensor to obtain a corresponding fourth image of a fiducial marker on the calibration wafer, a fiducial of the first wafer support within the cutout of the calibration wafer, and a fiducial of the first edge ring within the cutout of the calibration wafer while the autocalibration wafer is positioned over the first wafer support, the calibration wafer, and the first edge ring.

### Additional Embodiments

Although the above description refers to calibration wafers having cutouts at or near the edge of the calibration wafers, some implementations may use a calibration wafer having one or more through-holes, with corresponding fiducial markers, in an interior region of the calibration wafer that provide visibility and line-of-sight viewing of various fiducials (or position/alignment identifiers) on the wafer support area of the wafer support that would be otherwise covered and unviewable by conventional wafers without such through-holes. As an alternative, or in addition, to some of the examples provided above, these through-holes provide visibility of fiducials on the wafer support area other than the outer edge of the wafer support area, such as fiducials in a center area or center region of the wafer support area. The fiducials on the wafer support area may include fiducial markers, physical structures such as edges of features on the wafer support area (e.g., ridges, channels, or grooves, for example), or a combination thereof. The fiducial markers on the calibration wafer, nearby the through-holes, are used in conjunction with the visible and detected fiducials on the wafer support area to determine the relative offset of the calibration wafer with respect to the wafer support. In some implementations, the through-holes may have various shapes, such as circular, square, rectangular, obround, elliptical, triangular, or other geometric shape.

An autocalibration wafer may also be provided with one or more imaging sensors that correspond with, or provide a field of view to, the calibration wafer's one or more through-holes when positioned above the calibration wafer. For example, for a calibration wafer with a through-hole at its center, an autocalibration wafer may be provided that has the centrally-located, downward-facing second imaging sensor 524 or 624 of FIGS. 5 and 6 that provides a field of view to the calibration wafer's center through-hole.

In some embodiments, these calibration wafers with one or more through-holes in an interior region of the calibration wafer may be used for some wafer supports that do not use an edge ring and/or that have fiducials on the wafer support area. In some implementations, the calibration wafer may have one or more through-holes and one or more edge cutouts at the calibration wafer edge, similar to above, in order to provide visibility to a fiducial of an edge ring, such as its interior edge, and a fiducial on the wafer support area.

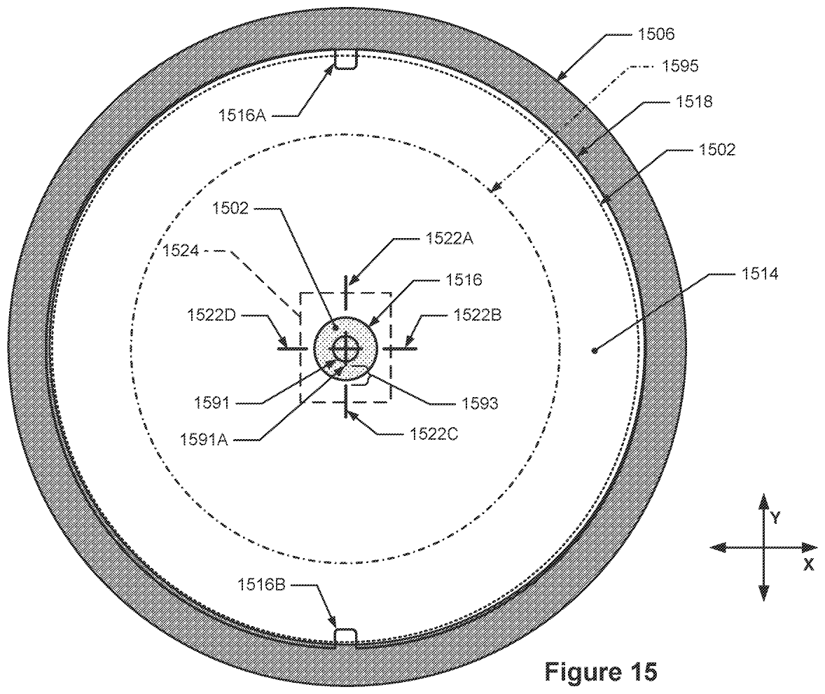

FIG. 15 depicts a calibration wafer having a center through-hole positioned on a wafer support having a fiducial. The calibration wafer 1514 here has a through-hole 1516 at the calibration wafer's 1514 center. In this example, the through-hole 1516 is positioned in an interior area 1595 of the calibration wafer 1514 that has an outer boundary (represented by the dash-dot-dash line) less than the outer diameter of the calibration wafer 1514 edge 1518 and may also be closer to the calibration wafer's center point (or center axis) than the edge cutouts, when such cutouts are present. The calibration wafer 1514 also has one or more fiducial markers 1522A-D positioned adjacent to, or nearby, the through-hole 1516. Further in this example, these fiducial markers 1522A-D are lines that are aligned with, or converge at, the center of the calibration wafer 1514 and may be used to determine various positioning, such as in the various x- or y-axis offsets and/or angular positioning and orientation. The fiducial markers 1522A-D are spaced apart and positioned at known locations and distances, such as orthogonal to each other about the center axis. The calibration wafer is also positioned on a wafer support area 1502 that includes one or more fiducial markers 1591 at a center region of the wafer support area. The through-hole 1516 of the calibration wafer 1514 allows visibility of the wafer support area's 1502 one or more fiducial markers 1591. For clarity, the area of the wafer support 1502 that is visible through the through-hole 1516 of the calibration wafer 1514 is identified with light shading. The fiducial marker on the wafer support area 1502 may be various configurations, shapes, and sizes, such as lines, circles, triangles, squares, or a combination thereof. In this example, the fiducial markers 1591 include a cross with a circle. In some embodiments, the calibration wafer 1514 may have a single edge cutout or no edge cutouts (i.e. no 1516A and 1516B). In some embodiments, where the edge ring has a unique position/location/alignment indicator or feature, a single edge cut out positioned over such indicator or feature may be sufficient to align the edge ring properly. In some such embodiments, the position indicator may be shown on a top surface near the inner diameter of the edge ring. In some embodiments, the wafer support area may have a corresponding fiducial for aligning with the edge ring's position indicator. For example, the corresponding fiducial may be a symbol that is aligned with the edge ring's position indicator (within a reasonable tolerance range) when the edge ring is properly installed.

In some examples the fiducial or fiducials on the wafer support may be various structural elements, such as grooves, holes, lines, channels, raised structures, for example. One or more edges of these structural elements may be used as a wafer support fiducial. For instance, the wafer support area may have a channel that passes through the center of the wafer support area and an edge of this channel, similar to the edges described above, may be used as a fiducial marker. In some embodiments, a combination of a structural element and other fiducial marker, such as a printed or etched marking, may be used.

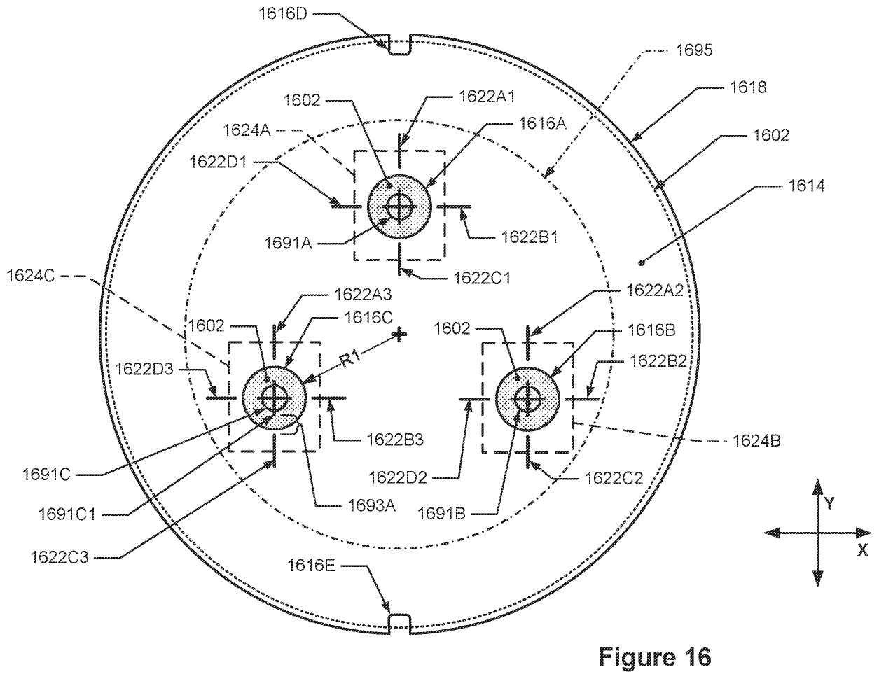

Similar to above, one or more gaps may exist between a fiducial marker on the calibration wafer and a fiducial marker on the wafer support and these one or more gaps may be detected and measured to determine the relative offset between the calibration wafer and the wafer support. For example, in FIG. 15, a gap 1593 may exist between fiducial marker 1522C on the calibration wafer and fiducial marker 1591A on the wafer support area 1502 and this gap may be used, at least in part, to determine the relative offset between the calibration wafer and the wafer support. As noted above, the autocalibration wafers provided herein are configured to correspond with and capture images of the through-holes of the calibration wafer. For instance, in FIG. 15, an autocalibration wafer with a centrally located downward-facing imaging sensor, like sensors 524 or 624 of FIGS. 5 and 6, corresponds with the through-hole 1516 and is configured to be positioned above the calibration wafer so the imaging sensor has a field of view 1524 that can capture the fiducial markers 1522A-D of the calibration wafer 1514 and the fiducial markers 1591 on the wafer support 1502. In some embodiments, the through-hole 1516 of the calibration wafer 1514 may be radially offset from the center of the calibration wafer 1514 to align with one or more fiducials on the wafer support area 1502 that are also radially offset from the center of the wafer support area 1502 (for example, referring to FIG. 16, a calibration wafer with just through-hole 1616A but not through-holes 1616B or 1616C). In some such embodiments, the location of downward-facing image sensor of the autocalibration wafer may also be modified so that the through-hole location can be properly captured and analyzed.

In some embodiments, as provided above, the calibration wafer may also have one or more edge cutouts, such as 1516A and 1516B, that provide visibility to a fiducial of an edge ring 1506 and/or a fiducial at or near an edge of the wafer support area. These edge cutouts 1516A and 1516B, for instance, may be the same as those cutouts provided herein above and may be used separately or together with the calibration wafer's 1514 through-holes and fiducials to determine an offset between the edge ring and wafer support 1502.

In some implementations, the calibration wafer may have a plurality of through-holes. FIG. 16 depicts a calibration wafer having a plurality of through-holes that is positioned on a wafer support having a plurality of fiducials. In this example, the through-holes are positioned in an interior area 1695 of the calibration wafer 1614 that has a boundary (represented by the dash-dot-dash line) that is less than the outer diameter of the calibration wafer 1614 edge 1618 and may also be closer to the calibration wafer's center axis than the edge cutouts, when such cutouts are present. The through-holes 1616A-C have a circular shape and may be spaced about the calibration wafer's 1614 center, such as equally or substantially equally spaced around the center, e.g., 120°, at the same or substantially the same radial distance R1 from the center of the calibration wafer 1614. The calibration wafer 1614 also has one or more fiducial markers positioned adjacent to each of the through-holes 1616A-C, with fiducial markers 1622A1, 1622B1, 1622C1, and 1622D1 adjacent to through-hole 1616A, fiducial markers 1622A2, 1622B2, 1622C2, and 1622D2 adjacent to through-hole 1616B, and fiducial markers 1622A3, 1622B3, 1622C3, and 1622D3 adjacent to through-hole 1616C. In this example, the fiducial markers of each through-hole are lines that converge at, or aligned with, the center of the corresponding through-hole and may be used to determine various positioning, such as in the various x- or y-axis offsets and/or angular positioning and orientation. For each through-hole, the fiducial markers are spaced apart and positioned at known locations and distances, such as orthogonal to each other about a center axis of the corresponding through-hole.

In some embodiments, the calibration wafer may have only one through-hole, only two through-holes, only three through-holes, only four through-holes, or only five through-holes, for example. Adding too many through-holes, such as 20 for instance, in the calibration wafer may result in unwanted effects, such as unwanted particle generation. In some implementations, the calibration wafer may have one center through-hole line in FIG. 15 and one or more other through-holes in the interior region, such as one or more of the through-holes 1616A-C in FIG. 16.

In FIG. 16, the calibration wafer is positioned on a wafer support area 1602 that includes a plurality of fiducial markers 1691A-C that are arranged about the center of the wafer support area. As shown, these fiducial markers 1691A-C are positioned at the same radial distance from the center of the wafer support area and equally spaced about the center axis, such as 120°. This positioning and spacing may not be exact due to some manufacturing tolerances, for instance, and may be within about +/−5%. The through-holes 1616A-C allows visibility of the wafer support area's 1602 fiducial markers 1691A-C. For clarity, the areas of the wafer support 1602 that are visible through the through-holes 1616A-C of the calibration wafer 1614 are identified with light shading. In some embodiments, the fiducial markers on the wafer support area are not equally spaced about the center axis, thus the through-hole position on the calibration wafer will also not be equally spaced out. The fiducial markers on the wafer support area 1602 may be various configurations, shapes, and sizes, such as lines, circles, triangles, squares, or a combination thereof. In this example, the fiducial markers 1691A-C include a cross with a circle. Similar to above, some implementations of the fiducial or fiducials on the wafer support may be various structural elements, such as grooves, holes, lines, channels, raised structures, for example.

Similar to the disclosure for FIG. 15 above, one or more gaps may exist between a fiducial marker on the calibration wafer and a fiducial marker on the wafer support and these gaps may be detected and measured to determine the relative offset between the calibration wafer and the wafer support. For example, in FIG. 16, a gap 1693 may exist between fiducial marker 1622C3 on the calibration wafer 1614 and fiducial marker 1691C1 on the wafer support area 1602 and this gap may be used, at least in part, to determine the relative offset between the calibration wafer and the wafer support. As noted above, the autocalibration wafers provided herein are configured to correspond with and capture images of the through-holes of the calibration wafer. For instance, in FIG. 16, an autocalibration wafer may have three downward-facing imaging sensors, similar to sensors 522 or 622, that are each positioned to have a field of view that corresponds with a corresponding through-hole 1616A-C, such as fields of view 1624A-C that can capture the fiducial markers of the calibration wafer 1614 and the fiducial markers on the wafer support 1602 in FIG. 16.

In some embodiments, as provided above, the calibration wafer may also have one or more edge cutouts, such as 1616D and 1616E, that provide visibility to a fiducial of an edge ring (not shown) and/or fiducial near the edge of the wafer support area 1602 (including the edge, like described above). These edge cutouts 1616D and 1616E, for instance, may be the same as those cutouts provided herein above and may be used separately or together with the calibration wafer's 1614 through-holes and fiducials to determine an offset between the edge ring and wafer support 1602. In some embodiments, the calibration wafer 1614 may have a single edge cutout or no edge cutouts (i.e., no cutouts 1616D and 1616E). In some embodiments, where the edge ring has a unique position/location/alignment indicator or feature, a single edge cut out positioned over such indicator or feature may be sufficient to align the edge ring properly. In some such embodiments, the position indicator may be shown on a top surface near the inner diameter of the edge ring. In some embodiments, the wafer support area may have a corresponding fiducial for aligning with the edge ring's position indicator. For example, the corresponding fiducial may be a symbol that would be aligned with the edge ring's position indicator (within a reasonable tolerance range) when the edge ring is properly installed.

The techniques and systems provided above are also configured to use calibration wafers with through-holes. For example, some of the above techniques reference using the autocalibration wafer's edge cameras and obtaining images of fiducials visible within the cutouts of the calibration wafer may be considered to include using imaging sensors to obtain images of fiducials visible nearby, around, and/or within through-holes, such as fiducials on the wafer support area visible within the through-holes and the fiducials of the calibration wafer around the through-holes.

Further, although the above description refers to calibration wafers having cutouts and/or through-holes, some implementations may use a calibration wafer without cutouts, but with one or more fiducial markers or with one or more see-through windows. The techniques and implementations may therefore be used with the fiducials of the calibration wafer and the fiducials of the wafer support and/or edge ring (if used). This may be enabled by, for example, the calibration wafer being sized smaller than a process wafer and fiducials near the calibration wafer's outer edge such that the outer edge of the wafer support area and edge ring, if present, are positioned radially outwards from the calibration wafer's outer edge and therefore visible. In some such implementations, the top surface of the calibration wafer may be a lapped surface which may result in a mat surface finish that reduces reflection and allows for imaging of the calibration wafer and fiducials of the calibration wafer, the wafer support, and the edge ring, if present.

As noted above, the controller may be part of a system that may include semiconductor processing equipment, including a processing tool or tools, chamber or chambers, platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, as well as various parameters affecting semiconductor processing, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

It will be understood that while the above discussions have focused on autocalibration wafer systems that typically feature a plurality of imaging sensors and, in various further implementations, one or more additional sensors, some implementations may feature a single center-mounted imaging sensor and no edge-located imaging sensors or only edge-located imaging sensors and no center-mounted imaging sensor; such implementations may, in some instances, provide correspondingly less functionality than implementations featuring both a center-mounted and edge-mounted imaging sensors, although not necessarily. This disclosure is to be understood as encompassing such alternative implementations as well.

The term “wafer,” as used herein, may refer to semiconductor wafers or substrates or other similar types of wafers or substrates. A wafer station, as the term is used herein, may refer to any location in a semiconductor processing tool in which a wafer may be placed during any of various wafer processing operations or wafer transfer operations. Wafer support is used herein to refer to any structure in a wafer station that is configured to receive and support a semiconductor wafer, e.g., a pedestal, an electrostatic chuck, a wafer support shelf, etc.

The term “nominally centered,” as used herein, refers to a relative placement of two or more objects such that certain locations, e.g., center points or similar locations, are generally aligned with one another in the XY plane. Such alignment may not be perfect for various reasons, e.g., slippage of one of the objects, sensor drift, etc., but in most cases, a nominally centered object may be within a millimeter or two of a perfectly centered object.

It is also to be understood that the use of ordinal indicators, e.g., (a), (b), (c), . . . , herein is for organizational purposes only, and is not intended to convey any particular sequence or importance to the items associated with each ordinal indicator. For example, “(a) obtain information regarding velocity and (b) obtain information regarding position” would be inclusive of obtaining information regarding position before obtaining information regarding velocity, obtaining information regarding velocity before obtaining information regarding position, and obtaining information regarding position simultaneously with obtaining information regarding velocity. There may nonetheless be instances in which some items associated with ordinal indicators may inherently require a particular sequence, e.g., “(a) obtain information regarding velocity, (b) determine a first acceleration based on the information regarding velocity, and (c) obtain information regarding position”; in this example, (a) would need to be performed before (b) since (b) relies on information obtained in (a)-(c), however, could be performed before or after either of (a) or (b).

It is to be understood that use of the word “each,” such as in the phrase “for each <item> of the one or more <items>” or “of each <item>,” if used herein, should be understood to be inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, when a selected item may have one or more sub-items and a selection of one of those sub-items is made, it will be understood that in the case where the selected item has one and only one sub-item, selection of that one sub-item is inherent in the selection of the item itself.

It will also be understood that references to multiple controllers that are configured, in aggregate, to perform various functions are intended to encompass situations in which only one of the controllers is configured to perform all of the functions disclosed or discussed, as well as situations in which the various controllers each perform sub-portions of the functionality discussed. For example, an autocalibration wafer may include a controller that is configured to control the operation of the various sensors on the autocalibration wafer and communicate data therefrom to another controller associated with a semiconductor processing tool; the semiconductor processing tool controller may then analyze such data to determine various operational parameters for use with the semiconductor processing tool.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

1. A calibration wafer for use in a semiconductor processing tool, the calibration wafer comprising:
a nominally circular disk shape having an outer edge with a nominal diameter selected from the group consisting of: 200 mm±1 mm, 300 mm±1 mm, and 450 mm±1 mm;
two or more cutouts arranged along the outer edge; and
a plurality of fiducial markers, wherein:
each cutout is at least partially defined by one or more edges,
each cutout extends radially inwards at least 2 mm from a reference circle defined by the outer edge, and
one or more fiducial markers are adjacent to each cutout.

2. The calibration wafer of claim 1, wherein for each cutout, at least one fiducial marker extends around at least one edge of the one or more edges of the cutout.

3. The calibration wafer of claim 2, wherein:
each cutout has a shape, and
at least one fiducial marker has a substantially similar shape to the shape of the cutout.

4. The calibration wafer of claim 2, wherein for each cutout, at least one fiducial marker is adjacent to the least one edge of the cutout.

5. The calibration wafer of claim 1, wherein for each cutout, at least one fiducial marker has a section that extends along at least a part of at least one edge of the cutout and is offset from the at least one edge by a substantially constant offset distance.

6. The calibration wafer of claim 1, wherein for each cutout, at least one fiducial marker is positioned within a distance of about 5 mm or less from one edge of the corresponding cutout.

7. The calibration wafer of claim 1, wherein for each cutout, at least one fiducial marker has a width between about 3 mm and about 0.01 mm.

8. The calibration wafer of claim 1, wherein for each cutout, at least one fiducial marker has a shape of a C-shape, an L-shape, a semi-circular shape, a partially obround shape, a linear shape, a plurality of lines, a non-linear shape, or one or more linear sections and one or more non-linear sections.

9. The calibration wafer of claim 1, wherein:
each cutout includes at least four fiducial markers that form a pattern, and
the pattern is a plurality of circles, a plurality of triangles, a plurality of squares, a plurality of rectangles, a plurality of diamonds, a plurality of squares with at least two squares in contact with each other, a checkerboard, or a combination thereof.

10. The calibration wafer of claim 1, wherein for each cutout, at least one fiducial marker has a linear shape and is oriented along an axis that substantially intersects with a center of the calibration wafer.

11. The calibration wafer of claim 1, wherein:
when viewed along an axis parallel to a center axis of the calibration wafer, each cutout has a shape, and
the shape is a square, a square with rounded corners, a rectangle, a rectangle with rounded corners, a V-shape, a circle, a semi-circle, a triangle, a triangle with rounded corners, an obround shape, an ellipse, a hexagon, a pentagon, an octagon, a shape with linear and non-linear sections, or a shape with a plurality of linear sections.

12. The calibration wafer of claim 1, wherein:
when viewed along an axis parallel to a center axis of the calibration wafer, each cutout has a shape, and
the shape has a width less than or equal to about 10 mm and a length less than or equal to about 10 mm.

13. The calibration wafer of claim 1, further comprising three or more cutouts arranged along the outer edge.

14. The calibration wafer of claim 1, wherein the cutouts are arranged in a circular array about a center point of the calibration wafer.

15. The calibration wafer of claim 14, wherein the cutouts are spaced substantially equally from each other about the center point.

16. The calibration wafer of claim 1, wherein each cutout is a through-hole.

17. The calibration wafer of claim 1, further comprising:
a top surface; and
a bottom surface opposite the top surface and at least partially defining a nominal thickness, wherein:
the top surface has a different surface roughness than the bottom surface.

18. The calibration wafer of claim 17, wherein the top surface is a lapped or polished surface.

19. The calibration wafer of claim 1, further comprising a nominal thickness of between about 0.5 mm and about 1.5 mm.

20. The calibration wafer of claim 1, further comprising:
one or more through-holes in an interior region of the calibration wafer, and
a second plurality of fiducial markers, wherein:
each through-hole is at least partially defined by one or more edges, and
one or more fiducial markers of the second plurality of fiducial markers are adjacent to each through-hole.

21-30. (canceled)
